(19) United States
(12) Patent Application Publication
(10) Pub. No.: US 2023/0292534 A1
(43) Pub. Date: Sep. 14, 2023

(54) PHOTOELECTRIC CONVERSION ELEMENT AND METHOD FOR MANUFACTURING SAME

(71) Applicant: SUMITOMO CHEMICAL COMPANY, LIMITED, Tokyo (JP)

(72) Inventors: Mayuko OGASAWARA, Tsukuba-shi (JP); Akiko KISHIDA, Tsukuba-shi (JP); Takashi ARIMURA, Tsukuba-shi (JP); Miki KATAKURA, Niihama-shi (JP)

(73) Assignee: SUMITOMO CHEMICAL COMPANY, LIMITED, Tokyo (JP)

(21) Appl. No.: 18/015,716

(22) PCT Filed: Jul. 9, 2021
(86) PCT No.: PCT/JP2021/025923

§ 371 Date: Jan. 11, 2023

(30) Foreign Application Priority Data
Jul. 17, 2020 (JP) 2020-123250

(51) Int. Cl. H10K 30/30; H10K 85/20; H10K 85/10; H10K 85/60; H10K 71/40

(52) U.S. Cl. CPC H10K 30/30; H10K 85/215; H10K 85/151; H10K 85/113; H10K 85/621; H10K 85/626; H10K 85/6576; H10K 85/657; H10K 71/40

(57) ABSTRACT

Heat resistance is improved.

A photoelectric conversion element 10 includes an anode 12, a cathode 16, and an active layer 14 provided between the anode and the cathode, in which the active layer contains at least one p-type semiconductor material and at least two n-type semiconductor materials, and a dispersive energy Hansen solubility parameter δD(P) of the at least one p-type semiconductor material and a first dispersive energy Hansen solubility parameter δD(Ni) and a second dispersive energy Hansen solubility parameter δD(Nii) of the at least two n-type semiconductor materials satisfy the following requirements (i) and (ii):

2.1 MPa^{0.5}<|δD(P)−δD(Ni)|+|δD(Ni)−δD(Nii)|<4.0 MPa^{0.5} Requirement (i):

0.8 MPa^{0.5}<|δD(P)−δD(Ni)| and 0.2 MPa^{0.5}<|δD(Ni)−δD(Nii)| Requirement (ii):

### TECHNICAL FIELD

The present invention relates to a photoelectric conversion element and a method for manufacturing the same.

### BACKGROUND ART

A photoelectric conversion element is, for example, an extremely useful device from the viewpoint of energy saving and reduction of a carbon dioxide emission amount, and has attracted attention.

The photoelectric conversion element is an element including at least a pair of electrodes including an anode and a cathode, and an active layer provided between the pair of electrodes. In the photoelectric conversion element, at least one of the pair of electrodes is formed of a transparent or translucent material, and light is incident on the active layer from the transparent or translucent electrode. Charges (holes and electrons) are generated in the active layer by energy (hν) of light incident on the active layer, and the generated holes move toward the anode and the electrons move toward the cathode. Then, the charges that have reached the anode and the cathode are taken out to the outside of the element.

The active layer having a phase separation structure composed of a phase containing an n-type semiconductor material and a phase containing a p-type semiconductor material by mixing the n-type semiconductor material (electron accepting compound) and the p-type semiconductor material (electron donating compound) is also referred to as a bulk heterojunction type active layer.

In such a photoelectric conversion element including a bulk heterojunction type active layer, in order to further improve photoelectric conversion efficiency, for example, P3HT is used as a p-type semiconductor material, and [6,6]-phenyl-C71 butyric acid methyl ester (C70PCBM), which is a fullerene derivative, is used as an n-type semiconductor material (see Patent Document 1 and Non-Patent Documents 1 and 2).

### PRIOR ART DOCUMENTS

### Patent Document

Patent Document 1: CN 109980090 A

### Non-Patent Documents

Non-Patent Document 1: Nanoscale Research Letters, 2019, 14, 201.
Non-Patent Document 2: Materials Chemistry Frontiers, 2019, 3, 1085.

### SUMMARY OF THE INVENTION

### Problems to be Solved by the Invention

However, in the photoelectric conversion element according to the prior art documents described above, in consideration of a heating temperature in a step of manufacturing the photoelectric conversion element, a step of incorporating the photoelectric conversion element in a device, and the like, for example, characteristics such as an external quantum efficiency (EQE) of the photoelectric conversion element are deteriorated due to a heat treatment such as a reflow step performed in the step of manufacturing the photoelectric conversion element or the step of incorporating the photoelectric conversion element in a device to which the photoelectric conversion element is applied.

Therefore, it is required to suppress the deterioration of the external quantum efficiency in the heat treatment in the manufacturing step and the heat treatment when the photoelectric conversion element is incorporated in a device, and to improve heat resistance.

### Means for Solving the Problems

As a result of conducting intensive studies to solve the above problems, the present inventors have found that, by adopting the condition of the Hansen solubility parameter of the semiconductor material used as the material of the bulk heterojunction type active layer as a predetermined condition, the deterioration of the external quantum efficiency of the photoelectric conversion element can be suppressed, and the heat resistance can thus be improved, thereby completing the present invention. Therefore, the present invention provides the following [1] to [25].
[1] A photoelectric conversion element including an anode, a cathode, and an active layer provided between the anode and the cathode,
in which the active layer contains at least one p-type semiconductor material and at least two n-type semiconductor materials, and
a dispersive energy Hansen solubility parameter δD(P) of the at least one p-type semiconductor material and a first dispersive energy Hansen solubility parameter δD(Ni) and a second dispersive energy Hansen solubility parameter δD(Nii) of the at least two n-type semiconductor materials satisfy the following requirements (i) and (ii):

2.1 MPa^{0.5}<|δD(P)−δD(Ni)|+|δD(Ni)−δD(Nii)|<4.0 MPa^{0.5} Requirement (i):

0.8 MPa^{0.5}<|δD(P)−δD(Ni)| and 0.2 MPa^{0.5}<|δD(Ni)−δD(Nii)| Requirement (ii):
in the requirements (i) and (ii),
δD(P) is a value calculated by the following Equation (1),

$$\begin{matrix}[ Math . 1 ] & \\ δ D ( P ) = \frac{1}{{\sum }_{b = 1}^{a} {w}_{b}} {\sum }_{b = 1}^{a} {w}_{b} δ D ( {P}_{b} ) & ( 1 )\end{matrix}$$

in Equation (1),
a is an integer of 1 or more and represents the number of types of the p-type semiconductor materials contained in the active layer,
b is an integer of 1 or more and represents the order of weight values of the p-type semiconductor materials contained in the active layer when the weight values are arranged in descending order,
W_{b} represents a weight of the p-type semiconductor material (P_{b}) whose weight order is b, the p-type semiconductor material being contained in the active layer, and
δD(P_{b}) represents a dispersive energy Hansen solubility parameter of the p-type semiconductor material (P_{b}), and
δD(Ni) and δD(Nii) are determined based on δD(N′) and δD(N″) calculated by the following Equations (2) and (3), respectively, and when a value of |δD(P)−δD(N′)| and a value of |δD(P)−δD(N″)| are compared, a dispersive energy Hansen solubility parameter with a smaller value is δD(Ni), and a dispersive energy Hansen solubility parameter with a larger value is δD(Nii), in which δD(N′) is a value of a material having the largest value of the dispersive energy Hansen solubility parameter (δD) among two or more materials in a case where the number of materials having the highest order is two or more when weight values are arranged in descending order,

[Math. 2]

δD(N′)=δD(N₁) (2)

### in Equation (2),

δD(N₁) represents a dispersive energy Hansen solubility parameter of an n-type semiconductor material having the largest weight value contained in the active layer among the two or more n-type semiconductor materials,

$$\begin{matrix}[ Math . 2 ] & \\ δ D ( N ’ ’ ) = \frac{1}{{\sum }_{d = 2}^{c} {w}_{d}} {\sum }_{d = 2}^{c} {w}_{d} δ D ( {N}_{d} ) & ( 3 )\end{matrix}$$

in Equation (3),
c is an integer of 2 or more and represents the number of types of the n-type semiconductor materials contained in the active layer,
d is an integer of 1 or more and represents the order of weight values of the n-type semiconductor materials contained in the active layer when the weight values are arranged in descending order,
W_{d} represents a weight of the n-type semiconductor material (N_{d}) whose weight order is d, the n-type semiconductor material being contained in the active layer, and
δD(N_{d}) represents a dispersive energy Hansen solubility parameter of the n-type semiconductor material (N_{d}).
[2] The photoelectric conversion element according to [1], in which the p-type semiconductor material contains a polymer compound having a structural unit represented by the following Formula (I):

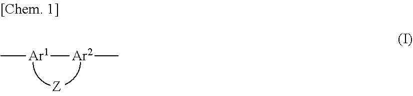

in Formula (I),
Ar¹ and Ar² each independently represent a trivalent aromatic heterocyclic group which may have a substituent, and
Z represents a group represented by any one of the following Formulas (Z-1) to (Z-7),

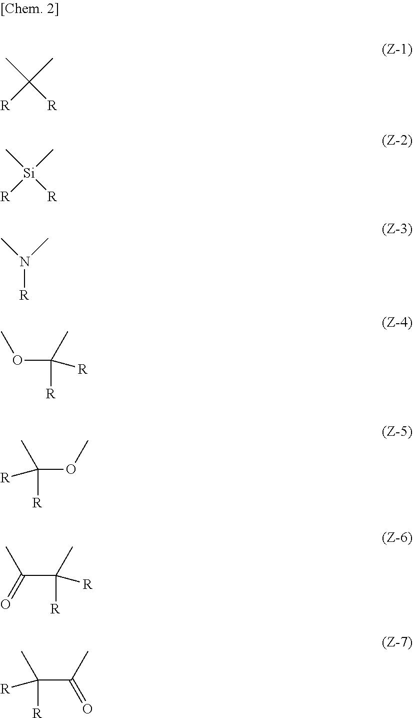

in Formulas (Z-1) to (Z-7),
R represents
a hydrogen atom,
a halogen atom,
an alkyl group which may have a substituent,
an aryl group which may have a substituent,
a cycloalkyl group which may have a substituent,
an alkoxy group which may have a substituent,
a cycloalkoxy group which may have a substituent,
an aryloxy group which may have a substituent,
an alkylthio group which may have a substituent,
a cycloalkylthio group which may have a substituent,
an arylthio group which may have a substituent,
a monovalent heterocyclic group which may have a substituent,
a substituted amino group which may have a substituent,
an acyl group which may have a substituent,
an imine residue which may have a substituent,
an amide group which may have a substituent,
an acid imide group which may have a substituent,
a substituted oxycarbonyl group which may have a substituent,
an alkenyl group which may have a substituent,
a cycloalkenyl group which may have a substituent,
an alkynyl group which may have a substituent,
a cycloalkynyl group which may have a substituent,
a cyano group,
a nitro group,
a group represented by —C(═O)—R^{a}, or
a group represented by —SO₂—R^{b},
R^{a} and R^{b} each independently represent
a hydrogen atom,
an alkyl group which may have a substituent,
an aryl group which may have a substituent,
an alkoxy group which may have a substituent,
an aryloxy group which may have a substituent, or
a monovalent heterocyclic group which may have a substituent, and
in Formulas (Z-1) to (Z-7), when the number of R's is two, the two R's may be the same as or different from each other.
[3] The photoelectric conversion element according to [1] or [2], in which at least one of the at least two n-type semiconductor materials is a non-fullerene compound.
[4] The photoelectric conversion element according to [3], in which at least one of the at least two n-type semiconductor materials is a non-fullerene compound, and the remaining n-type semiconductor material is a fullerene derivative.
[5] The photoelectric conversion element according to [3], in which both of the at least two n-type semiconductor materials are non-fullerene compounds.
[6] The photoelectric conversion element according to any one of [3] to [5], in which the non-fullerene compound is a compound represented by the following Formula (VIII):

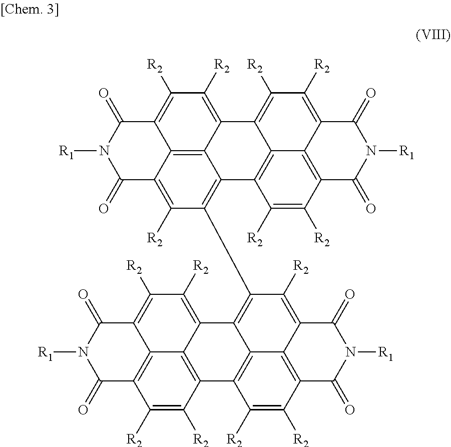

in Formula (VIII),
R₁ represents a hydrogen atom, a halogen atom, an alkyl group which may have a substituent, an alkoxy group which may have a substituent, a monovalent aromatic hydrocarbon group which may have a substituent, or a monovalent aromatic heterocyclic group which may have a substituent, and the plurality of R₁'s may be the same as or different from each other, and
R₂ represents a hydrogen atom, a halogen atom, an alkyl group which may have a substituent, an alkoxy group which may have a substituent, a monovalent aromatic hydrocarbon group which may have a substituent, or a monovalent aromatic heterocyclic group which may have a substituent, and the plurality of R₂'s may be the same as or different from each other.
[7] The photoelectric conversion element according to any one of [3] to [5], in which the non-fullerene compound is a compound represented by the following Formula (IX):

A¹-B¹⁰-A² (IX)
in Formula (IX),
A¹ and A² each independently represent an electron-withdrawing group, and
B¹⁰ represents a group having a n-conjugated system.
[8] The photoelectric conversion element according to [7], in which the non-fullerene compound is a compound represented by the following Formula (X):

A¹-(S¹)ₙ₁—B¹¹—(S²)ₙ₂-A² (X)
in Formula (X),
A¹ and A² each independently represent an electron-withdrawing group,
S¹ and S² each independently represent
a divalent carbocyclic group which may have a substituent,
a divalent heterocyclic group which may have a substituent,
a group represented by —C(R^{s1})═C(R^{s2})—, or
a group represented by —C≡C—,
R^{s1} and R^{s2} each independently represent a hydrogen atom or a substituent,
B¹¹ represents a divalent group having a condensed ring in which two or more ring structures selected from the group consisting of a carbocyclic ring and a heterocyclic ring are condensed, in which the divalent group does not have an ortho-peri-condensed structure and may have a substituent, and
n1 and n2 each independently represent an integer of 0 or more.
[9] The photoelectric conversion element according to [8], in which B¹¹ is a divalent group having a condensed ring in which two or more ring structures selected from the group consisting of structures represented by the following Formulas (Cy1) to (Cy9), in which the divalent group may have a substituent.

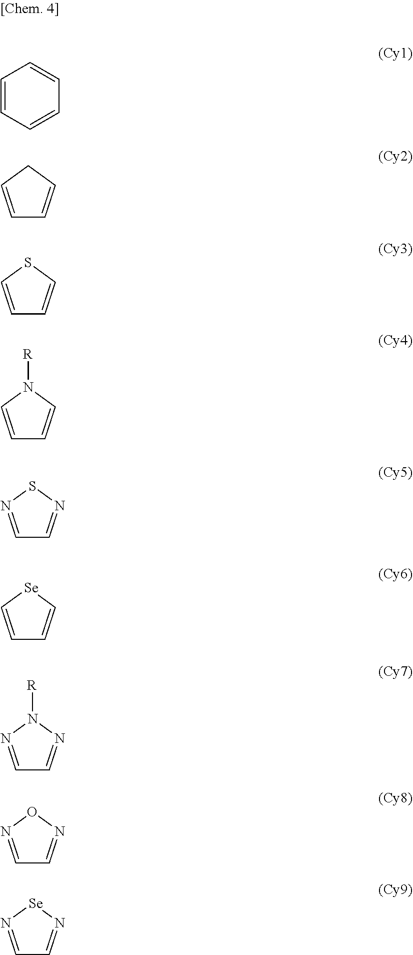

in the formulas, R is as defined above.
[10] The photoelectric conversion element according to [8] or [9], in which S¹ and S² each independently represent a group represented by the following Formula (s-1) or a group represented by the following Formula (s-2):

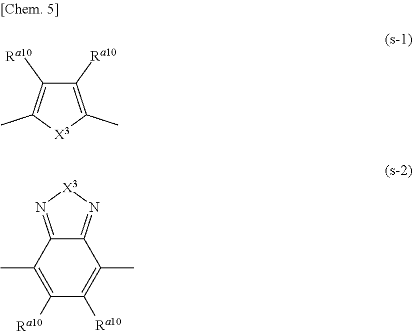

in Formulas (s-1) and (s-2),
X3 represents an oxygen atom or a sulfur atom, and
R^{a10}'s each independently represent a hydrogen atom, a halogen atom, or an alkyl group.
[11] The photoelectric conversion element according to any one of [7] to [10], in which A¹ and A² are each independently a group represented by —CH═C(—CN)₂ or a group selected from the group consisting of the following Formulas (a-1) to (a-7):

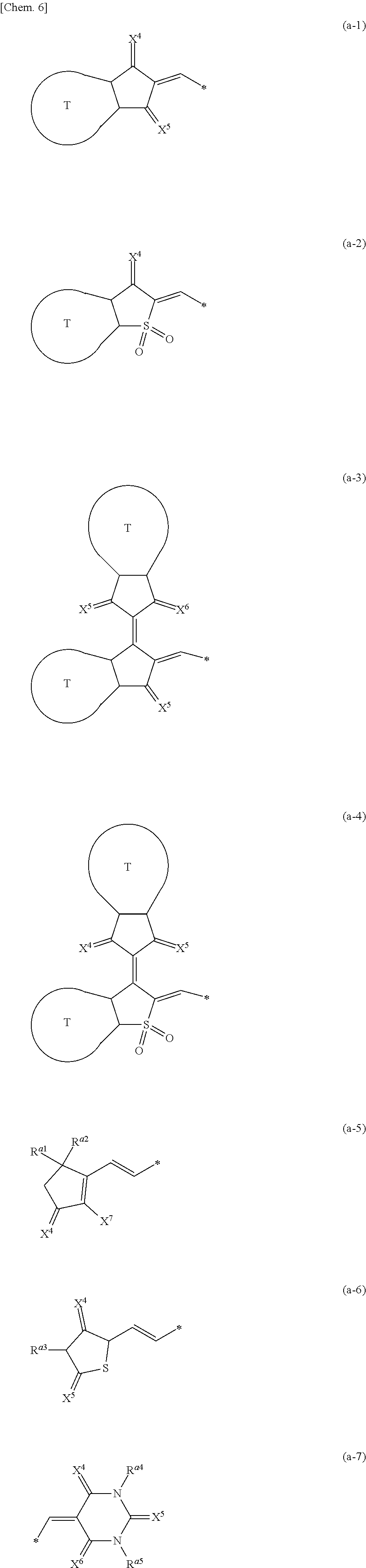

in Formulas (a-1) to (a-7),
T represents
a carbocyclic ring which may have a substituent or a heterocyclic ring which may have a substituent,
X⁴, X⁵, and X⁶ each independently represent an oxygen atom, a sulfur atom, an alkylidene group, or a group represented by ═C(—CN)₂,
X⁷ represents a hydrogen atom, a halogen atom, a cyano group, an alkyl group which may have a substituent, an alkoxy group which may have a substituent, an aryl group which may have a substituent, or a monovalent heterocyclic group which may have a substituent, and
R^{a1}, R^{a2}, R^{a3}, R^{a4}, and R^{a5} each independently represent a hydrogen atom, an alkyl group which may have a substituent, a halogen atom, an alkoxy group which may have a substituent, an aryl group which may have a substituent, or a monovalent heterocyclic group.
[12] The photoelectric conversion element according to any one of [1] to [11], in which the active layer is formed by a step including a heat treatment performed at a heating temperature of 200° C. or higher.
[13] The photoelectric conversion element according to any one of [1] to [12], in which the photoelectric conversion element is a photodetector.
[14] An image sensor including the photoelectric conversion element according to [13],
in which the image sensor is manufactured by a manufacturing method including a step including heating the photoelectric conversion element at a heating temperature of 200° C. or higher.
[15] A biometric authentication device including the photoelectric conversion element according to [13],
in which the biometric authentication device is manufactured by a manufacturing method including a step including heating the photoelectric conversion element at a heating temperature of 200° C. or higher.
[16] A method for manufacturing the photoelectric conversion element according to any one of [1] to [11], the method including a step of forming the active layer that includes a step (i) of obtaining a coating film by applying an ink containing the at least one p-type semiconductor material and the at least two n-type semiconductor materials to an object to be coated; and a step (ii) of removing a solvent from the obtained coating film.
[17] The method for manufacturing the photoelectric conversion element according to [16], further including a step of performing heating at a heating temperature of 200° C. or higher.
[18] The method for manufacturing the photoelectric conversion element according to [17], in which the step of performing heating at a heating temperature of 200° C. or higher is performed after the step (ii).
[19] A composition containing at least one p-type semiconductor material and at least two n-type semiconductor materials,
in which a dispersive energy Hansen solubility parameter δD(P) of the at least one p-type semiconductor material and a first dispersive energy Hansen solubility parameter δD(Ni) and a second dispersive energy Hansen solubility parameter δD(Nii) of the at least two n-type semiconductor materials satisfy the following requirements (i) and (ii):

2.1 MPa^{0.5}<|δD(P)−δD(Ni)|+|δD(Ni)−δD(Nii)|<4.0 MPa^{0.5} Requirement (i):

0.8 MPa^{0.5}<|δD(P)−δD(Ni)| and 0.2 MPa^{0.5}<|δD(Ni)−δD(Nii)| Requirement (ii):
in the requirements (i) and (ii),
δD(P) is a value calculated by the following Equation (1),

$$\begin{matrix}[ Math . 4 ] & \\ δ D ( P ) = \frac{1}{{\sum }_{b = 1}^{a} {w}_{b}} {\sum }_{b = 1}^{a} {w}_{b} δ D ( {P}_{b} ) & ( 1 )\end{matrix}$$

in Equation (1),
a is an integer of 1 or more and represents the number of types of the p-type semiconductor materials contained in the active layer,
b is an integer of 1 or more and represents the order of weight values of the p-type semiconductor materials contained in the active layer when the weight values are arranged in descending order,
W_{b} represents a weight of the p-type semiconductor material (P_{b}) whose weight order is b, the p-type semiconductor material being contained in the active layer, and
δD(P_{b}) represents a dispersive energy Hansen solubility parameter of the p-type semiconductor material (P_{b}), and
δD(Ni) and δD(Nii) are determined based on δD(N′) and δD(N″) calculated by the following Equations (2) and (3), respectively, and when a value of |δD(P)−δD(N′)| and a value of |δD(P)−δD(N″)| are compared, a dispersive energy Hansen solubility parameter with a smaller value is δD(Ni), and a dispersive energy Hansen solubility parameter with a larger value is δD(Nii), in which δD(N′) is a value of a material having the largest value of the dispersive energy Hansen solubility parameter (δD) among two or more materials in a case where the number of materials having the highest order is two or more when weight values are arranged in descending order,

[Math. 5]

δD(N′)=δD(N₁) (2)
in Equation (2),
δD(N₁) represents a dispersive energy Hansen solubility parameter of an n-type semiconductor material having the largest weight value contained in the active layer among the two or more n-type semiconductor materials,

$$\begin{matrix}[ Math . 6 ] & \\ δ D ( N ’ ’ ) = \frac{1}{{\sum }_{d = 2}^{c} {w}_{d}} {\sum }_{d = 2}^{c} {w}_{d} δ D ( {N}_{d} ) & ( 3 )\end{matrix}$$

in Equation (3),
c is an integer of 2 or more and represents the number of types of the n-type semiconductor materials contained in the active layer,
d is an integer of 1 or more and represents the order of weight values of the n-type semiconductor materials contained in the active layer when the weight values are arranged in descending order,
W_{d} represents a weight of the n-type semiconductor material (N_{d}) whose weight order is d, the n-type semiconductor material being contained in the active layer, and
δD(N_{d}) represents a dispersive energy Hansen solubility parameter of the n-type semiconductor material (N_{d}).
[20] The composition according to [19], in which the p-type semiconductor material is a polymer compound having a structural unit represented by the following Formula (I):

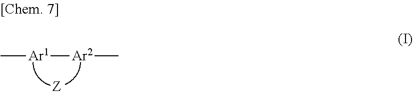

in Formula (I),
Ar¹ and Ar² each independently represent a trivalent aromatic heterocyclic group which may have a substituent, and
Z represents a group represented by any one of the following Formulas (Z-1) to (Z-7),

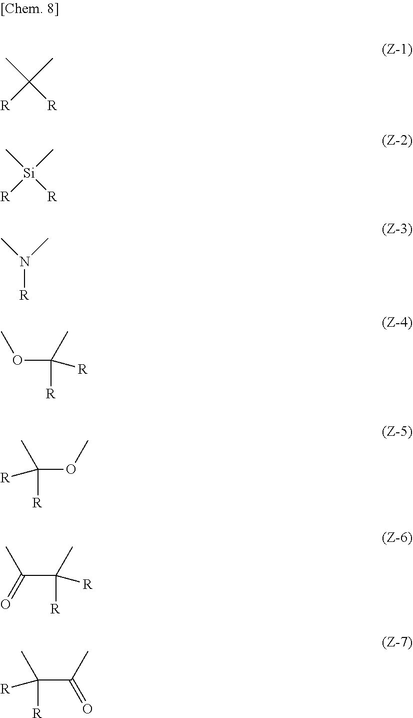

in Formulas (Z-1) to (Z-7),
R represents
a hydrogen atom,
a halogen atom,
an alkyl group which may have a substituent,
an aryl group which may have a substituent,
a cycloalkyl group which may have a substituent,
an alkoxy group which may have a substituent,
a cycloalkoxy group which may have a substituent,
an aryloxy group which may have a substituent,
an alkylthio group which may have a substituent,
a cycloalkylthio group which may have a substituent,
an arylthio group which may have a substituent,
a monovalent heterocyclic group which may have a substituent,
a substituted amino group which may have a substituent,
an acyl group which may have a substituent,
an imine residue which may have a substituent,
an amide group which may have a substituent,
an acid imide group which may have a substituent,
a substituted oxycarbonyl group which may have a substituent,
an alkenyl group which may have a substituent,
a cycloalkenyl group which may have a substituent,
an alkynyl group which may have a substituent,
a cycloalkynyl group which may have a substituent,
a cyano group,
a nitro group,
a group represented by —C(═O)—R^{a}, or
a group represented by —SO₂—R^{b},
R^{a} and R^{b} each independently represent
a hydrogen atom,
an alkyl group which may have a substituent,
an aryl group which may have a substituent,
an alkoxy group which may have a substituent,
an aryloxy group which may have a substituent, or
a monovalent heterocyclic group which may have a substituent, and
in Formulas (Z-1) to (Z-7), when the number of R's is two, the two R's may be the same as or different from each other, and
at least one of the at least two n-type semiconductor materials is a non-fullerene compound.
[21] The composition according to [20], in which at least one of the at least two n-type semiconductor materials is a non-fullerene compound, and the remaining n-type semiconductor material is a fullerene derivative.
[22] The composition according to [20], in which both of the at least two n-type semiconductor materials are non-fullerene compounds.
[23] The composition according to any one of [20] to [22], in which the non-fullerene compound is a compound represented by the following Formula (VIII):

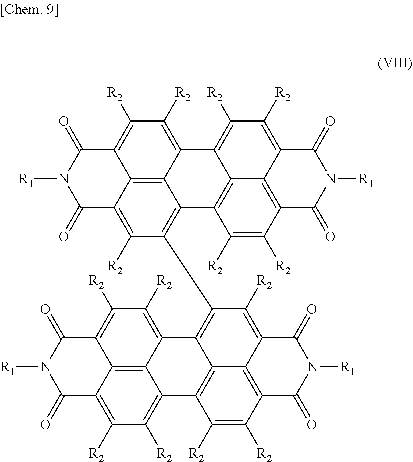

in Formula (VIII),
R₁ represents a hydrogen atom, a halogen atom, an alkyl group which may have a substituent, an alkoxy group which may have a substituent, a monovalent aromatic hydrocarbon group which may have a substituent, or a monovalent aromatic heterocyclic group which may have a substituent, and the plurality of R₁'s may be the same as or different from each other, and
R₂ represents a hydrogen atom, a halogen atom, an alkyl group which may have a substituent, an alkoxy group which may have a substituent, a monovalent aromatic hydrocarbon group which may have a substituent, or a monovalent aromatic heterocyclic group which may have a substituent, and the plurality of R₂'s may be the same as or different from each other.
[24] The composition according to any one of [20] to [22], in which the non-fullerene compound is a compound represented by the following Formula (IX):

A¹-B¹⁰-A² (IX)
in Formula (IX),
A¹ and A² each independently represent an electron-withdrawing group, and
B¹⁰ represents a group having a n-conjugated system.
[25] An ink containing the composition according to any one of [19] to [24].

### Effect of the Invention

According to the present invention, in the step of manufacturing the photoelectric conversion element or the step of incorporating the photoelectric conversion element in a device to which the photoelectric conversion element is applied, the deterioration of the external quantum efficiency of the photoelectric conversion element can be effectively suppressed, and the heat resistance can thus be improved.

### BRIEF DESCRIPTION OF THE DRAWINGS

FIG. 1 is a view schematically illustrating a configuration example of a photoelectric conversion element.

FIG. 2 is a view schematically illustrating a configuration example of an image detection unit.

FIG. 3 is a view schematically illustrating a configuration example of a fingerprint detection unit.

FIG. 4 is a view schematically illustrating a configuration example of an image detection unit for an X-ray imaging device.

FIG. 5 is a view schematically illustrating a configuration example of a vein detection unit for a vein authentication device.

FIG. 6 is a view schematically illustrating a configuration example of an image detection unit for an indirect time-of-flight (TOF) type distance measuring device.

FIG. 7 is a graph showing a relationship between a heating temperature and EQEₕₑₐₜ/EQE_{100° C.}.

FIG. 8 is a graph showing a relationship between a heating temperature and EQEₕₑₐₜ/EQE_{100° C.}.

FIG. 9 is a graph showing a relationship between a heating temperature and dark currentₕₑₐₜ/dark current_{100° C.}.

FIG. 10 is a graph showing a relationship between a heating temperature and dark currentₕₑₐₜ/dark current_{100° C.}.

FIG. 11 is a graph showing a relationship between a heating temperature and dark currentₕₑₐₜ/dark current_{100° C.}.

FIG. 12 is a graph showing a relationship between |δD(P)−δD(Ni)| and |δD(Ni)−δD(Nii)|.

### MODE FOR CARRYING OUT THE INVENTION

Hereinafter, a photoelectric conversion element according to an embodiment of the present invention will be described with reference to the drawings. Note that the drawings merely schematically illustrate the shape, size, and arrangement of constituent elements to the extent that the invention can be understood. The present invention is not limited by the following description, and each constituent element can be appropriately changed without departing from the gist of the present invention. In addition, the configuration according to the embodiment of the present invention is not necessarily made or used in the arrangement illustrated in the drawings.

Terms commonly used in the following description will be first described.

The “polymer compound” means a polymer having a molecular weight distribution and a number average molecular weight of 1×10³ or more and 1×10⁸ or less in terms of polystyrene. Note that a structural unit included in the polymer compound is 100 mol % in total.

The “structural unit” means one or more residues derived from a raw material monomer present in the polymer compound.

The “hydrogen atom” may be a light hydrogen atom or a heavy hydrogen atom.

Examples of the “halogen atom” include a fluorine atom, a chlorine atom, a bromine atom, and an iodine atom.

An aspect of “which may have a substituent” includes both aspects of a case where all hydrogen atoms constituting a compound or group are unsubstituted and a case where some or all of one or more hydrogen atoms are substituted with a substituent.

Examples of the “substituent” include a halogen atom, an alkyl group, a cycloalkyl group, an alkenyl group, a cycloalkenyl group, an alkynyl group, a cycloalkynyl group, an alkoxy group, a cycloalkoxy group, an alkylthio group, a cycloalkylthio group, an aryl group, an aryloxy group, an arylthio group, a monovalent heterocyclic group, a substituted amino group, an acyl group, an imine residue, an amide group, an acid imide group, a substituted oxycarbonyl group, a cyano group, an alkylsulfonyl group, and a nitro group.

In the present specification, the “alkyl group” may have any of a linear shape, a branched shape, and a cyclic shape unless otherwise specified. The number of carbon atoms in a linear alkyl group is usually 1 to 50, preferably 1 to 30, and more preferably 1 to 20, without including the number of carbon atoms in the substituent. The number of carbon atoms in a branched or cyclic alkyl group is usually 3 to 50, preferably 3 to 30, and more preferably 4 to 20, without including the number of carbon atoms in the substituent.

Specific examples of the alkyl group include a methyl group, an ethyl group, an n-propyl group, an isopropyl group, an n-butyl group, an isobutyl group, a tert-butyl group, an n-pentyl group, an isoamyl group, a 2-ethylbutyl group, an n-hexyl group, a cyclohexyl group, an n-heptyl group, a cyclohexylmethyl group, a cyclohexylethyl group, an n-octyl group, a 2-ethylhexyl group, a 3-n-propylheptyl group, an adamantyl group, an n-decyl group, a 3,7-dimethyloctyl group, a 2-ethyloctyl group, a 2-n-hexyl-decyl group, an n-dodecyl group, a tetradecyl group, a hexadecyl group, an octadecyl group, and an icosyl group.

The alkyl group may have a substituent. The alkyl group having a substituent is, for example, a group in which a hydrogen atom in the alkyl group exemplified above is substituted with a substituent such as an alkoxy group, an aryl group, or a fluorine atom.

Specific examples of alkyl having a substituent include a trifluoromethyl group, a pentafluoroethyl group, a perfluorobutyl group, a perfluorohexyl group, a perfluorooctyl group, a 3-phenylpropyl group, a 3-(4-methylphenyl) propyl group, a 3-(3,5-dihexylphenyl)propyl group, and a 6-ethyloxyhexyl group.

The “cycloalkyl group” may be a monocyclic group or a polycyclic group. The cycloalkyl group may have a substituent. The number of carbon atoms in the cycloalkyl group is usually 3 to 30 and preferably 12 to 19 without including the number of carbon atoms in the substituent.

Examples of the cycloalkyl group include alkyl groups having no substituent, such as a cyclopentyl group, a cyclohexyl group, a cycloheptyl group, and an adamantyl group, and a group in which a hydrogen atom in these groups is substituted with a substituent such as an alkyl group, an alkoxy group, an aryl group, or a fluorine atom.

Specific examples of a cycloalkyl group having a substituent include a methylcyclohexyl group and an ethylcyclohexyl group.

The “p-valent aromatic carbocyclic group” means a remaining atomic group obtained by removing p hydrogen atoms directly bonded to carbon atoms constituting a ring from an aromatic hydrocarbon which may have a substituent. The p-valent aromatic carbocyclic group may further have a substituent.

The “aryl group” means a monovalent aromatic carbocyclic group, which is a remaining atomic group obtained by removing one hydrogen atom directly bonded to carbon atoms constituting a ring from an aromatic hydrocarbon which may have a substituent.

The aryl group may have a substituent. Examples of the aryl group include a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 2-phenylphenyl group, a 3-phenylphenyl group, a 4-phenylphenyl group, and a group in which a hydrogen atom in these groups is substituted with a substituent such as an alkyl group, an alkoxy group, an aryl group, or a fluorine atom.

The “alkoxy group” may have any of a linear shape, a branched shape, and a cyclic shape. The number of carbon atoms in the alkoxy group is usually 1 to 40 and preferably 1 to 10 without including the number of carbon atoms in the substituent. The number of carbon atoms in the alkoxy group is usually 3 to 40 and preferably 4 to 10 without including the number of carbon atoms in the substituent.

The alkoxy group may have a substituent. Examples of the alkoxy group include a methoxy group, an ethoxy group, an n-propyloxy group, an isopropyloxy group, an n-butyloxy group, an isobutyloxy group, a tert-butyloxy group, an n-pentyloxy group, an n-hexyloxy group, an n-heptyloxy group, an n-octyloxy group, a 2-ethylhexyloxy group, an n-nonyloxy group, an n-decyloxy group, a 3,7-dimethyloctyloxy group, a 3-heptyldodecyloxy group, a lauryloxy group, and a group in which a hydrogen atom in these groups is substituted with a substituent such as an alkoxy group, an aryl group, or a fluorine atom.

A cycloalkyl group included in the “cycloalkoxy group” may be a monocyclic group or a polycyclic group. The cycloalkoxy group may have a substituent. The number of carbon atoms in the cycloalkoxy group is usually 3 to 30 and preferably 12 to 19 without including the number of carbon atoms in the substituent.

Examples of the cycloalkoxy group include cycloalkoxy groups having no substituent, such as a cyclopentyloxy group, a cyclohexyloxy group, and a cycloheptyloxy group, and a group in which a hydrogen atom in these groups is substituted with a substituent such as a fluorine atom or an alkyl group.

The number of carbon atoms in the “aryloxy group” is usually 6 to 60 and preferably 6 to 48 without including the number of carbon atoms in the substituent.

The aryloxy group may have a substituent. Examples of the aryloxy group include a phenoxy group, a 1-naphthyloxy group, a 2-naphthyloxy group, a 1-anthracenyloxy group, a 9-anthracenyloxy group, a 1-pyrenyloxy group, and a group in which a hydrogen atom in these groups is substituted with a substituent such as an alkyl group, an alkoxy group, or a fluorine atom.

The “alkylthio group” may have any of a linear shape, a branched shape, and a cyclic shape. The number of carbon atoms in a linear alkylthio group is usually 1 to 40 and preferably 1 to 10 without including the number of carbon atoms in the substituent. The number of carbon atoms in a branched or cyclic alkylthio group is usually 3 to 40 and preferably 4 to 10 without including the number of carbon atoms in the substituent.

The alkylthio group may have a substituent. Specific examples of the alkylthio group include a methylthio group, an ethylthio group, a propylthio group, an isopropylthio group, a butylthio group, an isobutylthio group, a tert-butylthio group, a pentylthio group, a hexylthio group, a cyclohexylthio group, a heptylthio group, an octylthio group, a 2-ethylhexylthio group, a nonylthio group, a decylthio group, a 3,7-dimethyloctylthio group, a laurylthio group, and a trifluoromethylthio group.

A cycloalkyl group included in the “cycloalkylthio group” may be a monocyclic group or a polycyclic group. The cycloalkylthio group may have a substituent. The number of carbon atoms in the cycloalkylthio group is usually 3 to 30 and preferably 12 to 19 without including the number of carbon atoms in the substituent.

Examples of a cycloalkylthio group which may have a substituent include a cyclohexylthio group.

The number of carbon atoms in the “arylthio group” is usually 6 to 60 and preferably 6 to 48 without including the number of carbon atoms in the substituent.

The arylthio group may have a substituent. Examples of the arylthio group include a phenylthio group, a C1 to C12 alkyloxyphenylthio group (C1 to C12 indicate that the number of carbon atoms in the group described immediately thereafter is 1 to 12, and the same applies to the following), a C1 to C12 alkylphenylthio group, a 1-naphthylthio group, a 2-naphthylthio group, and a pentafluorophenylthio group.

The “p-valent heterocyclic group” (p represents an integer of 1 or more) means a remaining atomic group obtained by removing p hydrogen atoms among hydrogen atoms directly bonded to carbon atoms or heteroatoms constituting a ring from a heterocyclic compound which may have a substituent.

The p-valent heterocyclic group may further have a substituent. The number of carbon atoms in the p-valent heterocyclic group is usually 2 to 30 and preferably 2 to 6 without including the number of carbon atoms in the substituent.

Examples of the substituent which may be included in the divalent aromatic heterocyclic group include a halogen atom, an alkyl group, an aryl group, an alkoxy group, an aryloxy group, an alkylthio group, an arylthio group, a monovalent heterocyclic group, a substituted amino group, an acyl group, an imine residue, an amide group, an acid imide group, a substituted oxycarbonyl group, an alkenyl group, an alkynyl group, a cyano group, and a nitro group. A “p-valent aromatic heterocyclic group” is included in the p-valent heterocyclic group.

The “p-valent aromatic heterocyclic group” means a remaining atomic group obtained by removing p hydrogen atoms among hydrogen atoms directly bonded to carbon atoms or heteroatoms constituting a ring from an aromatic heterocyclic compound which may have a substituent. The p-valent aromatic heterocyclic group may further have a substituent.

The aromatic heterocyclic compound includes a compound in which an aromatic ring is condensed to a heterocyclic ring even when the heterocyclic ring itself does not exhibit aromaticity, in addition to a compound in which a heterocyclic ring itself exhibits aromaticity.

Among the aromatic heterocyclic compounds, specific examples of the compound in which a heterocyclic ring itself exhibits aromaticity include oxadiazole, thiadiazole, thiazole, oxazole, thiophene, pyrrole, phosphole, furan, pyridine, pyrazine, pyrimidine, triazine, pyridazine, quinoline, isoquinoline, carbazole, and dibenzophosphole.

Among the aromatic heterocyclic compounds, specific examples of the compound in which an aromatic ring is condensed to a heterocyclic ring even when the aromatic heterocyclic ring itself does not exhibit aromaticity include phenoxazine, phenothiazine, dibenzoborole, dibenzosilole, and benzopyran.

The number of carbon atoms in the monovalent heterocyclic group is usually 2 to 60 and preferably 4 to 20 without including the number of carbon atoms in the substituent.

The monovalent heterocyclic group may have a substituent, and specific examples of the monovalent heterocyclic group include a thienyl group, a pyrrolyl group, a furyl group, a pyridyl group, a piperidyl group, a quinolyl group, an isoquinolyl group, a pyrimidinyl group, a triazinyl group, and a group in which a hydrogen atom in these groups is substituted with an alkyl group, an alkoxy group, or the like.

The “substituted amino group” means an amino group having a substituent. Examples of the substituent of the amino group include an alkyl group, an aryl group, and a monovalent heterocyclic group, and an alkyl group, an aryl group, or a monovalent heterocyclic group is preferable. The number of carbon atoms in the substituted amino group is usually 2 to 30.

Examples of the substituted amino group include a dialkylamino group such as a dimethylamino group or a diethylamino group; and a diarylamino group such as a diphenylamino group, a bis(4-methylphenyl)amino group, a bis(4-tert-butylphenyl)amino group, or a bis(3,5-di-tert-butylphenyl)amino group.

The “acyl group” may have a substituent. The number of carbon atoms in the acyl group is usually 2 to 20 and preferably 2 to 18 without including the number of carbon atoms in the substituent. Specific examples of the acyl group include an acetyl group, a propionyl group, a butyryl group, an isobutyryl group, a pivaloyl group, a benzoyl group, a trifluoroacetyl group, and a pentafluorobenzoyl group.

The “imine residue” means a remaining atomic group obtained by removing one hydrogen atom directly bonded to a carbon atom or a nitrogen atom constituting a carbon atom-nitrogen atom double bond from an imine compound. The “imine compound” means an organic compound having a carbon atom-nitrogen atom double bond in the molecule. Examples of the imine compound include aldimine, ketimine, and a compound in which a hydrogen atom bonded to a nitrogen atom constituting a carbon atom-nitrogen atom double bond in aldimine is substituted with an alkyl group or the like.

The number of carbon atoms in the imine residue is usually 2 to 20 and preferably 2 to 18. Examples of the imine residue include a group represented by the following structural formula.

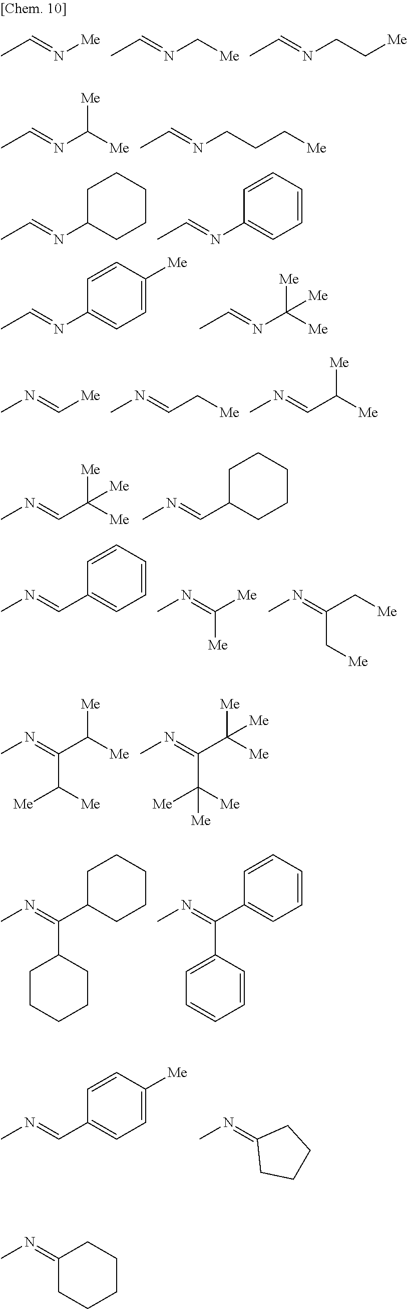

The “amide group” means a remaining atomic group obtained by removing one hydrogen atom bonded to a nitrogen atom from an amide. The number of carbon atoms in the amide group is usually 1 to 20 and preferably 1 to 18.

Specific examples of the amide group include a formamide group, an acetamide group, a propioamide group, a butyroamide group, a benzamide group, a trifluoroacetamide group, a pentafluorobenzamide group, a diformamide group, a diacetamide group, a dipropioamide group, a dibutyroamide group, a dibenzamide group, a ditrifluoroacetamide group, and a dipentafluorobenzamide group.

The “acid imide group” means a remaining atomic group obtained by removing one hydrogen atom bonded to a nitrogen atom from an acid imide. The number of carbon atoms in the acid imide group is usually 4 to 20. Specific examples of the acid imide group include a group represented by the following structural formula.

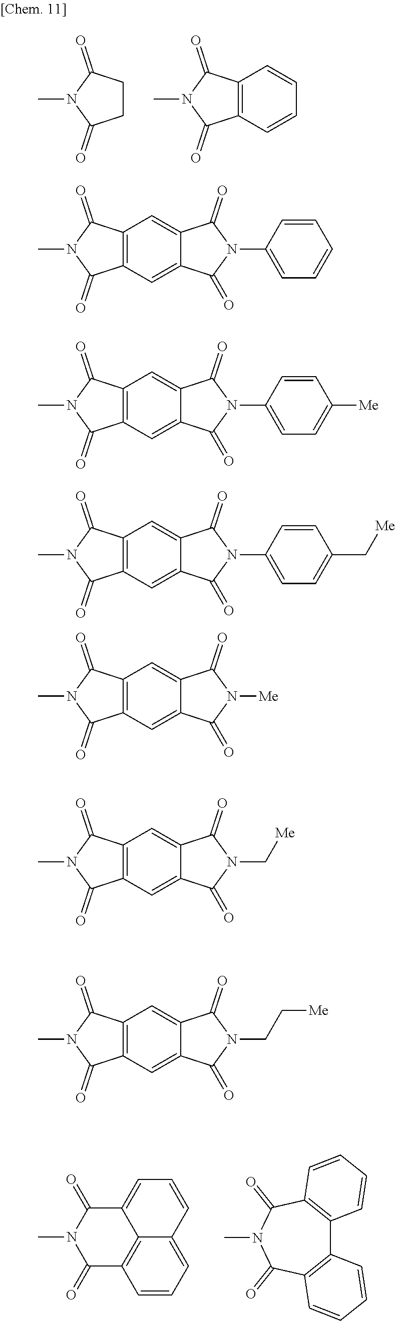

The “substituted oxycarbonyl group” means a group represented by R′—O—(C═O)—.

Here, R′ represents an alkyl group, an aryl group, an arylalkyl group, or a monovalent heterocyclic group.

The number of carbon atoms in the substituted oxycarbonyl group is usually 2 to 60 and preferably 2 to 48 without including the number of carbon atoms in the substituent.

Specific examples of the substituted oxycarbonyl group include a methoxycarbonyl group, an ethoxycarbonyl group, a propoxycarbonyl group, an isopropoxycarbonyl group, a butoxycarbonyl group, an isobutoxycarbonyl group, a tert-butyloxycarbonyl group, a pentyloxycarbonyl group, a hexyloxycarbonyl group, a cyclohexyloxycarbonyl group, a heptyloxycarbonyl group, an octyloxycarbonyl group, a 2-ethylhexyloxycarbonyl group, a nonyloxycarbonyl group, a decyloxycarbonyl group, a 3,7-dimethyloctyloxycarbonyl group, a dodecyloxycarbonyl group, a trifluoromethoxycarbonyl group, a pentafluoroethoxycarbonyl group, a perfluorobutoxycarbonyl group, a perfluorohexyloxycarbonyl group, a perfluorooctyloxycarbonyl group, a phenoxycarbonyl group, a naphthoxycarbonyl group, and a pyridyloxycarbonyl group.

The “alkenyl group” may have any of a linear shape, a branched shape, and a cyclic shape. The number of carbon atoms in a linear alkenyl group is usually 2 to 30 and preferably 3 to 20 without including the number of carbon atoms in the substituent. The number of carbon atoms in a branched or cyclic alkenyl group is usually 3 to 30 and preferably 4 to 20 without including the number of carbon atoms in the substituent.

The alkenyl group may have a substituent. Examples of the alkenyl group include a vinyl group, a 1-propenyl group, a 2-propenyl group, a 2-butenyl group, a 3-butenyl group, a 3-pentenyl group, a 4-pentenyl group, a 1-hexenyl group, a 5-hexenyl group, a 7-octenyl group, and a group in which a hydrogen atom in these groups is substituted with a substituent such as an alkoxy group, an aryl group, or a fluorine atom.

The “cycloalkenyl group” may be a monocyclic group or a polycyclic group. The cycloalkenyl group may have a substituent. The number of carbon atoms in the cycloalkenyl group is usually 3 to 30 and preferably 12 to 19 without including the number of carbon atoms in the substituent.

Examples of the cycloalkenyl group include cycloalkenyl groups having no substituent, such as a cyclohexenyl group, and a group in which a hydrogen atom in these groups is substituted with a substituent such as an alkyl group, an alkoxy group, an aryl group, or a fluorine atom.

Examples of a cycloalkenyl group having a substituent include a methylcyclohexenyl group and an ethylcyclohexenyl group.

The “alkynyl group” may have any of a linear shape, a branched shape, and a cyclic shape. The number of carbon atoms in a linear alkenyl group is usually 2 to 20 and preferably 3 to 20 without including the number of carbon atoms in the substituent. The number of carbon atoms in a branched or cyclic alkenyl group is usually 4 to 30 and preferably 4 to 20 without including the number of carbon atoms in the substituent.

The alkynyl group may have a substituent. Examples of the alkynyl group include an ethynyl group, a 1-propynyl group, a 2-propynyl group, a 2-butynyl group, a 3-butynyl group, a 3-pentynyl group, a 4-pentynyl group, a 1-hexynyl group, a 5-hexynyl group, and a group in which a hydrogen atom in these groups is substituted with a substituent such as an alkoxy group, an aryl group, or a fluorine atom.

The “cycloalkynyl group” may be a monocyclic group or a polycyclic group. The cycloalkynyl group may have a substituent. The number of carbon atoms in the cycloalkynyl group is usually 4 to 30 and preferably 12 to 19 without including the number of carbon atoms in the substituent.

Examples of the cycloalkynyl group include cycloalkynyl groups having no substituent, such as a cyclohexynyl group, and a group in which a hydrogen atom in these groups is substituted with a substituent such as an alkyl group, an alkoxy group, an aryl group, or a fluorine atom.

Examples of a cycloalkynyl group having a substituent include a methylcyclohexynyl group and an ethylcyclohexynyl group.

The “alkylsulfonyl group” may be linear or branched. The alkylsulfonyl group may have a substituent. The number of carbon atoms in the alkylsulfonyl group is usually 1 to 30 without including the number of carbon atoms in the substituent. Specific examples of the alkylsulfonyl group include a methylsulfonyl group, an ethylsulfonyl group, and a dodecylsulfonyl group.

The reference sign “*” attached to the chemical formula represents a bond.

The “n-conjugated system” means a system in which n electrons are delocalized to a plurality of bonds.

The “ink” means a liquid used in a coating method, and is not limited to a colored liquid. In addition, the “coating method” includes a method for forming a film (layer) using a liquid substance, and examples thereof include a slot die coating method, a slit coating method, a knife coating method, a spin coating method, a casting method, a micro-gravure coating method, a gravure coating method, a bar coating method, a roll coating method, a wire bar coating method, a dip coating method, a spray coating method, a screen printing method, a gravure printing method, a flexographic printing method, an offset printing method, an inkjet coating method, a dispenser printing method, a nozzle coating method, and a capillary coating method.

The ink may be a solution, or may be a dispersion such as an emulsion or a suspension.

The “absorption peak wavelength” is a parameter specified based on an absorption peak of an absorption spectrum measured in a predetermined wavelength range, and refers to a wavelength of an absorption peak having the largest absorbance among absorption peaks of the absorption spectrum.

The “external quantum efficiency” is also simply referred to as EQE, and refers to a value indicating the number of electrons that can be extracted to the outside of the photoelectric conversion element among the generated electrons with respect to the number of photons emitted to the photoelectric conversion element in terms of ratio (%).

1. Photoelectric Conversion Element

A photoelectric conversion element includes an anode, a cathode, and an active layer provided between the anode and the cathode,
the active layer contains at least one p-type semiconductor material and at least two n-type semiconductor materials, and
a dispersive energy Hansen solubility parameter δD(P) of the at least one p-type semiconductor material and a first dispersive energy Hansen solubility parameter δD(Ni) and a second dispersive energy Hansen solubility parameter δD(Nii) of the at least two n-type semiconductor materials satisfy the following requirements (i) and (ii):

2.1 MPa^{0.5}<|δD(P)−δD(Ni)|+|δD(Ni)−δD(Nii)|<4.0 MPa^{0.5} Requirement (i):

0.8 MPa^{0.5}<|δD(P)−δD(Ni)| and 0.2 MPa^{0.5}<|δD(Ni)−δD(Nii)| Requirement (ii):
in the requirements (i) and (ii),
δD(P) is a value calculated by the following Equation (1),

$$\begin{matrix}[ Math . 7 ] & \\ δ D ( P ) = \frac{1}{{\sum }_{b = 1}^{a} {w}_{b}} {\sum }_{b = 1}^{a} {w}_{b} δ D ( {P}_{b} ) & ( 1 )\end{matrix}$$

in Equation (1),
a is an integer of 1 or more and represents the number of types of the p-type semiconductor materials contained in the active layer,
b is an integer of 1 or more and represents the order of weight values of the p-type semiconductor materials contained in the active layer when the weight values are arranged in descending order,
W_{b} represents a weight of the p-type semiconductor material (P_{b}) whose weight order is b, the p-type semiconductor material being contained in the active layer, and
δD(P_{b}) represents a dispersive energy Hansen solubility parameter of the p-type semiconductor material (P_{b}), and
δD(Ni) and δD(Nii) are determined based on δD(N′) and δD(N″) calculated by the following Equations (2) and (3), respectively, and when a value of |δD(P)−δD(N′)| and a value of |δD(P)−δD(N″)| are compared, a dispersive energy Hansen solubility parameter with a smaller value is δD(Ni), and a dispersive energy Hansen solubility parameter with a larger value is δD(Nii), in which δD(N′) is a value of a material having the largest value of the dispersive energy Hansen solubility parameter (δD) among two or more materials in a case where the number of materials having the highest order is two or more when weight values are arranged in descending order,

[Math. 8]

δD(N′)=δD(N₁) (2)
in Equation (2),
δD(N₁) represents a dispersive energy Hansen solubility parameter of an n-type semiconductor material having the largest weight value contained in the active layer among the two or more n-type semiconductor materials,

$$\begin{matrix}[ Math . 9 ] & \\ δ D ( N ’ ’ ) = \frac{1}{{\sum }_{d = 2}^{c} {w}_{d}} {\sum }_{d = 2}^{c} {w}_{d} δ D ( {N}_{d} ) & ( 3 )\end{matrix}$$

in Equation (3),
c is an integer of 2 or more and represents the number of types of the n-type semiconductor materials contained in the active layer,
d is an integer of 1 or more and represents the order of weight values of the n-type semiconductor materials contained in the active layer when the weight values are arranged in descending order,
W_{d} represents a weight of the n-type semiconductor material (N_{d}) whose weight order is d, the n-type semiconductor material being contained in the active layer, and
δD(N_{d}) represents a dispersive energy Hansen solubility parameter of the n-type semiconductor material (N_{d}).

(Hansen Solubility Parameter)

Here, first, Hansen solubility parameters (HSP) used as an index relating to the photoelectric conversion element of the present embodiment and the semiconductor material contained in the active layer thereof will be described.

The Hansen solubility parameter (HSP) is a kind of solubility parameter, and is used for searching for a solvent in a polymer compound, examining solubility in the case of mixing a plurality of polymer compounds, designing formulation of additives, and the like.

The Hansen solubility parameter includes three components of a dispersion term (dispersive energy Hansen solubility parameter) 5D which can be an index of a dispersion force, a polarity term (polarization energy Hansen solubility parameter) δP which can be an index of a dipole-dipole force due to electrostatic interaction, and a hydrogen bond term (hydrogen bond energy Hansen solubility parameter) δH which can be an index of a hydrogen bond force due to a hydrogen bond, and these components can be expressed three-dimensionally.

As for the definitions and calculation methods of the Hansen solubility parameters, for example, Charles M. Hansen, Hansen Solubility Parameters: A Users Handbook and B, John, Solubility parameters: theory and application, The Book and paper group annual Vol. 3 are well known, and can be appropriately used in the present embodiment.

In addition, the Hansen solubility parameters (δD, δP, and δH) can be calculated based on the chemical structure of the compound using, for example, commercially available computer software such as Hansen Solubility Parameters in Practice (HSPiP).

As described above, the active layer according to the photoelectric conversion element of the present embodiment is an active layer having a bulk heterojunction type structure containing at least one p-type semiconductor material and at least two n-type semiconductor materials and having a phase separation structure.

In the case of the active layer having a bulk heterojunction type structure, from the viewpoint of forming a preferred phase separation structure, the compatibility between the p-type semiconductor material and the n-type semiconductor material is generally adjusted so as not to be increased. However, when the compatibility between the p-type semiconductor material and the n-type semiconductor material is low, the semiconductor materials may be aggregated or crystallized in the active layer, for example, during the heat treatment. As a result, the deterioration of the EQE and the increase in dark current occur. Therefore, the semiconductor materials need to be appropriately dispersed in the active layer. Therefore, in the present embodiment, the dispersive energy Hansen solubility parameter (δD) that can be used as an index of the dispersion force among the three components of the Hansen solubility parameter is used.

(Method for Calculating Hansen Solubility Parameter)

Here, a method for calculating the dispersive energy Hansen solubility parameter (δD) according to the present embodiment using computer software (for example, HSPiP) will be described.

First, the chemical structure of the semiconductor material (p-type semiconductor material or n-type semiconductor material) is determined. In a case where the specified chemical structure is complex or long and thus cannot be directly calculated by computer software, the following procedures [1] to [3] according to a general method are performed.
[1] First, the specified chemical structure of the semiconductor material is cut to be divided into a plurality of partial structures, and hydrogen atoms are added to each of bonds generated by the division to obtain a partial compound having the partial structure. In a case where the semiconductor material is a polymer compound having a plurality of structural units, the semiconductor material is divided for each structural unit or for each of two or more appropriate structural units. Here, in a case where the semiconductor material is a fullerene derivative, fullerene is restored, and a hydrogen atom is added to a bond of a functional group cut out from a fullerene skeleton.

Here, the position at which the semiconductor material is divided (cut) may be determined on the condition that (i) a carbon-carbon bond that does not form a ring structure (in a case where the semiconductor material is a fullerene derivative, it may be a plurality of bonds that are closest to the fullerene skeleton and that can be divided by cutting the functional group added to the fullerene skeleton), and (ii) the number of the partial structures to be cut by division is minimized (when there are multiple division methods that minimize the number of cut partial structures, among the cut partial structures, a division method in which a molecular weight of the partial structure having the smallest molecular weight is selected, and furthermore, when there are a plurality of division methods in which the number of cut partial structure is minimized and the molecular weight of the partial structure having the minimum molecular weight among the partial structures, a position at which the value of δD to be finally calculated becomes larger is selected).
[2] δD is calculated for each partial compound generated from the obtained partial structure. As δD of fullerene which is a partial structure of a fullerene derivative, a literature value is used.
[3] A value obtained by multiplying the calculated δD value for each partial compound by the weight (molecular weight) fraction of the partial compound in consideration of the number ratio is added, and the finally obtained value is taken as the dispersive energy Hansen solubility parameter (δD) of the semiconductor material before division.

(Requirement (i))

The active layer of the photoelectric conversion element according to the present embodiment contains at least one p-type semiconductor material and at least two n-type semiconductor materials (details of the p-type semiconductor material and the n-type semiconductor material will be described below).

In the present embodiment, a dispersive energy Hansen solubility parameter of the at least one p-type semiconductor material δD(P) and a first dispersive energy Hansen solubility parameter δD(Ni) and a second dispersive energy Hansen solubility parameter δD(Nii) of the at least two n-type semiconductor materials are selected so that a requirement (i): 2.1 MPa^{0.5}<|δD(P)−δD(Ni)|+|δD(Ni)−δD(Nii)|<4.0 MPa^{0.5} is satisfied.

In other words, the dispersive energy Hansen solubility parameter of the at least one p-type semiconductor material δD(P) and the first dispersive energy Hansen solubility parameter δD(Ni) and the second dispersive energy Hansen solubility parameter δD(Nii) of the at least two n-type semiconductor materials may be selected so that the sum value of the absolute value of the value obtained by subtracting the value of the first dispersive energy Hansen solubility parameter δD(Ni) of the n-type semiconductor material from the value of the dispersive energy Hansen solubility parameter δD(P) of the p-type semiconductor material and the absolute value of the value obtained by subtracting the value of the second dispersive energy Hansen solubility parameter δD(Nii) from the value of the first dispersive energy Hansen solubility parameter δD(Ni) is more than 2.1 MPa^{0.5} and less than 4.0 MPa^{0.5}.

The value of the parameter according to the requirement (i) is preferably 2.14 MPa^{0.5} or more, more preferably 2.5 MPa^{0.5} or more, and still more preferably 2.7 MPa^{0.5} or more, from the viewpoint of setting compatibility between the p-type semiconductor material and the n-type semiconductor material to a preferable state. The value of the parameter according to the requirement (i) is preferably 3.8 MPa^{0.5} or less, more preferably 3.4 MPa^{0.5} or less, and still more preferably 3.2 MPa^{0.5} or less, from the viewpoint of setting compatibility between the p-type semiconductor material and the n-type semiconductor material to a preferable state.

When at least one p-type semiconductor material and at least two n-type semiconductor materials are selected so as to satisfy the requirement (i), compatibility between the p-type semiconductor material and the n-type semiconductor material becomes preferable, and a preferred phase separation structure can be formed. Therefore, in particular, even when heating is performed at a heating temperature of 200° C. or higher, it is possible to suppress aggregation or crystallization of the n-type semiconductor material. As a result, the deterioration of the EQE can be suppressed, and the dark current can be reduced, thereby improving the heat resistance.

(Requirement (ii))

In the present embodiment, a dispersive energy Hansen solubility parameter of the at least one p-type semiconductor material δD(P) and a first dispersive energy Hansen solubility parameter δD(Ni) and a second dispersive energy Hansen solubility parameter δD(Nii) of the at least two n-type semiconductor materials are selected so that a requirement (ii): 0.8 MPa^{0.5}<|δD(P)−δD(Ni)| and 0.2 MPa^{0.5}<|δD(Ni)−δD(Nii)| is satisfied.

In other words, the dispersive energy Hansen solubility parameter of the at least one p-type semiconductor material δD(P) and the first dispersive energy Hansen solubility parameter δD(Ni) and the second dispersive energy Hansen solubility parameter δD(Nii) of the at least two n-type semiconductor materials may be selected so that the absolute value of the value obtained by subtracting the value of the first dispersive energy Hansen solubility parameter δD(Ni) of the n-type semiconductor material from the value of the dispersive energy Hansen solubility parameter of the p-type semiconductor material δD(P) is more than 0.8 MPa^{0.5}, and the absolute value of the value obtained by subtracting the value of the second dispersive energy Hansen solubility parameter δD(Nii) from the value of the first dispersive energy Hansen solubility parameter δD(Ni) of the n-type semiconductor material is more than 0.2 MPa^{0.5}.

The value of the parameter |δD(Ni)−δD(Nii)| according to the requirement (ii) is preferably 0.25 MPa^{0.5} or more, more preferably 0.30 MPa^{0.5} or more, and still more preferably 0.40 MPa^{0.5} or more. In addition, the value of the parameter |δD(P)−δD(Ni)| according to the requirement (ii) is preferably 0.95 MPa^{0.5} or more, more preferably 1.15 MPa^{0.5} or more, and still more preferably 1.30 MPa^{0.5} or more.

When at least one p-type semiconductor material and at least two n-type semiconductor materials are selected so as to satisfy the requirement (ii), compatibility between the p-type semiconductor material and the n-type semiconductor material, compatibility between the plurality of n-type semiconductor materials become preferable, and a preferred phase separation structure can be formed. Therefore, in particular, even when heating is performed at a heating temperature of 200° C. or higher, it is possible to suppress aggregation or crystallization of the n-type semiconductor material. As a result, the deterioration of the EQE can be suppressed, and the dark current can be reduced, thereby improving the heat resistance.

In the requirements (i) and (ii), when two or more p-type semiconductor materials are contained in the active layer, δD(P) may be a value calculated as follows by the following Equation (1).

$$\begin{matrix}[ Math . 10 ] & \\ δ D ( P ) = \frac{1}{{\sum }_{b = 1}^{a} {w}_{b}} {\sum }_{b = 1}^{a} {w}_{b} δ D ( {P}_{b} ) & ( 1 )\end{matrix}$$

In Equation (1), a is an integer of 1 or more and represents the number of types of the p-type semiconductor materials contained in the active layer, and b is an integer of 1 or more and represents the order of weight values of the p-type semiconductor materials contained in the active layer when the weight values are arranged in descending order, W_{b} represents a weight of the p-type semiconductor material (P_{b}) whose weight order is b, the p-type semiconductor material being contained in the active layer, and δD(P_{b}) represents a dispersive energy Hansen solubility parameter of the p-type semiconductor material (P_{b}).

In other words, δD(P) in a case where two or more p-type semiconductor materials are used is a sum of values obtained by multiplying the value of δD calculated for each of the contained p-type semiconductor materials by the weight fraction of each of the p-type semiconductor materials.

In the requirements (i) and (ii), in a case where two or more n-type semiconductor materials are contained in the active layer, δD(Ni) and δD(Nii) are determined based on δD(N′) and δD(N″) calculated by the following Equations (2) and (3), respectively, and when a value of |δD(P)−δD(N′)| and a value of |δD(P)−δD(N″)| are compared, a dispersive energy Hansen solubility parameter with a smaller value is δD(Ni), and a dispersive energy Hansen solubility parameter with a larger value is δD(Nii), in which δD(N′) is a value of a material having the largest value of the dispersive energy Hansen solubility parameter (δD) among two or more materials in a case where the number of materials having the highest order is two or more when weight values are arranged in descending order,

[Math. 11]

δD(N′)=δD(N₁) (2)

In Equation (2), δD(N₁) represents a dispersive energy Hansen solubility parameter of an n-type semiconductor material having the largest weight value contained in the active layer among the two or more n-type semiconductor materials.

$$\begin{matrix}[ Math . 12 ] & \\ δ D ( N ’ ’ ) = \frac{1}{{\sum }_{d = 2}^{c} {w}_{d}} {\sum }_{d = 2}^{c} {w}_{d} δ D ( {N}_{d} ) & ( 3 )\end{matrix}$$

In Equation (3), c is an integer of 2 or more and represents the number of types of the n-type semiconductor materials contained in the active layer, and d is an integer of 1 or more and represents the order of weight values of the n-type semiconductor materials contained in the active layer when the weight values are arranged in descending order, W_{d} represents a weight of the n-type semiconductor material (N_{d}) whose weight order is d, the n-type semiconductor material being contained in the active layer, and δD(N_{d}) represents a dispersive energy Hansen solubility parameter of the n-type semiconductor material (N_{d}).

In other words, as for the first dispersive energy Hansen solubility parameter δD(Ni) and the second dispersive energy Hansen solubility parameter δD(Nii) in a case where two or more n-type semiconductor materials are used, the dispersive energy Hansen solubility parameter of the n-type semiconductor material having the largest weight value contained in the active layer among the two or more n-type semiconductor materials is δD(N′), the sum of the value obtained by multiplying the value of δD calculated for each of the remaining n-type semiconductor materials contained in the active layer by the weight fraction of each of the remaining n-type semiconductor materials is δD(N″), and when the value of |δD(P)−δD(N′)| and the value of |δD(P)−δD(N″)| are compared, a dispersive energy Hansen solubility parameter with a smaller value is δD(Ni), and a dispersive energy Hansen solubility parameter with a larger value is δD(Nii).

According to the photoelectric conversion element of the present embodiment, the dispersive energy Hansen solubility parameter of the at least one p-type semiconductor material δD(P), and the first dispersive energy Hansen solubility parameter δD(Ni) and the second dispersive energy Hansen solubility parameter δD(Nii) of the at least two n-type semiconductor materials are set as described above, such that in particular, the aggregation or crystallization of the n-type semiconductor materials that occurs when heated at a heating temperature of 200° C. or higher can be suppressed, and as a result, in the heat treatment in the step of manufacturing the photoelectric conversion element, the step of incorporating the photoelectric conversion element in a device to which the photoelectric conversion element is applied, or the like, the deterioration of the EQE of the photoelectric conversion element can be suppressed, and the dark current can be reduced, thereby effectively improving the heat resistance.

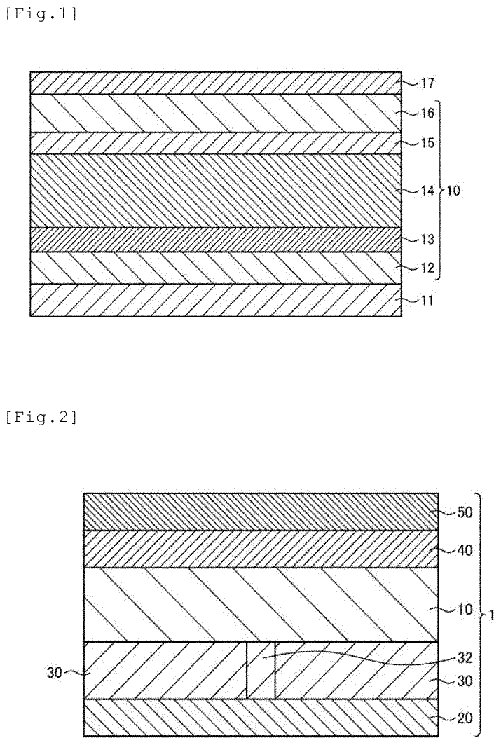

Here, a configuration example that can be taken by the photoelectric conversion element of the present embodiment will be described. FIG. 1 is a view schematically illustrating the configuration of the photoelectric conversion element of the present embodiment.

As illustrated in FIG. 1, a photoelectric conversion element 10 is provided on a support substrate 11. The photoelectric conversion element 10 includes an anode 12 provided so as to be in contact with the support substrate 11, a hole transport layer 13 provided so as to be in contact with the anode 12, an active layer 14 provided so as to be in contact with the hole transport layer 13, an electron transport layer 15 provided so as to be in contact with the active layer 14, and a cathode 16 provided so as to be in contact with the electron transport layer 15. In this configuration example, a sealing member 17 is further provided so as to be in contact with the cathode 16.

Hereinafter, constituent elements that can be included in the photoelectric conversion element of the present embodiment will be specifically described.

(Substrate)

The photoelectric conversion element is usually formed on a substrate (support substrate). In addition, there is also a case where sealing is performed by a substrate (sealing substrate). One of a pair of electrodes including an anode and a cathode is usually formed on the substrate. A material of the substrate is not particularly limited as long as it is a material that is not chemically changed particularly when a layer containing an organic compound is formed.

Examples of the material of the substrate include glass, plastic, a polymer film, and silicon. In a case where an opaque substrate is used, it is preferable that an electrode (in other words, the electrode provided on a side far from the opaque substrate) provided on an opposite side to an electrode provided on the opaque substrate is a transparent or translucent electrode.

(Electrode)

The photoelectric conversion element includes an anode and a cathode as a pair of electrodes. At least one electrode among the anode and the cathode is preferably a transparent or translucent electrode in order to allow light to be incident.

Examples of a material of the transparent or translucent electrode include a conductive metal oxide film and a translucent metal thin film. Specific examples of the material of the transparent or translucent electrode include indium oxide, zinc oxide, tin oxide, and a conductive material such as indium tin oxide (ITO), indium zinc oxide (IZO), or NESA, which is a composite thereof, gold, platinum, silver, and copper. As the material of the transparent or translucent electrode, ITO, IZO, or tin oxide is preferable. In addition, as the electrode, a transparent conductive film using an organic compound such as polyaniline and a derivative thereof, or polythiophene and a derivative thereof, as a material, may be used. The transparent or translucent electrode may be the anode or the cathode.

When one electrode of the pair of electrodes is transparent or translucent, the other electrode may be an electrode having low light transmittance. Examples of the material of the electrode having low light transmittance include a metal and a conductive polymer. Specific examples of a material of the electrode having low light transmittance include metals such as lithium, sodium, potassium, rubidium, cesium, magnesium, calcium, strontium, barium, aluminum, scandium, vanadium, zinc, yttrium, indium, cerium, samarium, europium, terbium, and ytterbium, and an alloy of two or more of these metals, an alloy of one or more of these metals and one or more metals selected from the group consisting of gold, silver, platinum, copper, manganese, titanium, cobalt, nickel, tungsten, and tin, graphite, a graphite interlayer compound, polyaniline and a derivative thereof, and polythiophene and a derivative thereof. Examples of the alloy include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

(Active Layer)

The active layer included in the photoelectric conversion element of the present embodiment has a bulk heterojunction type structure and contains a p-type semiconductor material and an n-type semiconductor material (details will be described below).

In the present embodiment, a thickness of the active layer is not particularly limited. The thickness of the active layer can be any suitable thickness in consideration of a balance between suppression of a dark current and extraction of a generated photocurrent. The thickness of the active layer is preferably 100 nm or more, more preferably 150 nm or more, and still more preferably 200 nm or more, particularly from the viewpoint of further reducing the dark current. In addition, the thickness of the active layer is preferably 10 μm or less, more preferably 5 μm or less, and still more preferably 1 μm or less.

Note that which of the p-type semiconductor material and the n-type semiconductor material functions in the active layer can be relatively determined from a HOMO energy level value or a LUMO energy level value of the selected compound (polymer). A relationship between an energy level value of each of a HOMO and a LUMO of the p-type semiconductor material contained in the active layer and an energy level value of each of a HOMO and a LUMO of the n-type semiconductor material contained in the active layer can be appropriately set within a range in which the photoelectric conversion element is operated.

In the present embodiment, the active layer is formed by a step including a heat treatment performed at a heating temperature of 200° C. or higher (details will be described below).

Here, a p-type semiconductor material (P) and an n-type semiconductor material suitable as materials of the active layer according to the present embodiment will be described.

(1) P-Type Semiconductor Material (P)

The p-type semiconductor material (P) is preferably a polymer compound having a predetermined weight average molecular weight in terms of polystyrene.

Here, the weight average molecular weight in terms of polystyrene means a weight average molecular weight calculated using gel permeation chromatography (GPC) and using a polystyrene standard sample.

The weight average molecular weight in terms of polystyrene of the p-type semiconductor material (P) is particularly preferably 3,000 or more and 500,000 or less from the viewpoint of improving solubility in a solvent.

In the present embodiment, the p-type semiconductor material (P) is preferably a n-conjugated polymer compound (also referred to as a D-A type conjugated polymer compound) having a donor structural unit (also referred to as a D structural unit) and an acceptor structural unit (also referred to as an A structural unit). Note that which one is the donor structural unit or the acceptor structural unit can be relatively determined from the energy level of the HOMO or the LUMO.

Here, the donor structural unit is a structural unit in which n electrons are excessive, and the acceptor structural unit is a structural unit in which n electrons are deficient.

In the present embodiment, the structural unit that can constitute the p-type semiconductor material (P) includes a structural unit in which a donor structural unit and an acceptor structural unit are directly bonded, and further includes a structural unit in which a donor structural unit and an acceptor structural unit are bonded via an arbitrary suitable spacer (a group or a structural unit).

Examples of the p-type semiconductor material (P) that is a polymer compound include polyvinylcarbazole and a derivative thereof, polysilane and a derivative thereof, a polysiloxane derivative having an aromatic amine structure in a side chain or a main chain, polyaniline and a derivative thereof, polythiophene and a derivative thereof, polypyrrole and a derivative thereof, polyphenylene vinylene and a derivative thereof, polythienylene vinylene and a derivative thereof, and polyfluorene and a derivative thereof.

The p-type semiconductor material (P) of the present embodiment is preferably a polymer compound having a structural unit represented by the following Formula (I). In the present embodiment, the structural unit represented by the following Formula (I) is usually a donor structural unit.

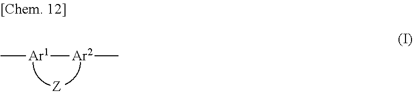

In Formula (I), Ar¹ and Ar² each independently represent a trivalent aromatic heterocyclic group which may have a substituent, and Z represents a group represented by any one of the following Formulas (Z-1) to (Z-7).

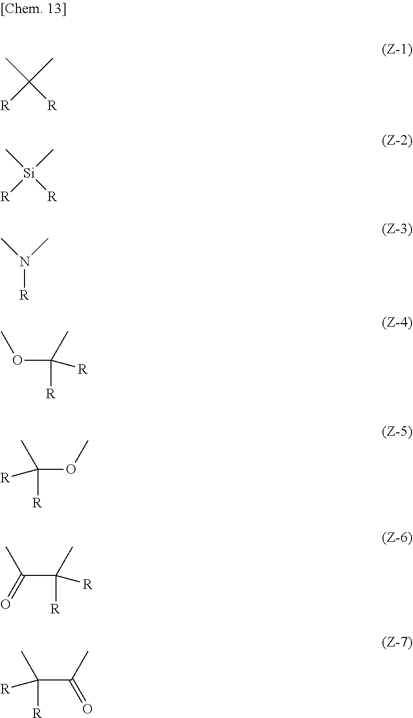

In Formulas (Z-1) to (Z-7), R represents a hydrogen atom, a halogen atom, an alkyl group which may have a substituent, an aryl group which may have a substituent, a cycloalkyl group which may have a substituent, an alkoxy group which may have a substituent, a cycloalkoxy group which may have a substituent, an aryloxy group which may have a substituent, an alkylthio group which may have a substituent, a cycloalkylthio group which may have a substituent, an arylthio group which may have a substituent, a monovalent heterocyclic group which may have a substituent, a substituted amino group which may have a substituent, an acyl group which may have a substituent, an imine residue which may have a substituent, an amide group which may have a substituent, an acid imide group which may have a substituent, a substituted oxycarbonyl group which may have a substituent, an alkenyl group which may have a substituent, a cycloalkenyl group which may have a substituent, an alkynyl group which may have a substituent, a cycloalkynyl group which may have a substituent, a cyano group, a nitro group, a group represented by —C(═O)—R^{a}, or a group represented by —SO₂—R^{b}. Here, R^{a} and R^{b} each independently represent a hydrogen atom, an alkyl group which may have a substituent, an aryl group which may have a substituent, an alkoxy group which may have a substituent, an aryloxy group which may have a substituent, or a monovalent heterocyclic group which may have a substituent. In each of Formulas (Z-1) to (Z-7), when the number of R′s is two, the two R′s may be the same as or different from each other.

The aromatic heterocyclic rings which may constitute Ar¹ and Ar² include a ring in which an aromatic ring is condensed to a heterocyclic ring even when the heterocyclic ring itself constituting the ring does not exhibit aromaticity, in addition to a monocyclic ring and a condensed ring in which a heterocyclic ring itself exhibits aromaticity.

Each of the aromatic heterocyclic rings which may constitute Ar¹ and Ar² may be a single ring or a condensed ring. In a case where the aromatic heterocyclic ring is a condensed ring, all of the rings constituting the condensed ring may be a condensed ring having aromaticity, or only some rings constituting the condensed ring may be a condensed ring having aromaticity.

In a case where these rings have a plurality of substituents, these substituents may be the same as or different from each other.

Specific examples of the aromatic carbocyclic rings which may constitute Ar¹ and Ar² include a benzene ring, a naphthalene ring, an anthracene ring, a tetracene ring, a pentacene ring, a pyrene ring, and a phenanthrene ring, a benzene ring and a naphthalene ring are preferable, a benzene ring and a naphthalene ring are more preferable, and a benzene ring is still more preferable. These rings may have a substituent.

Specific examples of the aromatic heterocyclic ring include ring structures having the compound described above as an aromatic heterocyclic compound, and include an oxadiazole ring, a thiadiazole ring, a thiazole ring, an oxazole ring, a thiophene ring, a pyrrole ring, a phosphole ring, a furan ring, a pyridine ring, a pyrazine ring, a pyrimidine ring, a triazine ring, a pyridazine ring, a quinoline ring, an isoquinoline ring, a carbazole ring, a dibenzophosphole ring, a phenoxazine ring, a phenothiazine ring, a dibenzoborole ring, a dibenzosilole ring, and a benzopyran ring. These rings may have a substituent.

The structural unit represented by Formula (I) is preferably a structural unit represented by the following Formula (II) or (III). In other words, the p-type semiconductor material (P) of the present embodiment is preferably a polymer compound having a structural unit represented by the following Formula (II) or (III).

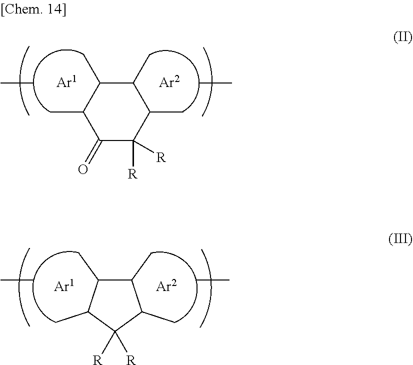

In Formulas (II) and (III), Ar¹, Ar², and R are as defined above.

Preferred examples of the structural units represented by Formulas (I) and (III) include structural units represented by the following Formulas (097) to (100).

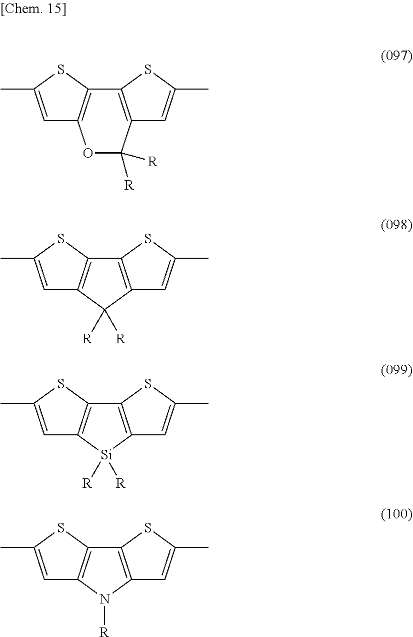

In Formulas (097) to (100), R is as defined above. When the number of R's is two, the two R's may be the same as or different from each other.

In addition, the structural unit represented by Formula (II) is preferably a structural unit represented by the following Formula (IV). In other words, the p-type semiconductor material (P) of the present embodiment is preferably a polymer compound having a structural unit represented by the following Formula (IV).

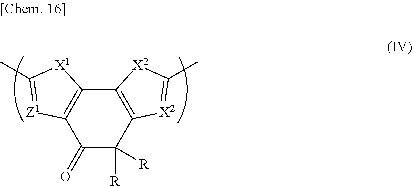

In Formula (IV), X¹ and X² are each independently a sulfur atom or an oxygen atom, Z¹ and Z² are each independently a group represented by ═C(R)— or a nitrogen atom, and R is as defined above.

The structural unit represented by Formula (IV) is preferably a structural unit in which each of X¹ and X² is a sulfur atom and each of Z¹ and Z² is a group represented by ═C(R)—.

Examples of a preferred structural unit represented by Formula (IV) include structural units represented by the following Formulas (IV-1) to (IV-16).

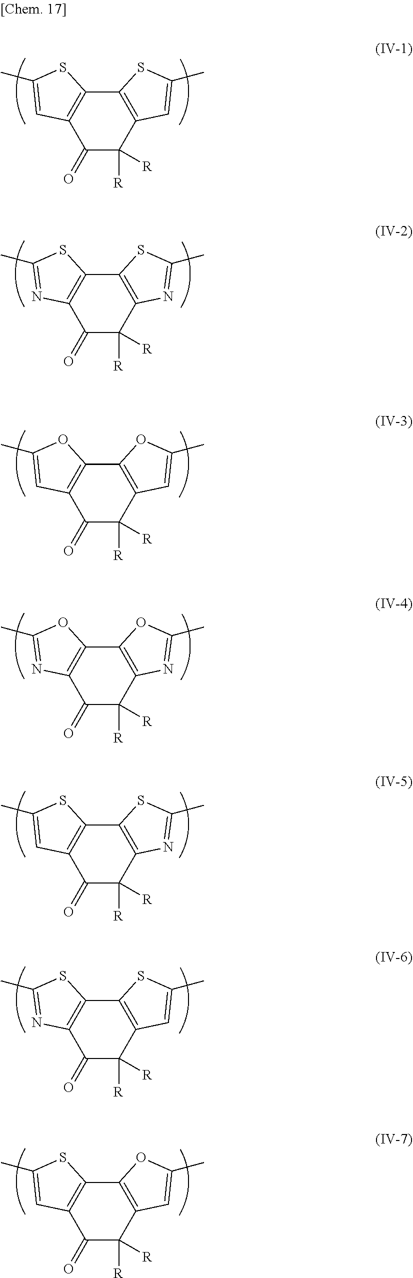

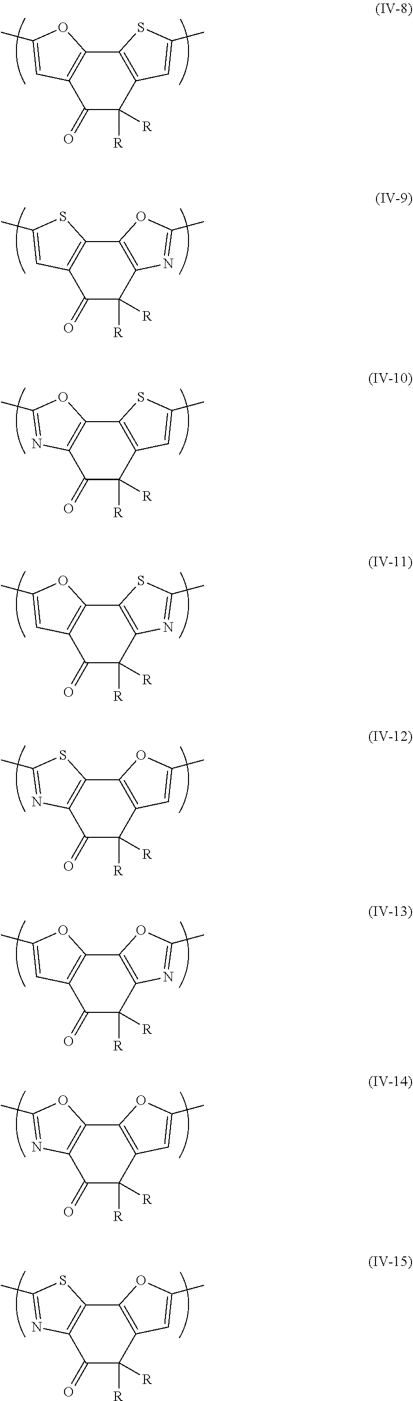

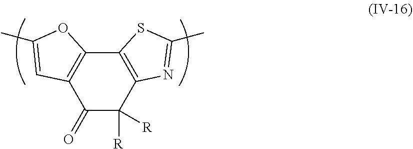

The structural unit represented by Formula (IV) is preferably a structural unit in which each of X² and X² is a sulfur atom and each of Z¹ and Z² is a group represented by ═C(R)—.

The polymer compound, which is the p-type semiconductor material (P) of the present embodiment, is preferably a polymer compound having a structural unit represented by the following Formula (V). In the present embodiment, the structural unit represented by the following Formula (V) is usually an acceptor structural unit.

[Chem. 18]

—Ar³— (V)

In Formula (V), Ar³ represents a divalent aromatic heterocyclic group.

The number of carbon atoms in the divalent aromatic heterocyclic group represented by Ar³ is usually 2 to 60, preferably 4 to 60, and more preferably 4 to 20. The divalent aromatic heterocyclic group represented by Ar³ may have a substituent. Examples of the substituent which may be included in the divalent aromatic heterocyclic group represented by Ar³ include a halogen atom, an alkyl group which may have a substituent, an aryl group which may have a substituent, an alkoxy group which may have a substituent, an aryloxy group which may have a substituent, an alkylthio group which may have a substituent, an arylthio group which may have a substituent, a monovalent heterocyclic group which may have a substituent, a substituted amino group which may have a substituent, an acyl group which may have a substituent, an imine residue which may have a substituent, an amide group which may have a substituent, an acid imide group which may have a substituent, a substituted oxycarbonyl group which may have a substituent, an alkenyl group which may have a substituent, an alkynyl group which may have a substituent, a cyano group, and a nitro group.

The structural unit represented by Formula (V) is preferably structural units represented by the following Formulas (V-1) to (V-8).

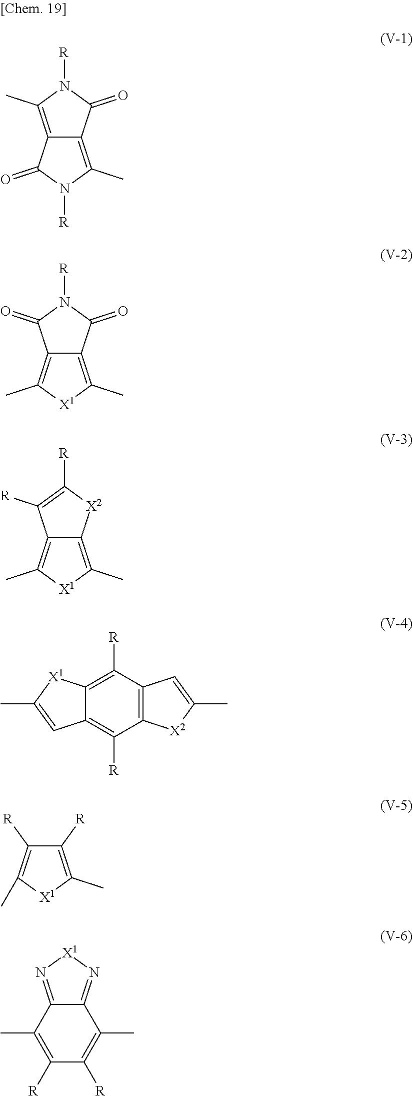

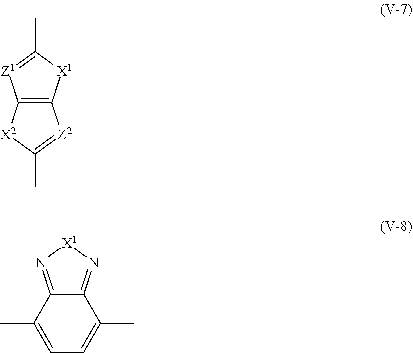

In Formulas (V-1) to (V-8), X¹, X², Z¹, Z², and R are as defined above. When the number of R's is two, the two R's may be the same as or different from each other.

Both X² and X² in Formulas (V-1) to (V-8) are preferably sulfur atoms from the viewpoint of availability of a raw material compound.

The p-type semiconductor material is preferably a n-conjugated polymer compound having a structural unit containing a thiophene skeleton and having a π-conjugated system.

Specific examples of the divalent aromatic heterocyclic group represented by Ar³ include groups represented by the following Formulas (101) to (190).

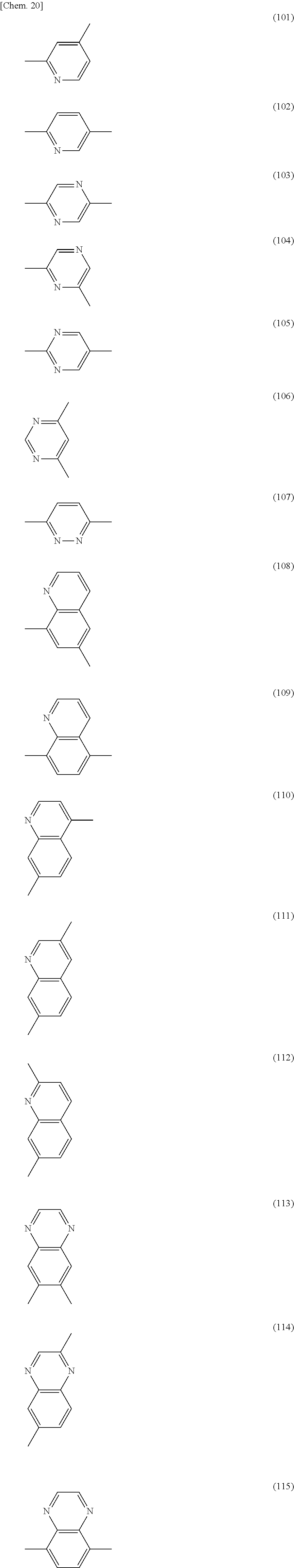

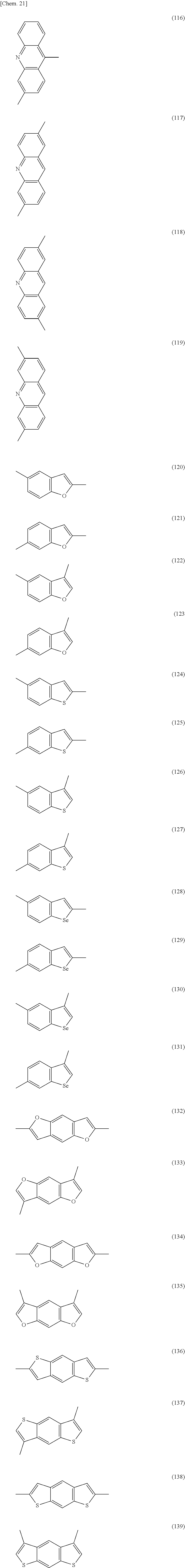

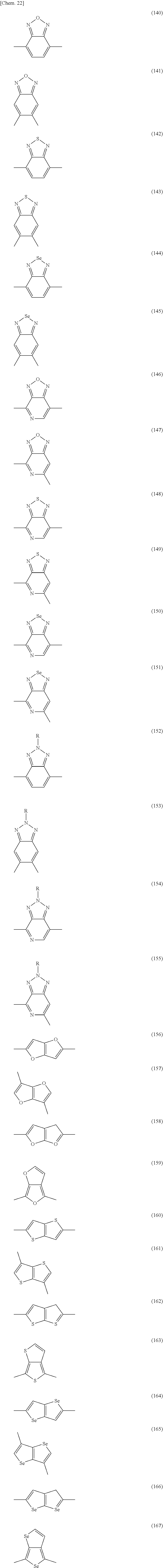

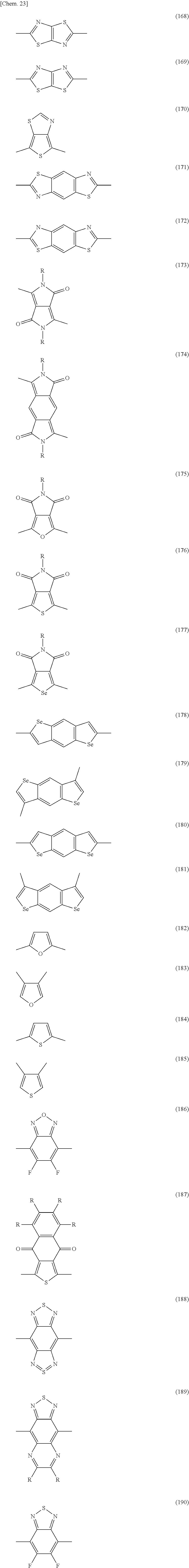

In Formulas (101) to (190), R is the same as described above. In a case where the number of R's is plural, the plurality of R's may be the same as or different from each other.

The polymer compound, which is the p-type semiconductor material (P) of the present embodiment, is preferably a n-conjugated polymer compound having a structural unit represented by Formula (I) as a donor structural unit and having a structural unit represented by Formula (V) as an acceptor structural unit.

The polymer compound, which is a p-type semiconductor material (P), may have two or more structural units of Formula (I) or two or more structural units of Formula (V).

For example, the polymer compound, which is the p-type semiconductor material (P) of the present invention, may have a structural unit represented by the following Formula (VI) from the viewpoint of improving solubility in a solvent.

[Chem. 24]

—Ar⁴— (VI)

In Formula (VI), Ar⁴ represents an arylene group.

The arylene group represented by Ar⁴ means a remaining atomic group obtained by removing two hydrogen atoms from an aromatic hydrocarbon which may have a substituent. The aromatic hydrocarbon also includes a compound having a condensed ring, and a compound in which two or more selected from the group consisting of an independent benzene ring and a condensed ring are bonded directly or via a divalent group such as a vinylene group.

Examples of the substituent which may be included in the aromatic hydrocarbon include the same substituents as in the above examples described as the substituent which may be included in the heterocyclic compound.

The number of carbon atoms in the arylene group represented by Ar⁴ is usually 6 to 60 and preferably 6 to 20 without including the number of carbon atoms in the substituent. The number of carbon atoms in the arylene group having the substituent is usually 6 to 100.

Examples of the arylene group represented by Ar⁴ include phenylene groups (for example, the following Formulas 1 to 3), naphthalene-diyl groups (for example, the following Formulas 4 to 13), anthracene-diyl groups (for example, the following Formulas 14 to 19), biphenyl-diyl groups (for example, the following Formulas 20 to 25), terphenyl-diyl groups (for example, the following Formulas 26 to 28), condensed ring compound groups (for example, the following Formulas 29 to 35), fluorene-diyl groups (for example, the following Formulas 36 to 38), and benzofluorene-diyl groups (for example, the following Formulas 39 to 46).

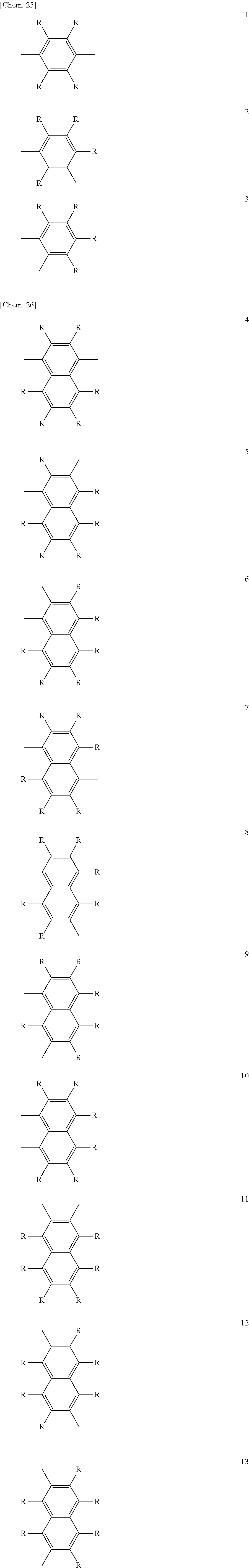

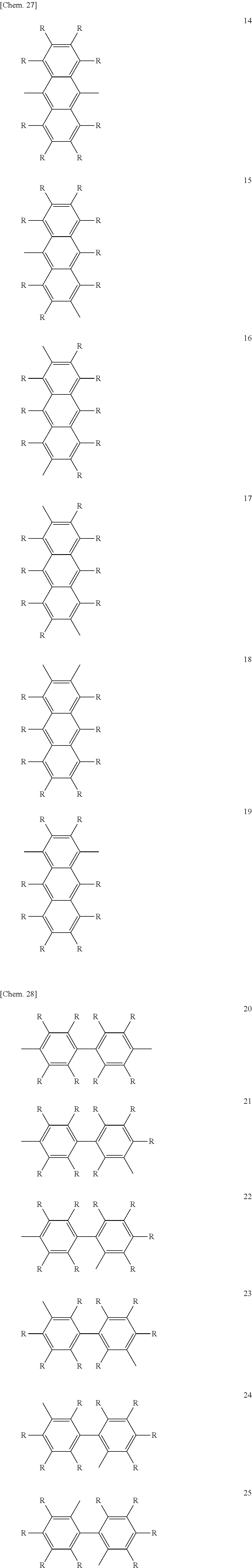

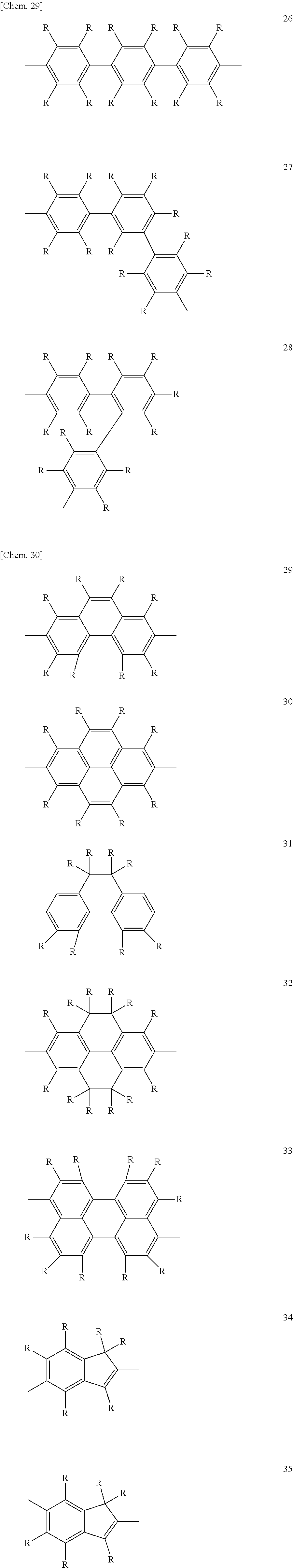

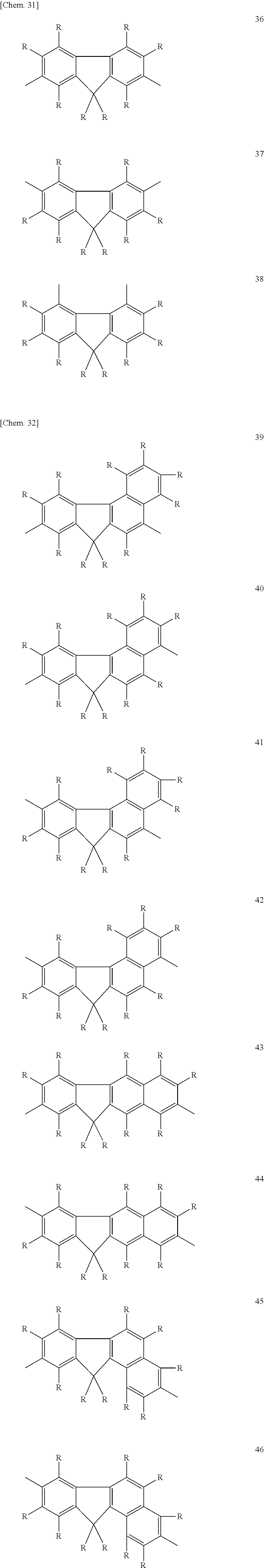

In the formulas, R is as defined above. The plurality of R's may be the same as or different from each other.

The structural unit represented by Formula (VI) is preferably a structural unit represented by the following Formula (VII).

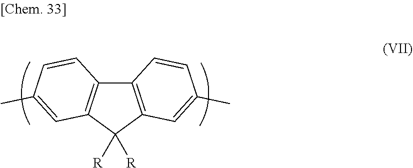

In Formula (VII), R is as defined above. Two R's may be the same as or different from each other.

The structural unit constituting the polymer compound that is the p-type semiconductor material (P) may be a structural unit in which two or more structural units selected from the structural units described above are combined and connected.

In a case where the polymer compound as a p-type semiconductor material (P) contains a structural unit represented by Formula (I) and/or a structural unit represented by Formula (V), when the amount of all the structural units contained in the polymer compound is 100 mol %, the total amount of the structural unit represented by Formula (I) and/or the structural unit represented by Formula (V) is usually 20 to 100 mol %, and preferably 40 to 100 mol % and still more preferably 50 to 100 mol % because charge transportability as the p-type semiconductor material (P) is improved.

Specific examples of the polymer compound, which is the p-type semiconductor material (P) of the present embodiment, include polymer compounds represented by the following Formulas (P-1) to (P-12).

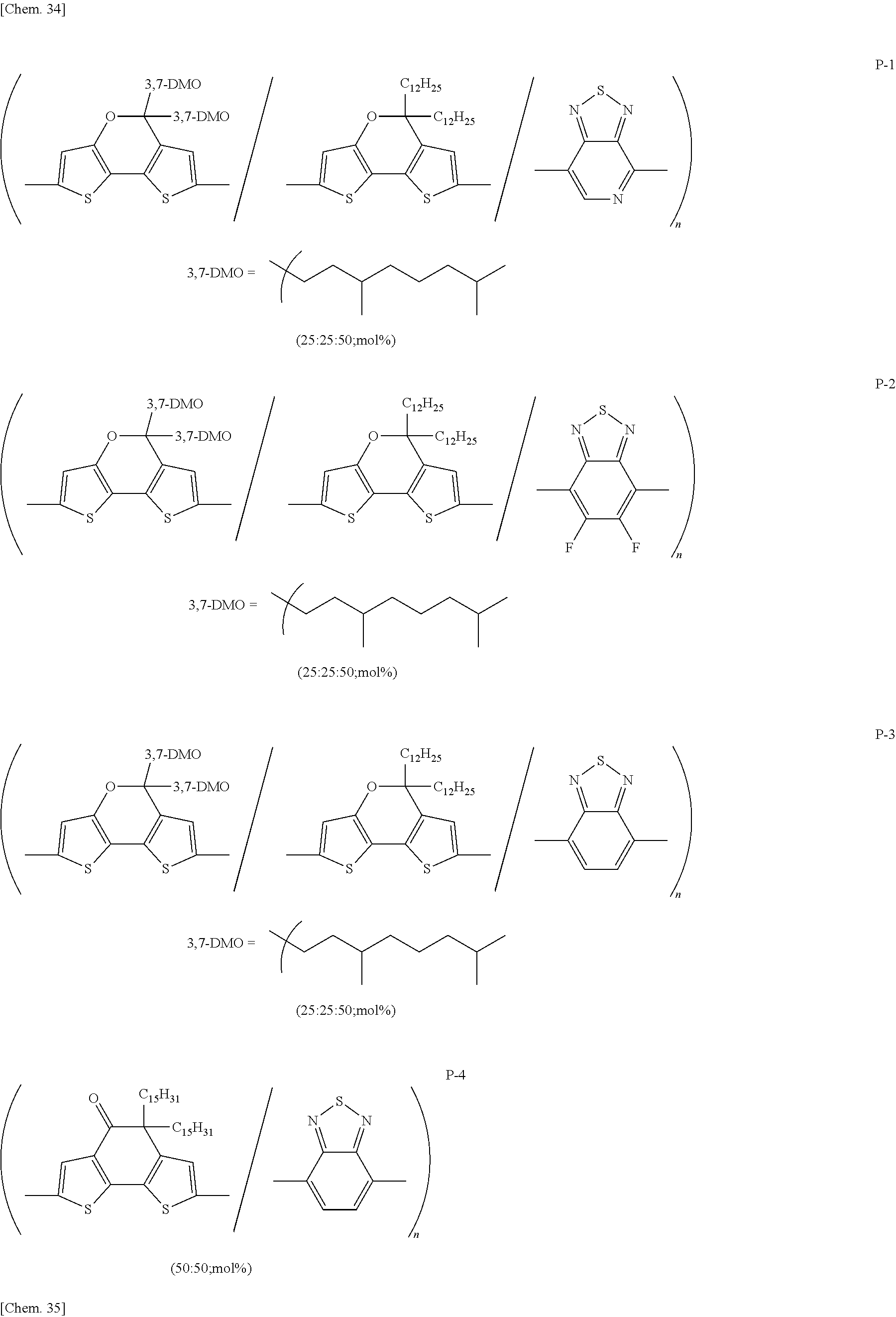

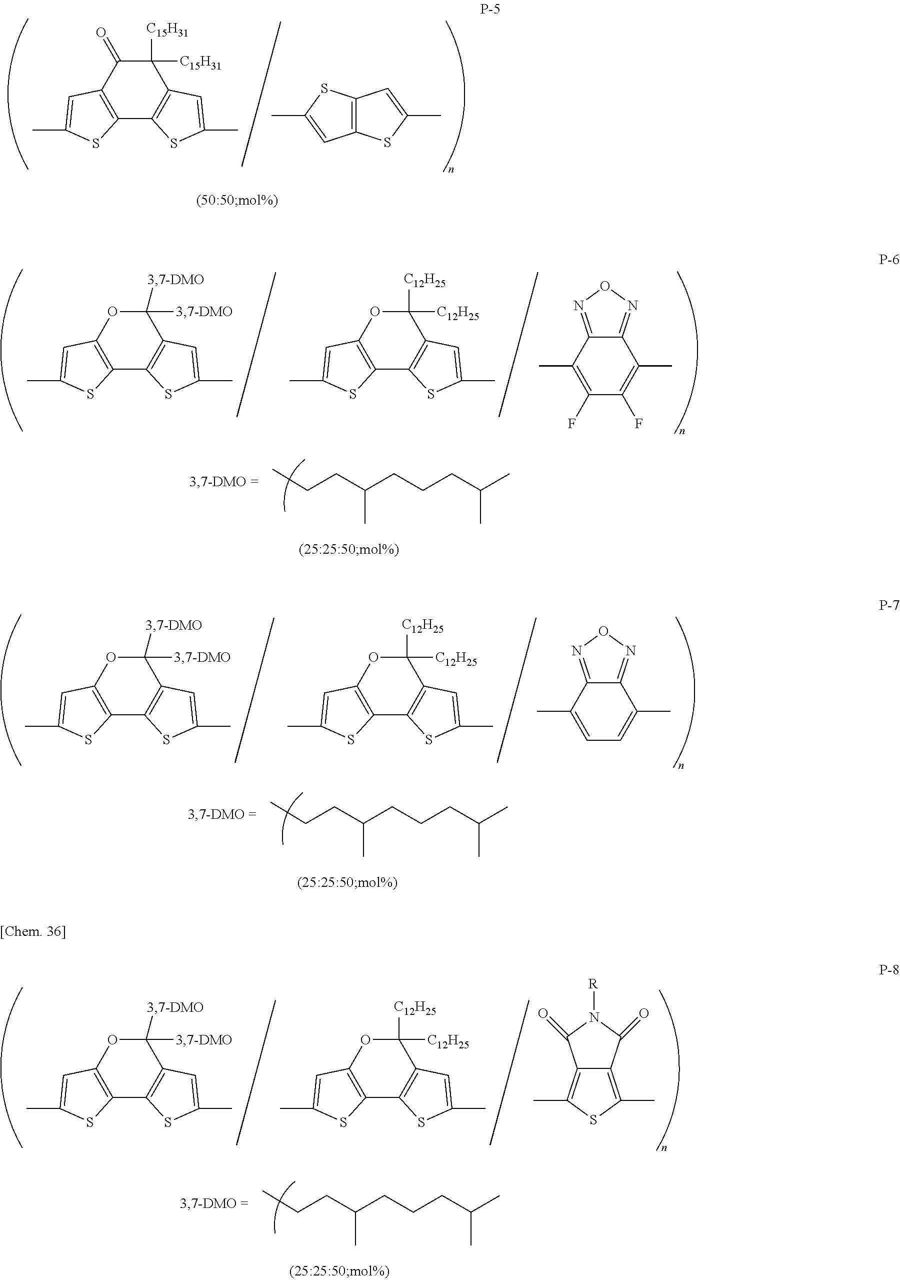

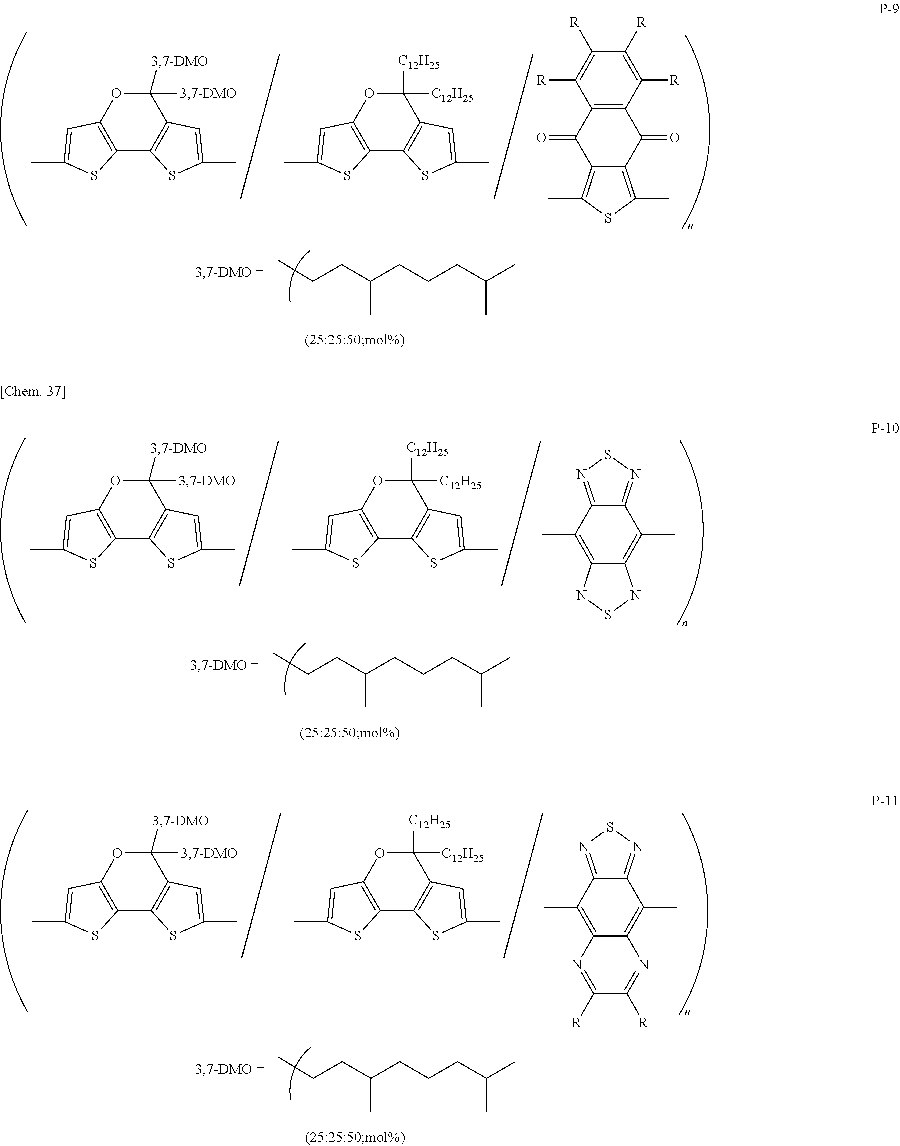

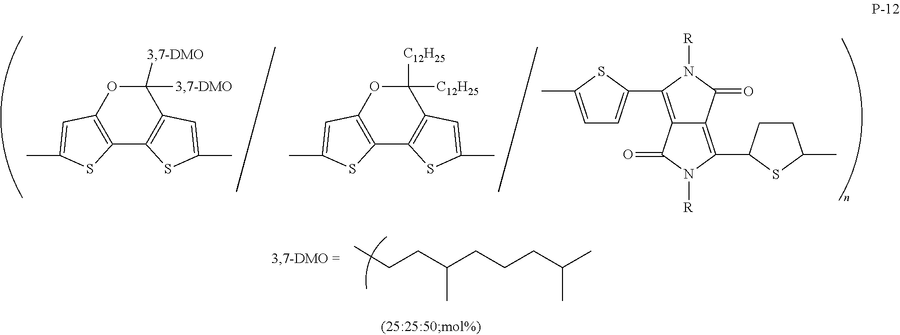

In the formulas, R is as defined above. The plurality of R's may be the same as or different from each other.

Among the specific examples of the polymer compound that is a p-type semiconductor material (P), from the viewpoint of suppressing the deterioration of the EQE or further improving the EQE, further suppressing an increase in dark current or further reducing the dark current to improve a balance thereof, and improving the heat resistance, it is preferable to use the polymer compounds represented by Formulas P-1 to P-5.

(2) N-Type Semiconductor Material

The n-type semiconductor material of the present embodiment may be a low-molecular-weight compound or a polymer compound.

Examples of the n-type semiconductor material that is a low-molecular-weight compound include an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, diphenyldicyanoethylene and a derivative thereof, a diphenoquinone derivative, a metal complex of 8-hydroxyquinoline and a derivative thereof, and a phenanthrene derivative such as bathocuproine.

Examples of the n-type semiconductor material that is a polymer compound include polyvinylcarbazole and a derivative thereof, polysilane and a derivative thereof, a polysiloxane derivative having an aromatic amine structure in a side chain or a main chain, polyaniline and a derivative thereof, polythiophene and a derivative thereof, polypyrrole and a derivative thereof, polyphenylene vinylene and a derivative thereof, polythienylene vinylene and a derivative thereof, polyquinoline and a derivative thereof, polyquinoxaline and a derivative thereof, and polyfluorene and a derivative thereof.

The active layer of the photoelectric conversion element according to the present embodiment can contain a non-fullerene compound as an n-type semiconductor material. Hereinafter, the n-type semiconductor material that can be contained in the active layer of the present embodiment will be described.

(i) Non-Fullerene Compound

The non-fullerene compound refers to a compound that is neither fullerene nor a fullerene derivative. As the non-fullerene compound, many compounds are known, and a commercially available non-fullerene compound can be used.

The non-fullerene compound, which is the n-type semiconductor material of the present embodiment, is preferably a compound containing a moiety DP having an electron donating property and a moiety AP having an electron accepting property.

The non-fullerene compound containing a moiety DP and a moiety AP more preferably contains one or more pairs of atoms in which the moieties DP in the non-fullerene compound are n-bonded to each other.

A moiety that does not have any of a ketone structure, a sulfoxide structure, and a sulfone structure in such a non-fullerene compound can be a moiety DP. Examples of the moiety AP include a moiety having a ketone structure.

The non-fullerene compound, which is the n-type semiconductor material of the present embodiment, is preferably a compound having a perylene tetracarboxylic acid diimide structure. Examples of the compound that is a non-fullerene compound and has a perylene tetracarboxylic acid diimide structure include compounds represented by the following formulas.

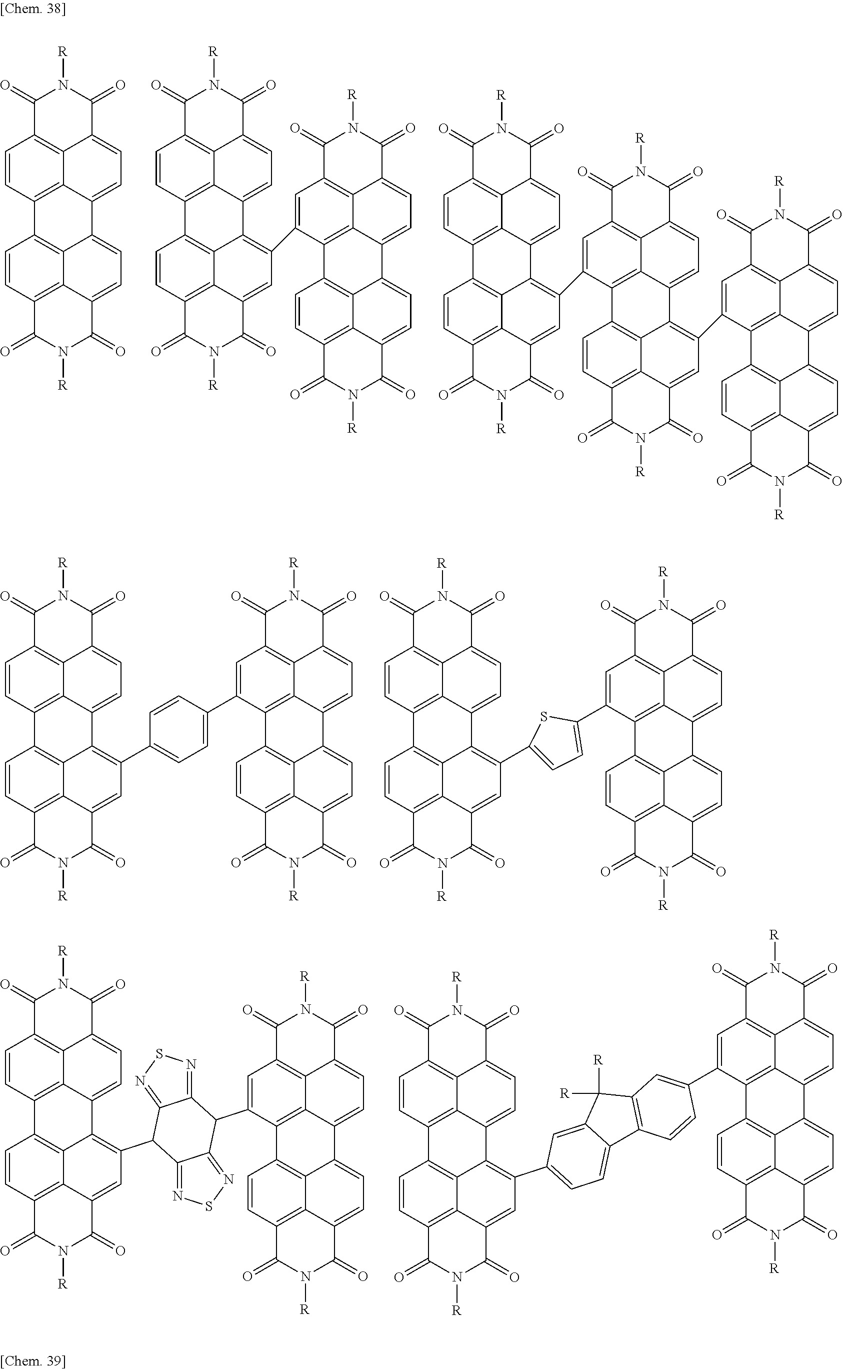

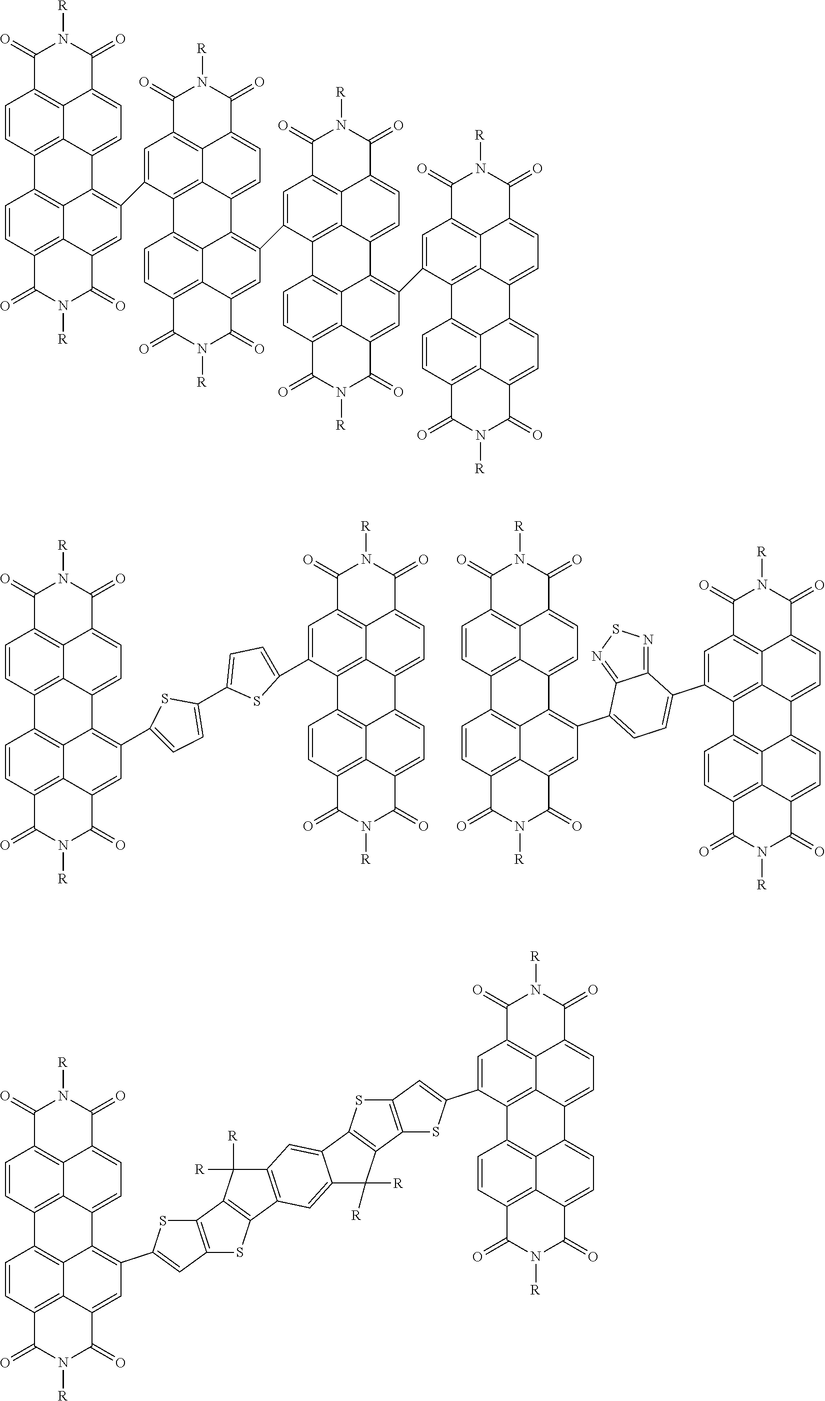

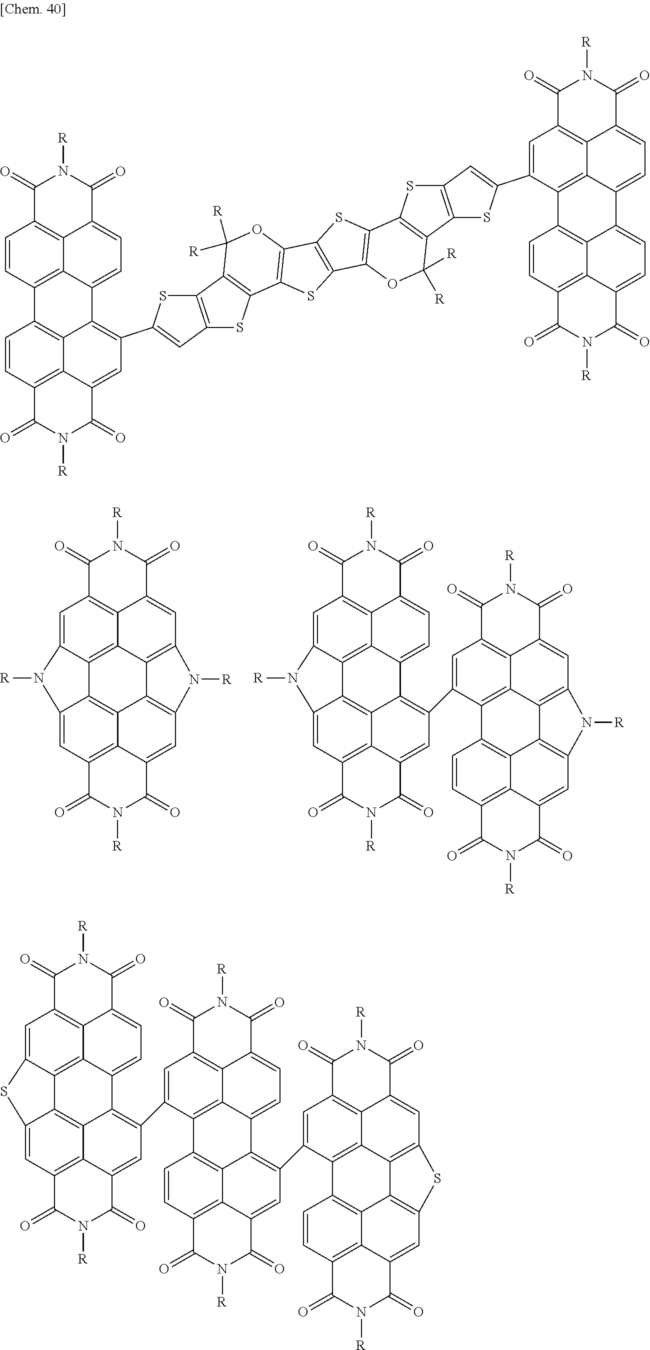

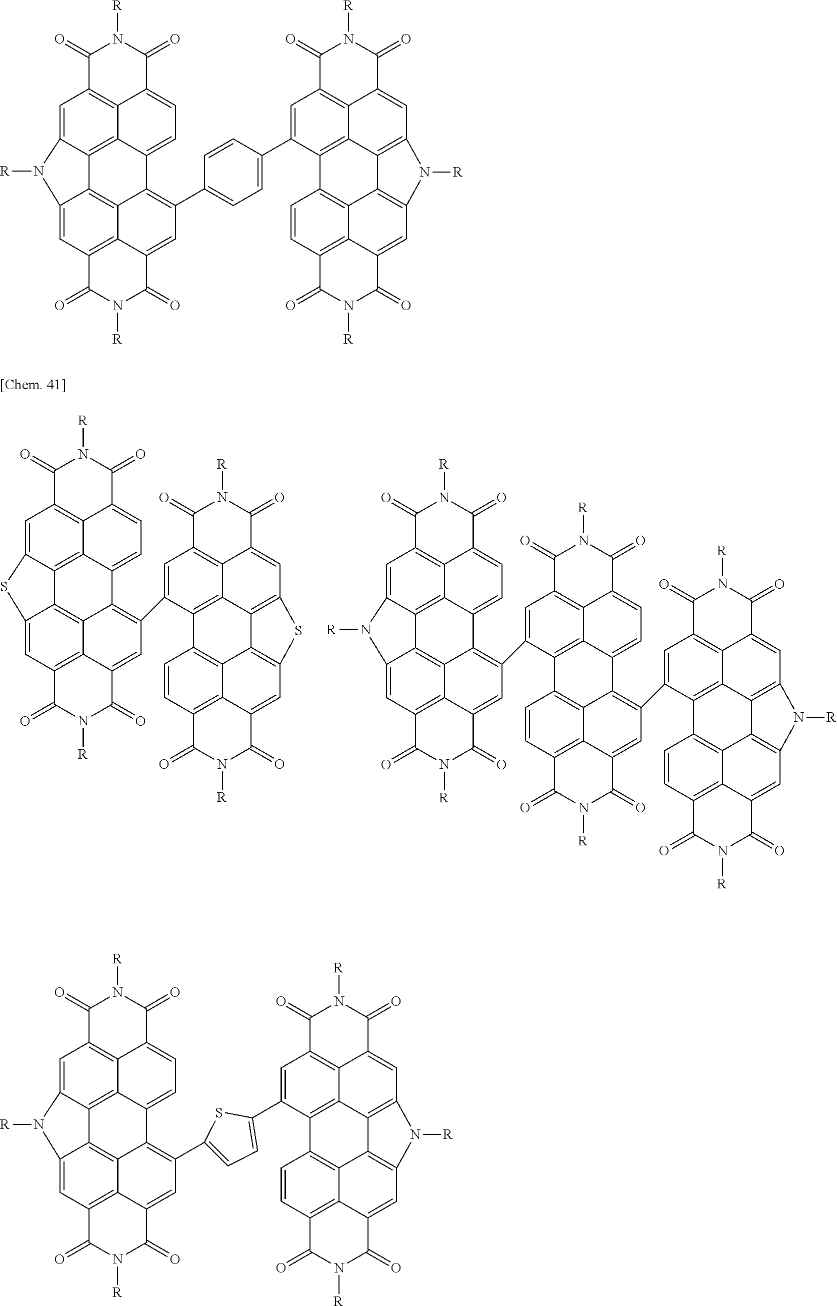

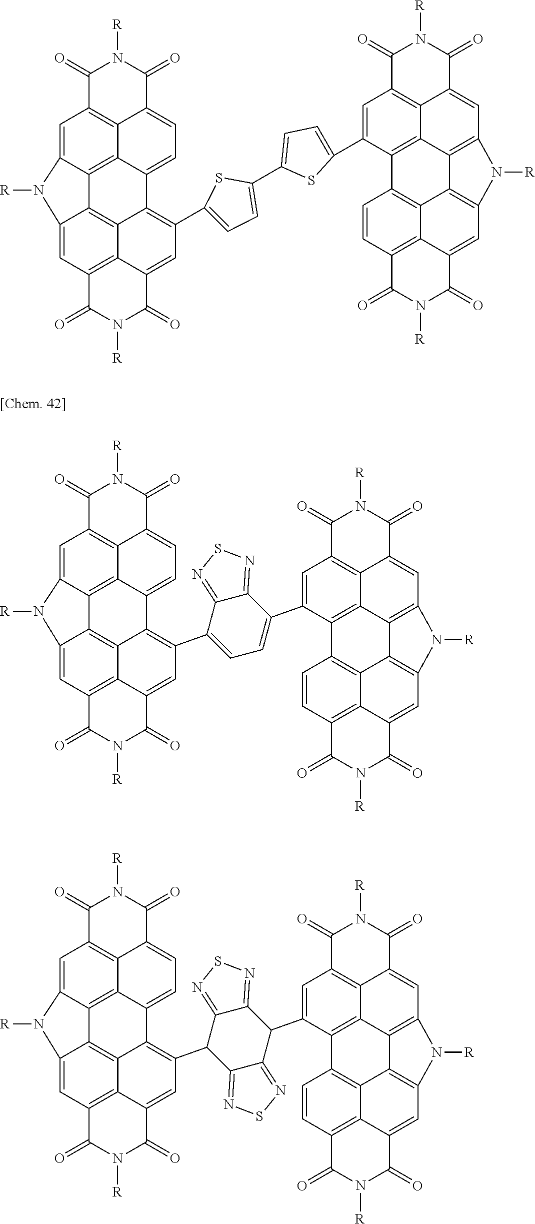

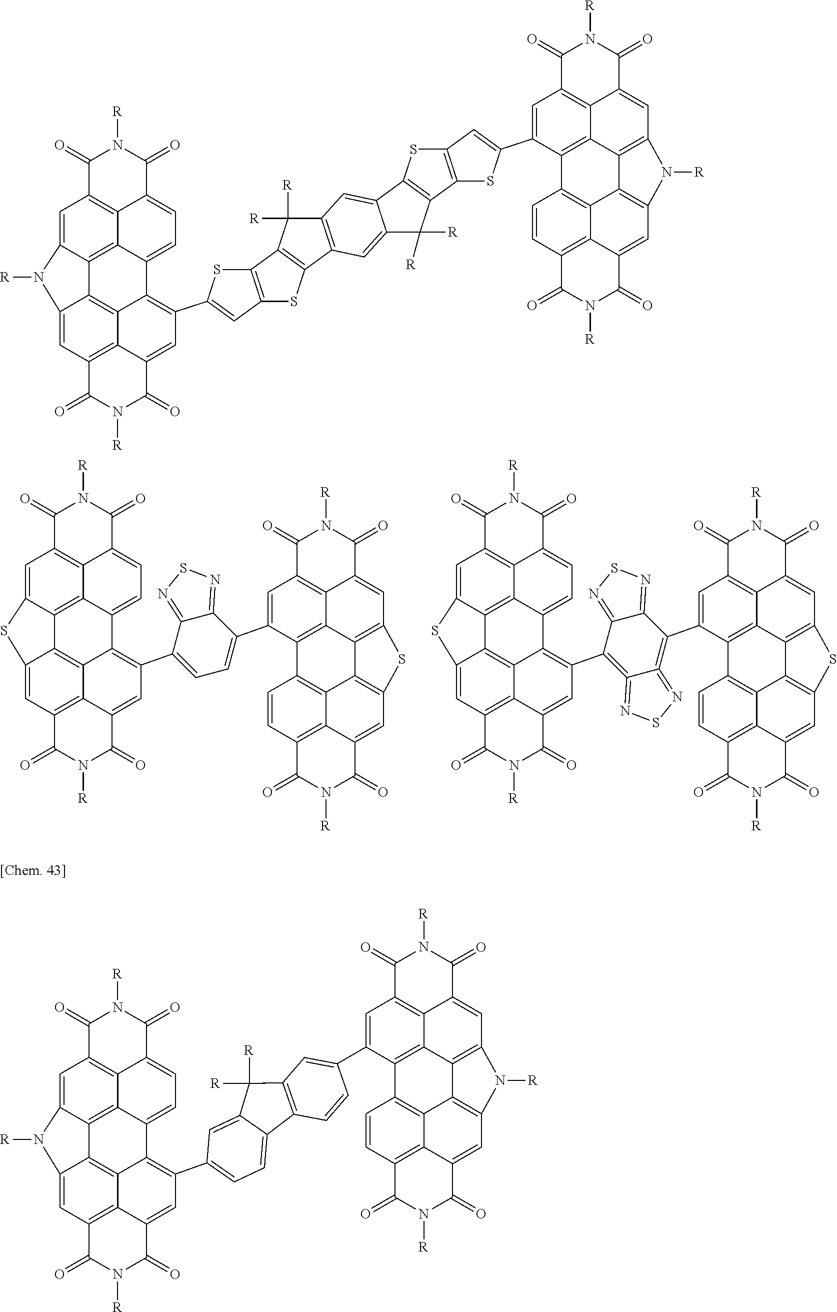

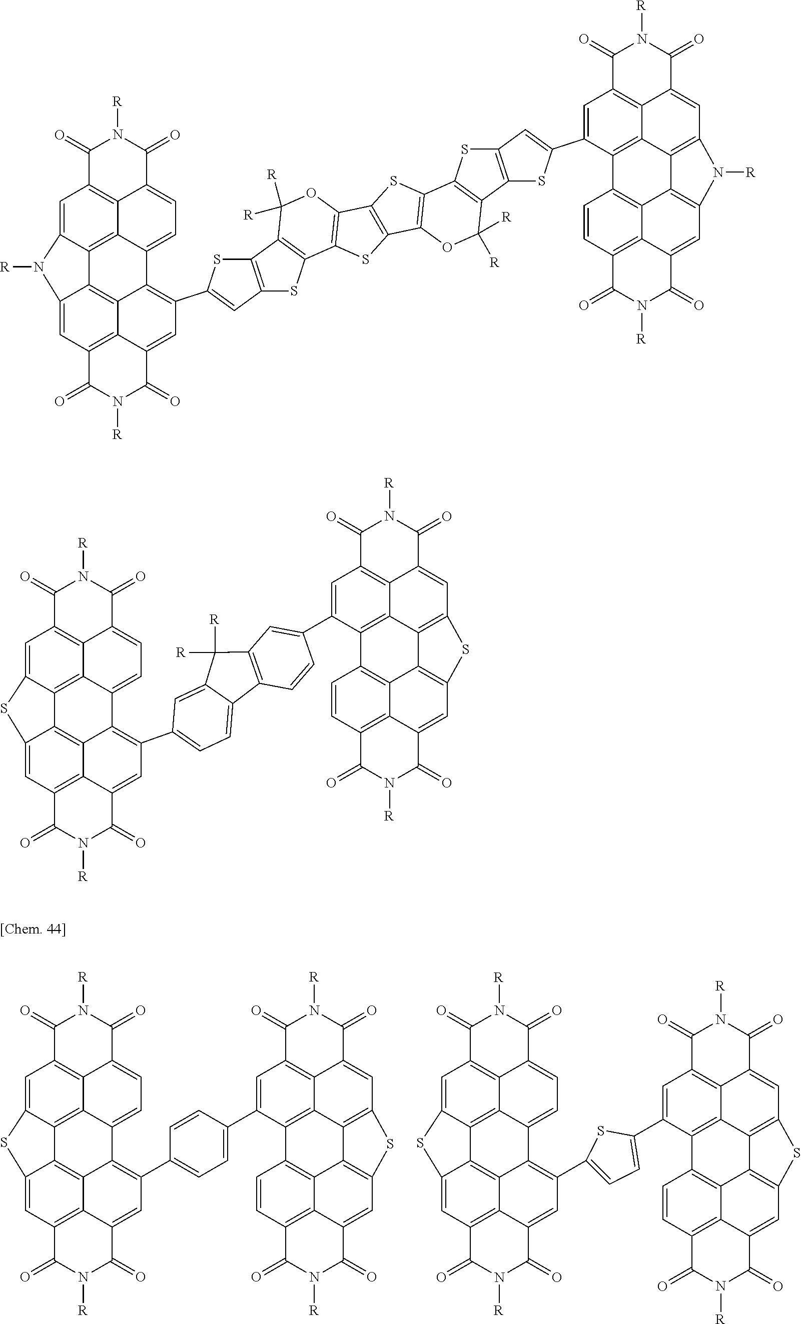

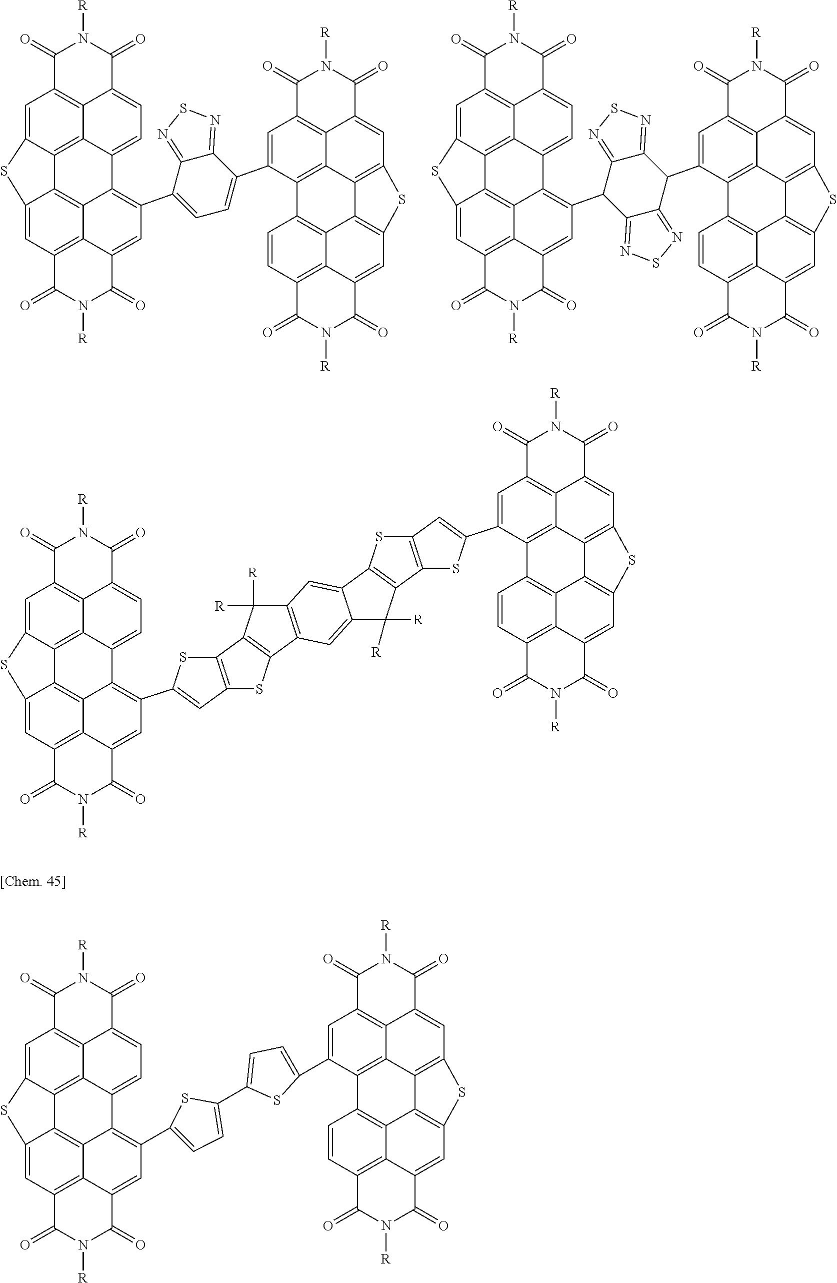

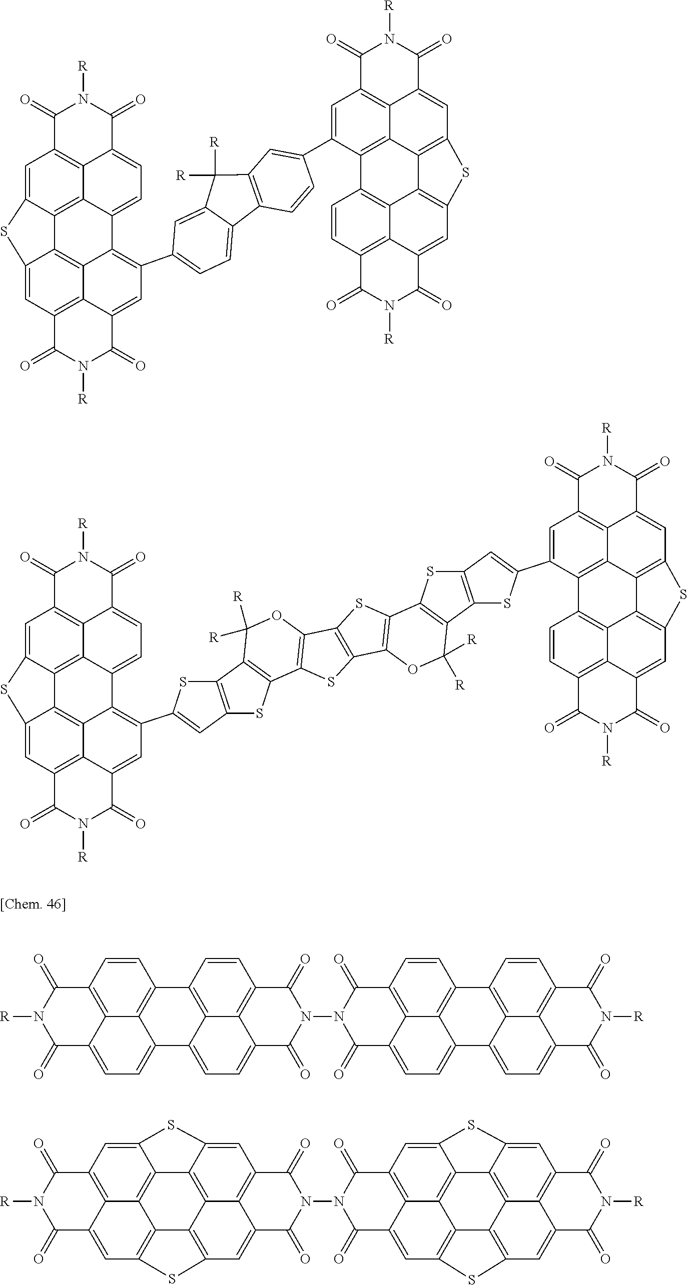

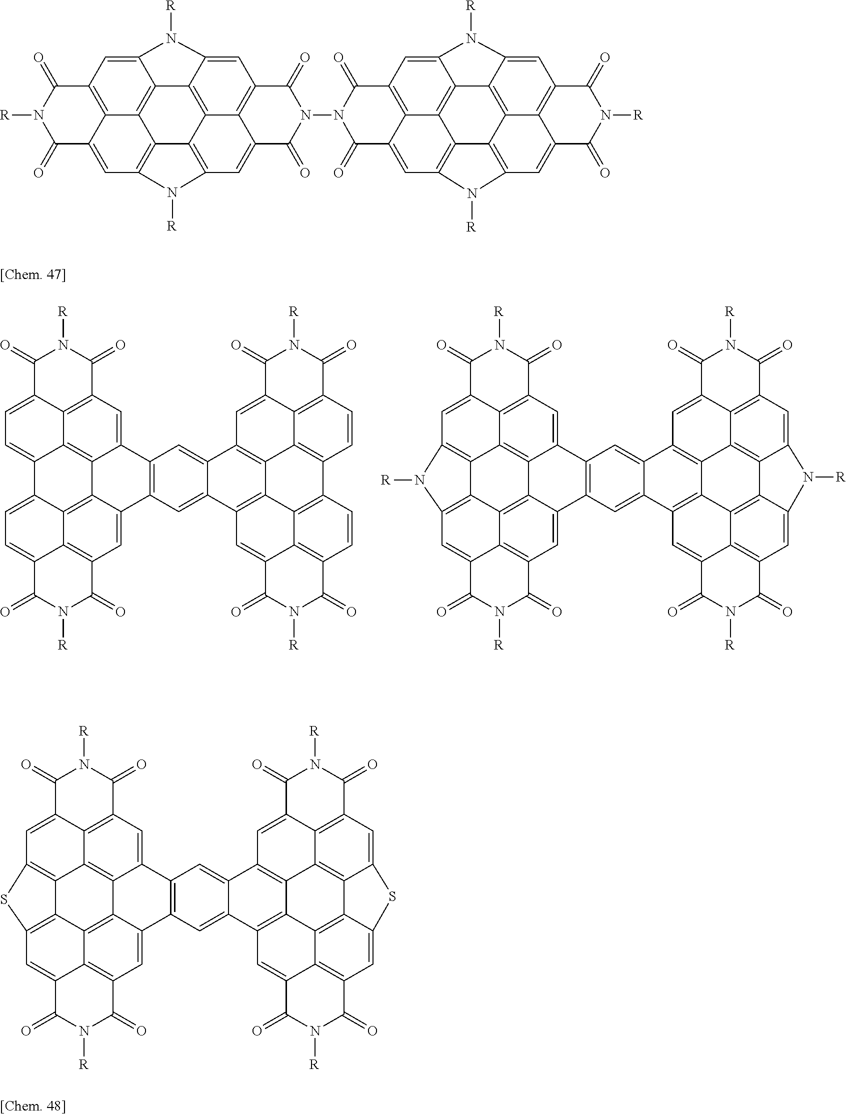

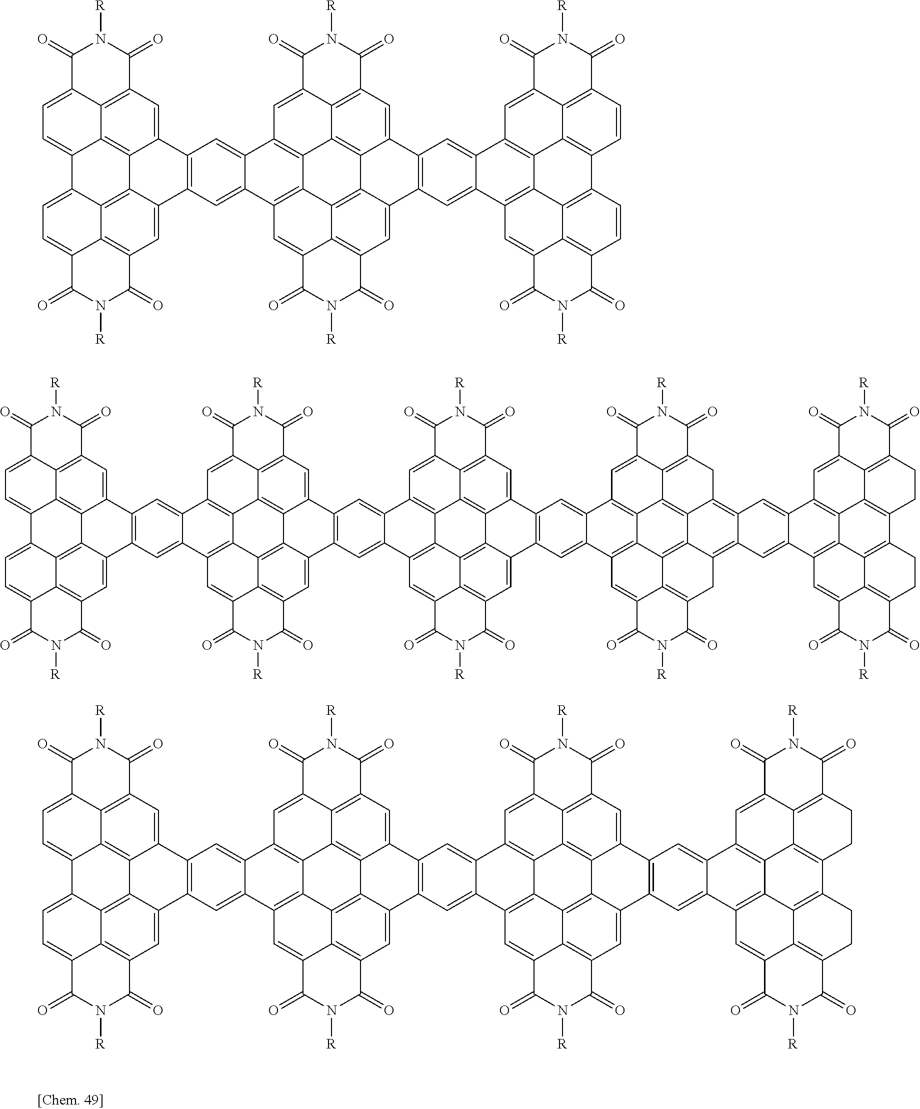

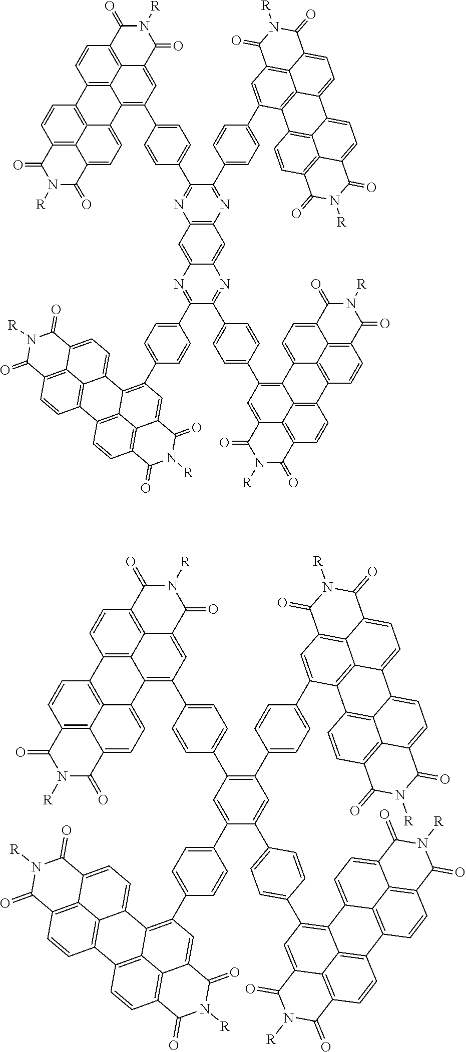

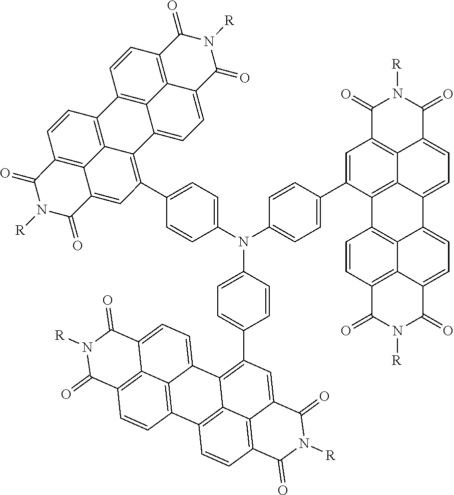

In the formulas, R is as defined above. The plurality of R's may be the same as or different from each other.

The non-fullerene compound, which is the n-type semiconductor material of the present embodiment, is preferably a compound represented by the following Formula (VIII). The compound represented by the following Formula (VIII) is a non-fullerene compound having a perylene tetracarboxylic acid diimide structure.

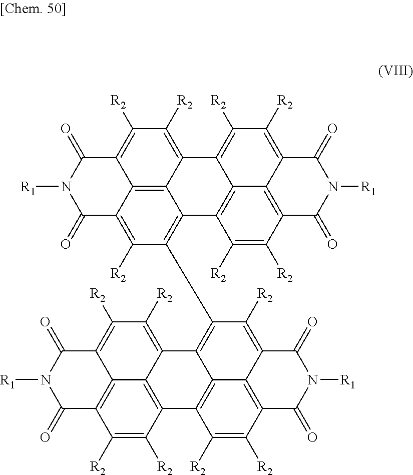

In Formula (VIII),
R₁ represents a hydrogen atom, a halogen atom, an alkyl group which may have a substituent, an alkoxy group which may have a substituent, a monovalent aromatic hydrocarbon group which may have a substituent, or a monovalent aromatic heterocyclic group which may have a substituent. The plurality of R₁'s may be the same as or different from each other.

In Formula (VIII), R₁ is preferably an alkyl group which may have a substituent. R₁ is preferably a group represented by —(CH₂)ₙCH₃, a group represented by —CH(CₙH₂ₙ₊₁)₂, or an alkyl group in which one or more hydrogen atoms in a group represented by —(CH₂)ₙCH₃ are substituted with a fluorine atom, and more preferably a group represented by —(CH₂) (CF₂)ₙ₋₁CF₃. Note that n means an integer, and in a case where R₁ is a group represented by —(CH₂)ₙCH₃, a lower limit value of n is preferably 1, more preferably 5, and still more preferably 7, and an upper limit value of n is preferably 30, more preferably 25, and still more preferably 15. In addition, in a case where R₁ is a group represented by —(CH₂) (CF₂)ₙ₋₁CF₃, a lower limit value of n is preferably 1, and more preferably 3, and an upper limit value of n is preferably 10, more preferably 7, and still more preferably 5.

R₂ represents a hydrogen atom, a halogen atom, an alkyl group which may have a substituent, an alkoxy group which may have a substituent, a monovalent aromatic hydrocarbon group which may have a substituent, or a monovalent aromatic heterocyclic group which may have a substituent. From the viewpoint of the energy level, R₂ is preferably an electron-withdrawing group, more preferably a halogen atom, an alkyl group containing one or more halogen atoms as a substituent, an alkoxy group containing one or more halogen atoms as a substituent, monovalent aromatic hydrocarbon group containing one or more halogen atoms as a substituent, or a monovalent aromatic heterocyclic group containing one or more halogen atoms as a substituent, still more preferably a bromine atom, a fluorine atom, an alkyl group containing one or more fluorine atoms as a substituent, an alkoxy group containing one or more fluorine atoms as a substituent, a monovalent aromatic hydrocarbon group containing one or more fluorine atoms as a substituent, or a monovalent aromatic heterocyclic group containing one or more fluorine atoms as a substituent, and most preferably an alkyl group containing one or more fluorine atoms as a substituent. The plurality of R₂'s may be the same as or different from each other.

In Formula (VIII), at least one of R₁ and R₂ is preferably a fluorine atom, an alkyl group containing a fluorine atom as a substituent, an alkoxy group containing a fluorine atom as a substituent, a monovalent aromatic hydrocarbon group containing a fluorine atom as a substituent, or an aromatic heterocyclic group containing a fluorine atom as a substituent, and it is more preferable that R₁ is an alkyl group containing one or more fluorine atoms as a substituent and R₂ is a hydrogen atom.

Examples of the n-type semiconductor material that can be preferably used in the present embodiment include a compound in which in Formula (VIII), R₁ is a group represented by —CH₂ (CF₂)₂CF₃ and R₂ is a hydrogen atom, and a compound in which R₁ is a group represented by —CH(C₅H₁₁)₂ and at least one of a plurality of R₂'s is a group represented by —CF₃.

Specific examples of the n-type semiconductor material represented by Formula (VIII) that can be preferably used in the present embodiment include compounds represented by the following Formulas (N-1) to (N-13).

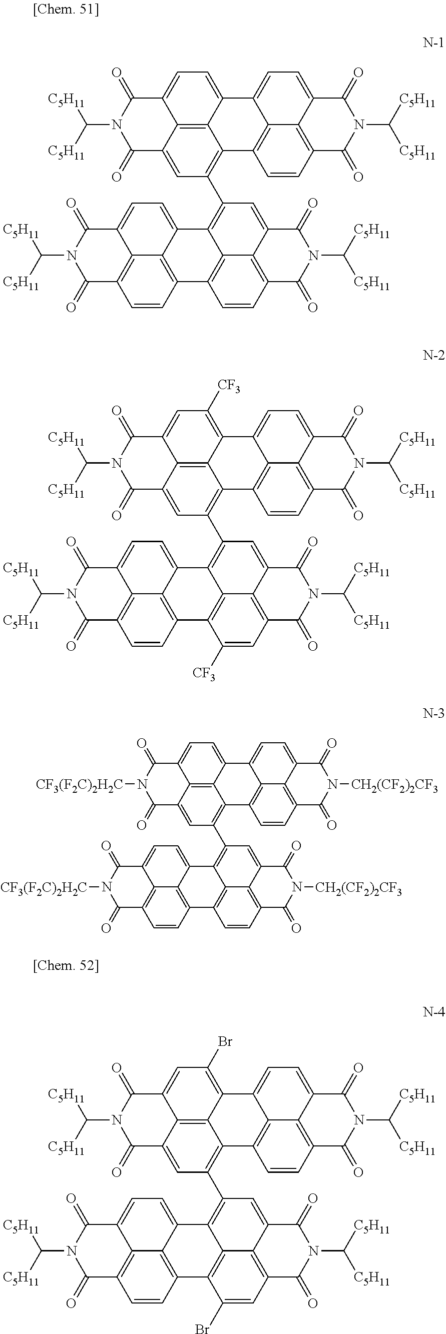

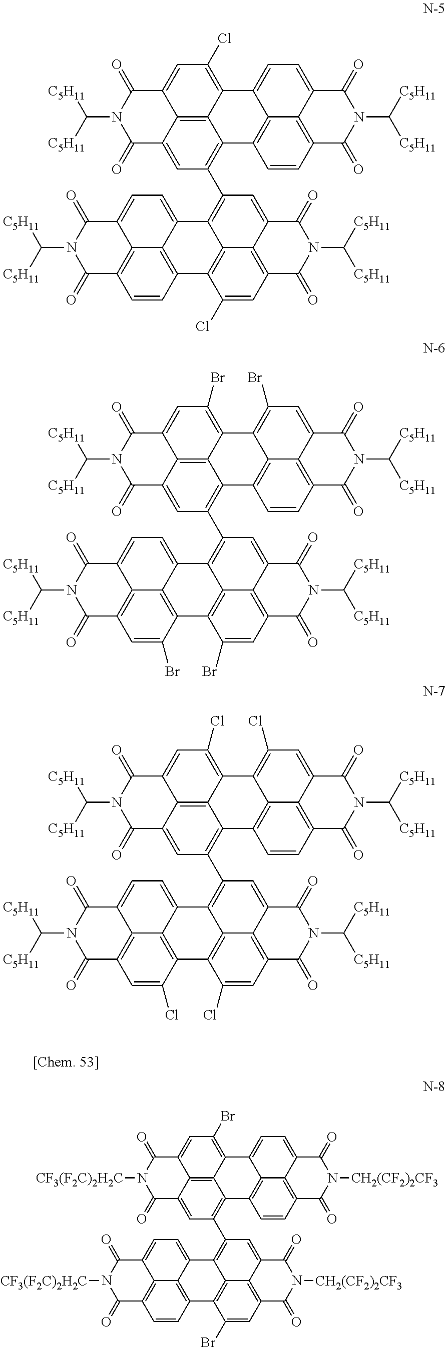

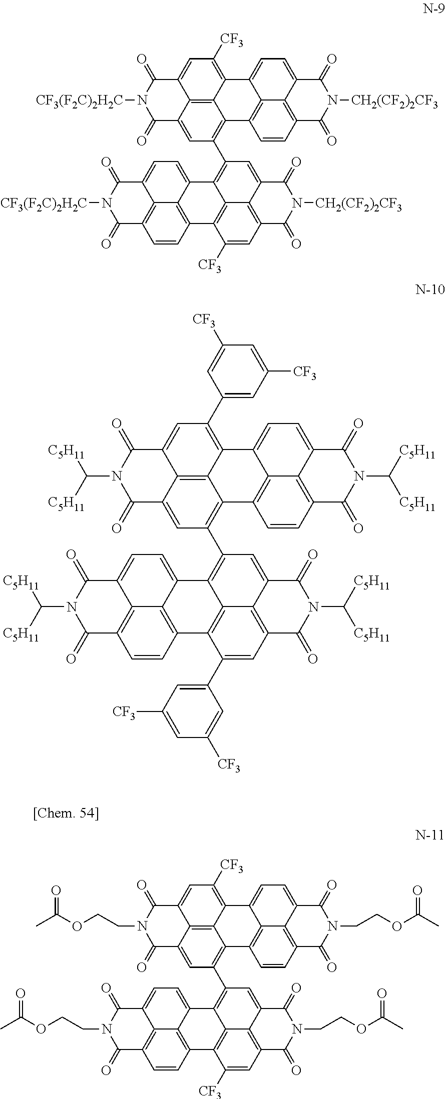

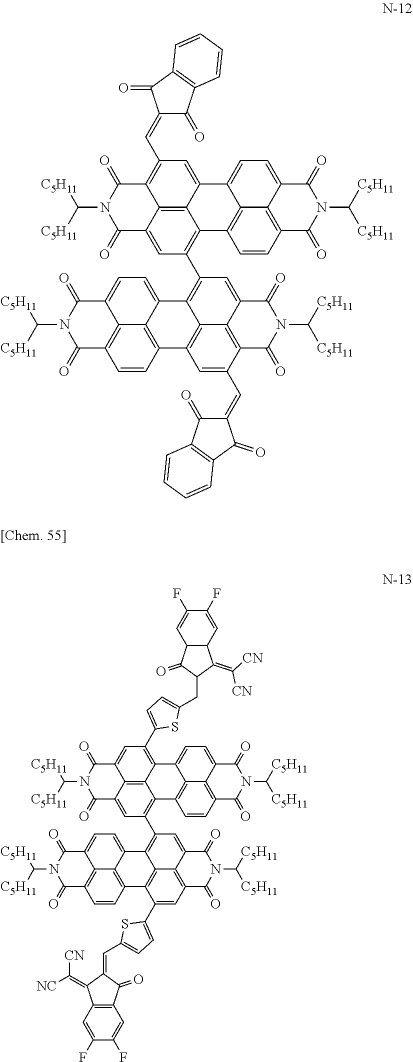

The non-fullerene compound, which is the n-type semiconductor material of the present embodiment, is preferably a compound represented by the following Formula (IX).

A¹-B¹⁰-A² (IX)

In Formula (IX),

A¹ and A² each independently represent an electron-withdrawing group, and B¹⁰ represents a group having a π-conjugated system. Note that each of A¹ and A² corresponds to a moiety AP having an electron accepting property, and B¹⁰ corresponds to a moiety DP having an electron donating property.

Examples of the electron-withdrawing group represented by A¹ or A² include a group represented by —CH═C(—CN)₂ and groups represented by the following Formulas (a-1) to (a-9).

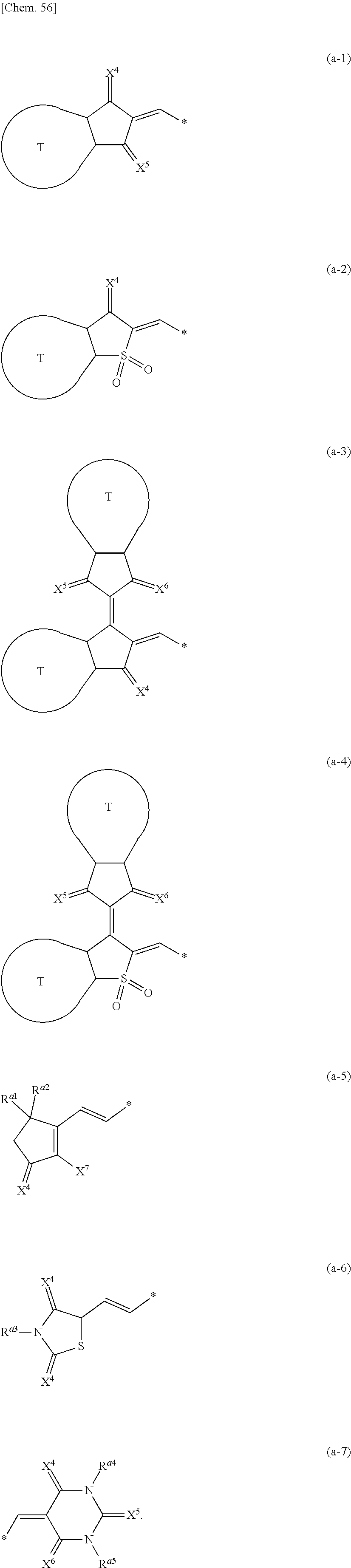

In Formulas (a-1) to (a-7),

T represents a carbocyclic ring which may have a substituent or a heterocyclic ring which may have a substituent. Each of the carbocyclic ring and the heterocyclic ring may be a single ring or a condensed ring. In a case where these rings have a plurality of substituents, the plurality of substituents may be the same as or different from each other.

Examples of the carbocyclic ring which is represented by T and may have a substituent include an aromatic carbocyclic ring, and an aromatic carbocyclic ring is preferable. Specific examples of the carbocyclic ring which is represented by T and may have a substituent include a benzene ring, a naphthalene ring, an anthracene ring, a tetracene ring, a pentacene ring, a pyrene ring, and a phenanthrene ring, a benzene ring, a naphthalene ring, and a phenanthrene ring are preferable, a benzene ring and a naphthalene ring are more preferable, and a benzene ring is still more preferable. These rings may have a substituent.

Examples of the heterocyclic ring which is represented by T and may have a substituent include an aromatic heterocyclic ring, and an aromatic carbocyclic ring is preferable. Specific examples of the heterocyclic ring which is represented by T and may have a substituent include a pyridine ring, a pyridazine ring, a pyrimidine ring, a pyrazine ring, a pyrrole ring, a furan ring, a thiophene ring, an imidazole ring, an oxazole ring, a thiazole ring, and a thienothiophene ring, a thiophene ring, a pyridine ring, a pyrazine ring, a thiazole ring, and a thiophene ring are preferable, and a thiophene ring is more preferable. These rings may have a substituent.

Examples of the substituent which may be included in the carbocyclic ring or heterocyclic ring represented by T include a halogen atom, an alkyl group, an alkoxy group, an aryl group, and a monovalent heterocyclic group, and a fluorine atom and/or an alkyl group having 1 to 6 carbon atoms is preferable.

X⁴, X⁵, and X⁶ each independently represent an oxygen atom, a sulfur atom, an alkylidene group, or a group represented by ═C(—CN)₂, and are preferably an oxygen atom, a sulfur atom, or a group represented by ═C(—CN)₂.

X⁷ represents a hydrogen atom or a halogen atom, a cyano group, an alkyl group which may have a substituent, an alkoxy group which may have a substituent, an aryl group which may have a substituent, or a monovalent heterocyclic group.

R^{a1}, R^{a2}, R^{a3}, R^{a4}, and R^{a5} each independently represent a hydrogen atom, an alkyl group which may have a substituent, a halogen atom, an alkoxy group which may have a substituent, an aryl group which may have a substituent, or a monovalent heterocyclic group, and may be preferably an alkyl group which may have a substituent or an aryl group which may have a substituent.

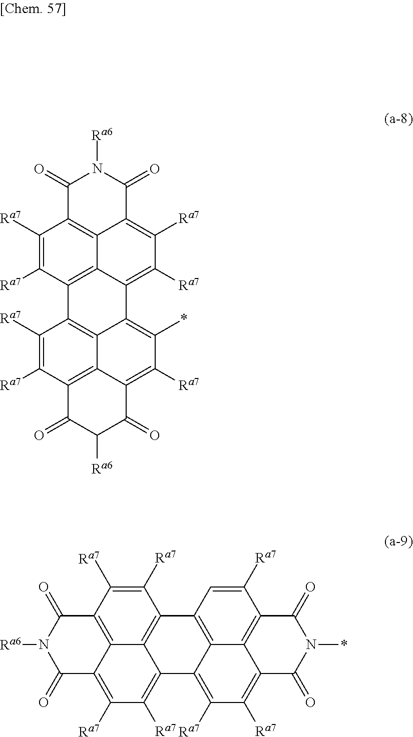

In Formulas (a-8) and (a-9),

R^{a6} and R^{a7} each independently represent a hydrogen atom, a halogen atom, an alkyl group which may have a substituent, a cycloalkyl group which may have a substituent, an alkoxy group which may have a substituent, a cycloalkoxy group which may have a substituent, a monovalent aromatic carbocyclic group which may have a substituent, or a monovalent aromatic heterocyclic group which may have a substituent, and a plurality of R^{a6}'s and a plurality of R^{a7}'s may be the same as or different from each other.

The electron-withdrawing group represented by A¹ or A² is preferably a group represented by any one of the following Formulas (a-1-1) to (a-1-4), (a-6-1), and (a-7-1). Here, a plurality of R^{a10}'s each independently represent a hydrogen atom or a substituent, and preferably represent a hydrogen atom, a halogen atom, or an alkyl group. R^{a3}, R^{a4}, and R^{a5} have the same meanings as described above, and preferably, each independently represent an alkyl group which may have a substituent or an aryl group which may have a substituent.

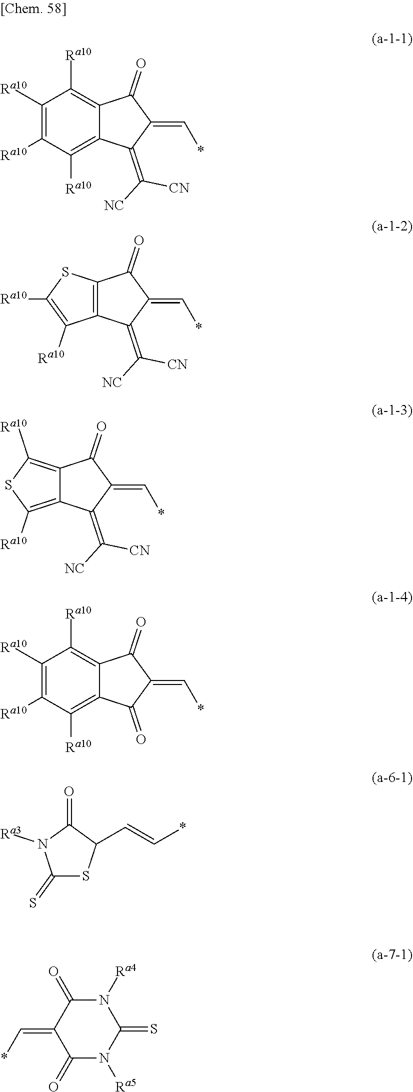

Examples of the group that is represented by B¹⁰ and has a n-conjugated system include a group represented by —(S¹)ₙ₁—B¹¹—(S²)ₙ₂— in a compound represented by Formula (X) described below.

The non-fullerene compound, which is the n-type semiconductor material of the present embodiment, is preferably a compound represented by the following Formula (X).

A¹-(S¹)ₙ₁—B¹¹—(S²)ₙ₂-A² (X)

In Formula (X),

A¹ and A² each independently represent an electron-withdrawing group. Examples and preferred examples of A¹ and A² are the same as the examples and preferred examples described in A¹ and A² in Formula (IX).

S¹ and S² each independently represent a divalent carbocyclic group which may have a substituent, a divalent heterocyclic group which may have a substituent, or a group represented by —C(R^{s1})═C(R^{s2})— (where, R^{s1} and R^{s2} each independently represent a hydrogen atom, a substituent (preferably, a hydrogen atom, a halogen atom, an alkyl group which may have a substituent, or a monovalent heterocyclic group which may have a substituent), or a group represented by —C≡C—).

The divalent carbocyclic group which may have a substituent and the divalent heterocyclic group which may have a substituent may be condensed rings, the divalent carbocyclic group and the divalent heterocyclic group being represented by S¹ or S². In a case where the divalent carbocyclic group or the divalent heterocyclic group has a plurality of substituents, the plurality of substituents may be the same as or different from each other.

In Formula (X),

n1 and n2 each independently represent an integer of 0 or more, preferably each independently represent 0 or 1, and more preferably represent 0 or 1 at the same time.

As described above, the non-fullerene compound represented by Formula (X) has a structure in which a moiety DP and a moiety AP are linked by S¹ and S² which are spacers (groups or structural units).

Examples of the divalent carbocyclic group include a divalent aromatic carbocyclic group.

Examples of the divalent heterocyclic group include a divalent aromatic heterocyclic group.

In a case where the divalent aromatic carbocyclic group or the divalent aromatic heterocyclic group is a condensed ring, all of the rings constituting the condensed ring may be condensed rings having aromaticity, or only some rings constituting the condensed ring may be condensed rings having aromaticity.

Examples of S¹ and S² include a group represented by any one of Formulas (101) to (172) and (178) to (185) described as the examples of the divalent aromatic heterocyclic group represented by Ara described above, and a group in which a hydrogen atom in this group is substituted with a substituent.

S¹ and S² preferably each independently represent a group represented by any one of the following Formulas (s-1) and (s-2).

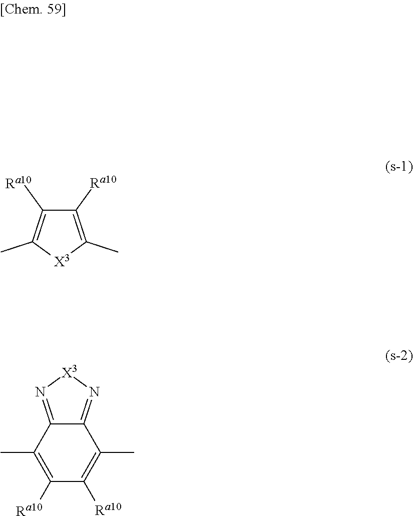

In Formulas (s-1) and (s-2),

X³ represents an oxygen atom or a sulfur atom.

Ra¹⁰ is as defined above.

S¹ and S² preferably each independently represent a group represented by Formula (142), Formula (148), or Formula (184), or a group in which a hydrogen atom in this group is substituted with a substituent, and more preferably a group represented by Formula (142) or Formula (184), or a group in which one hydrogen atom in the group represented by Formula (184) is substituted with an alkoxy group.

B¹¹ represents a condensed ring group having two or more structures selected from the group consisting of a carbocyclic structure and a heterocyclic structure, in which the condensed ring group does not have an ortho-peri-condensed structure and which may have a substituent.

The condensed ring group represented by B¹¹ may have a structure in which two or more structures that are the same as each other are condensed.

In a case where the condensed ring group represented by B¹¹ has a plurality of substituents, the plurality of substituents may be the same as or different from each other.

Examples of a carbocyclic structure that can constitute the condensed ring group represented by B¹¹ include a ring structure represented by the following Formula (Cy1) or (Cy2).

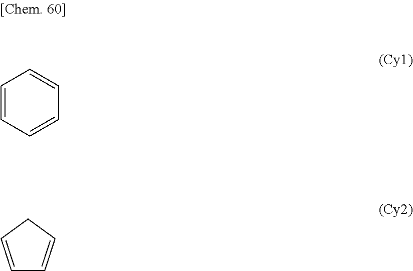 [SMILES: c1ccccc1 ; C1=CCC=C1]

Examples of a heterocyclic structure that can constitute the condensed ring group represented by B¹¹ include a ring structure represented by any one of the following Formulas (Cy3) to (Cy9).

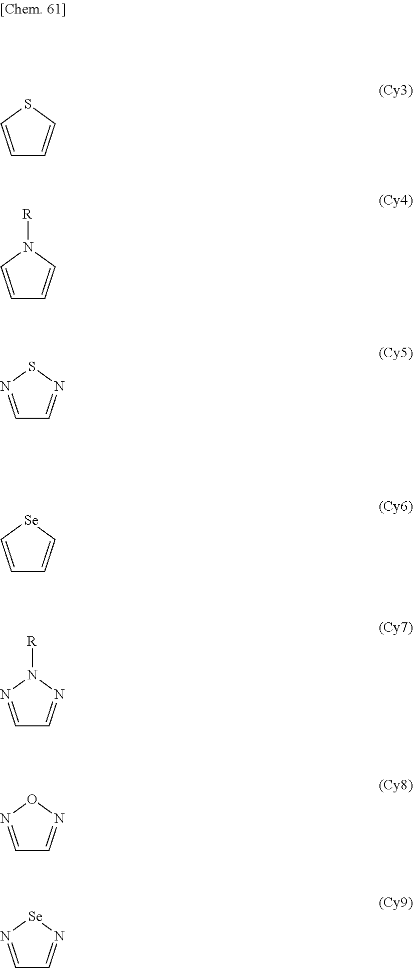

In the formulas,
R is as defined above, and
B¹¹ is preferably a condensed ring group formed by condensing two or more structures selected from the group consisting of structures represented by Formulas (Cy1) to (Cy9), in which the condensed ring group does not have an ortho-peri-condensed structure and which may have a substituent. B¹¹ may have a structure obtained by condensing two or more identical structures among the structures represented by Formulas (Cy1) to (Cy9).
B¹¹ is more preferably a condensed ring group formed by condensing two or more structures selected from the group consisting of structures represented by Formulas (Cy1) to (Cy5) and (Cy7), in which the condensed ring group does not have an ortho-peri-condensed structure and which may have a substituent.

The substituent which may be included in the condensed ring group and is represented by B¹¹ is preferably an alkyl group which may have a substituent, an aryl group which may have a substituent, an alkoxy group which may have a substituent, or a monovalent heterocyclic group which may have a substituent. The aryl group which may be included in the condensed ring group represented by B¹¹ may be substituted with, for example, an alkyl group.

Examples of the condensed ring group represented by B¹¹ include groups represented by the following Formulas (b-1) to (b-14), and a group in which a hydrogen atom in this group is further substituted with a substituent (preferably, an alkyl group which may have a substituent, an aryl group which may have a substituent, an alkoxy group which may have a substituent, or a monovalent heterocyclic group which may have a substituent).

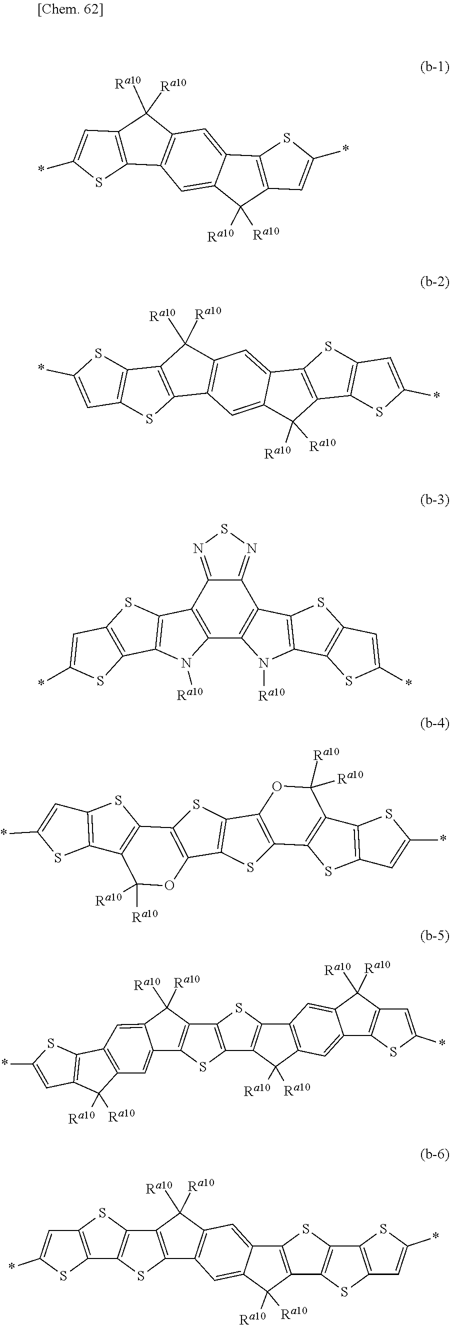

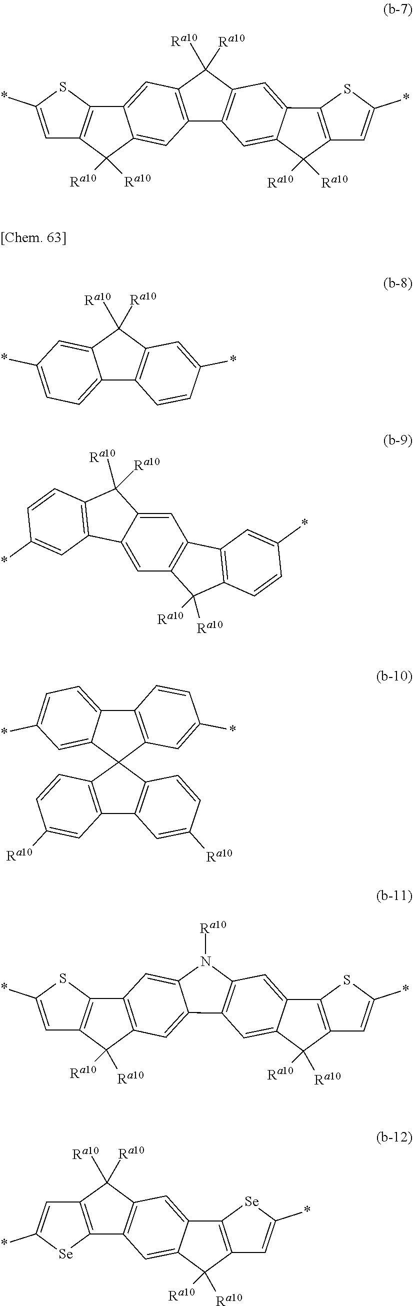

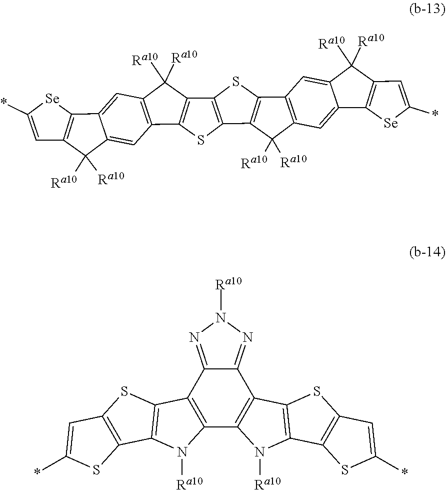

In Formulas (b-1) to (b-14),

R^{a10} is as defined above.

In Formulas (b-1) to (b-14), a plurality of R^{a10}'s are preferably each independently an alkyl group which may have a substituent or an aryl group which may have a substituent.

Examples of the compound represented by Formula (IX) or Formula (X) include compounds represented by the following formulas.

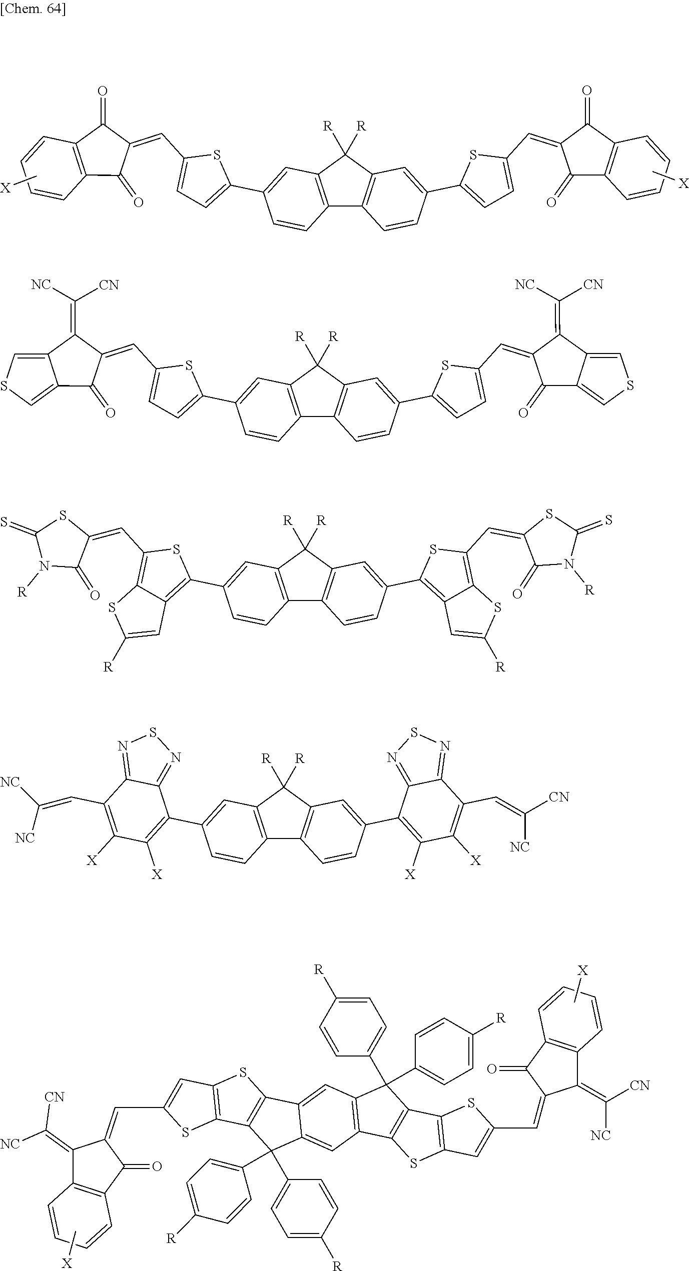

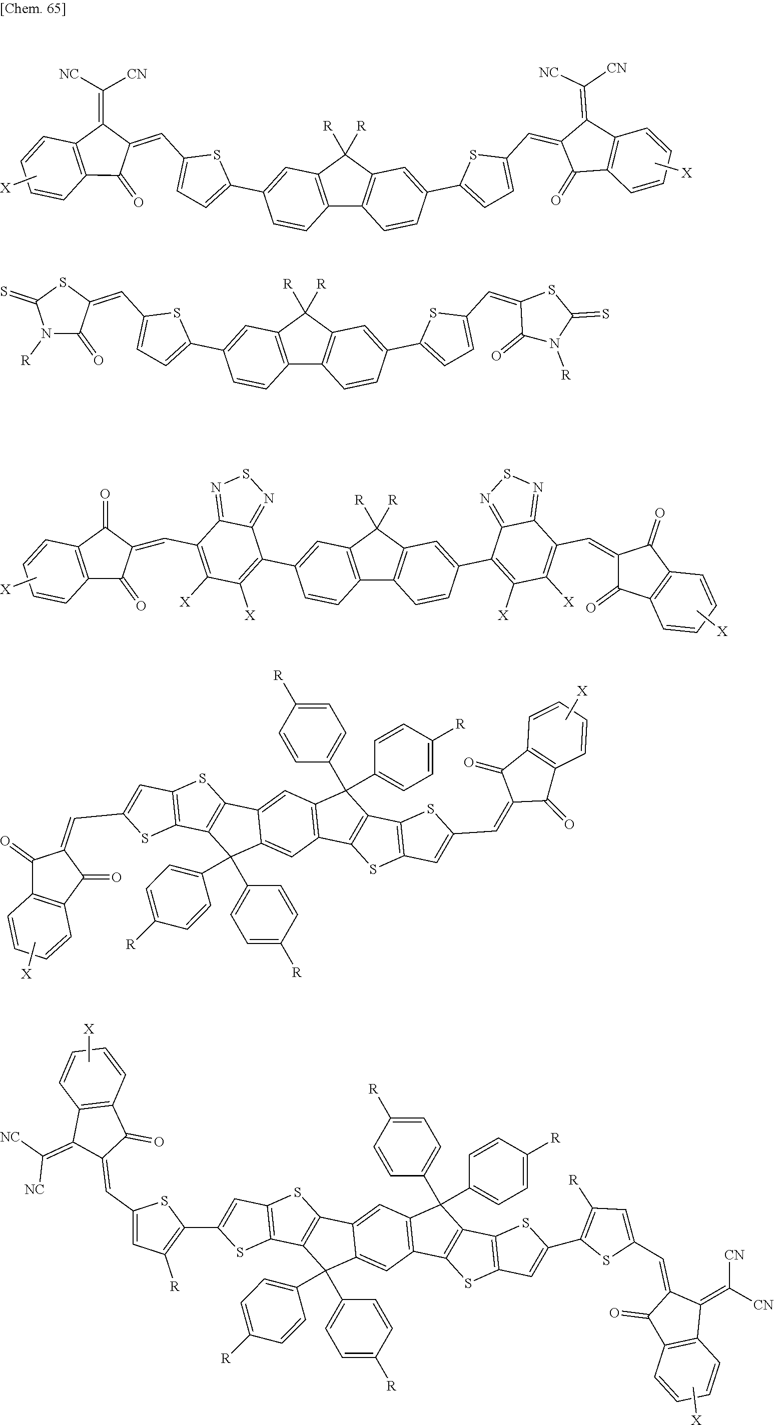

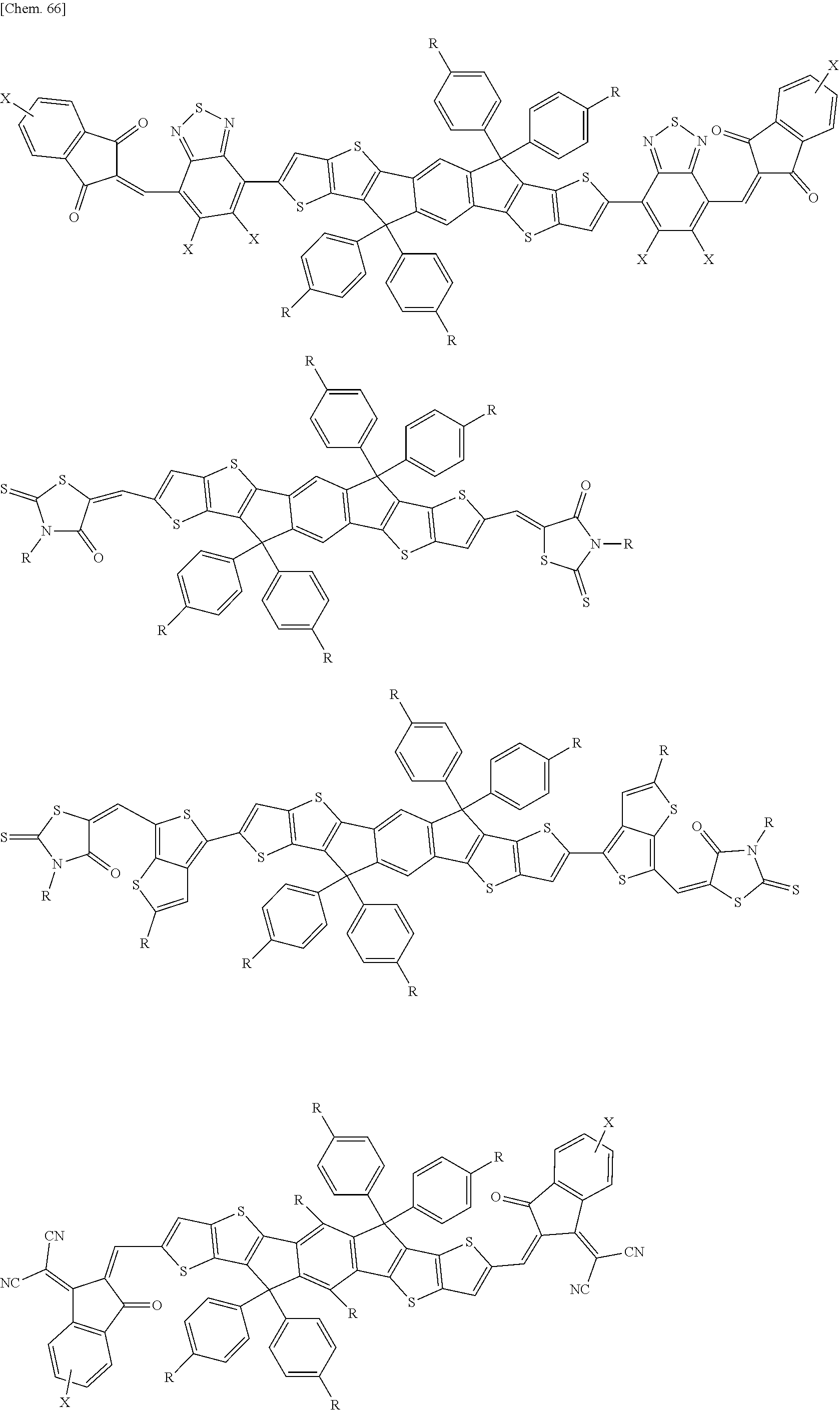

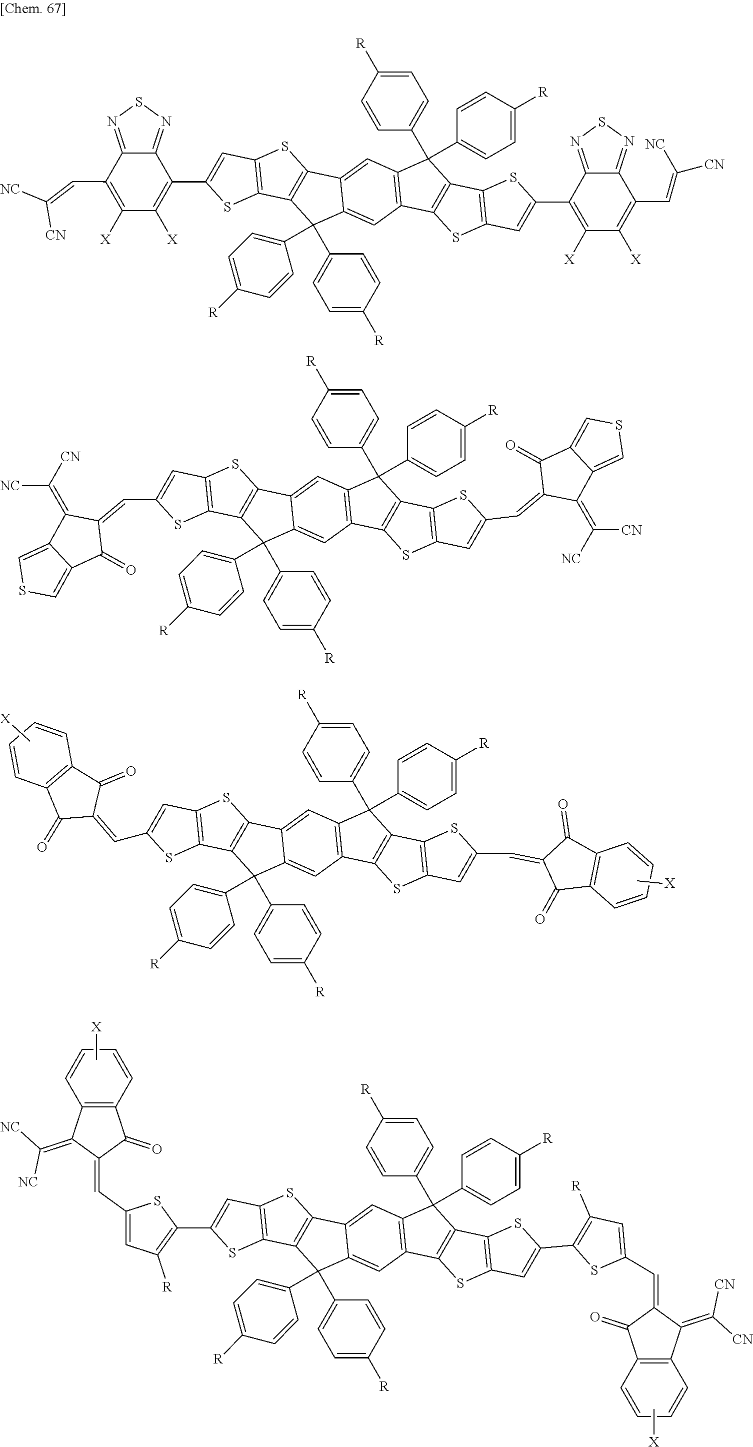

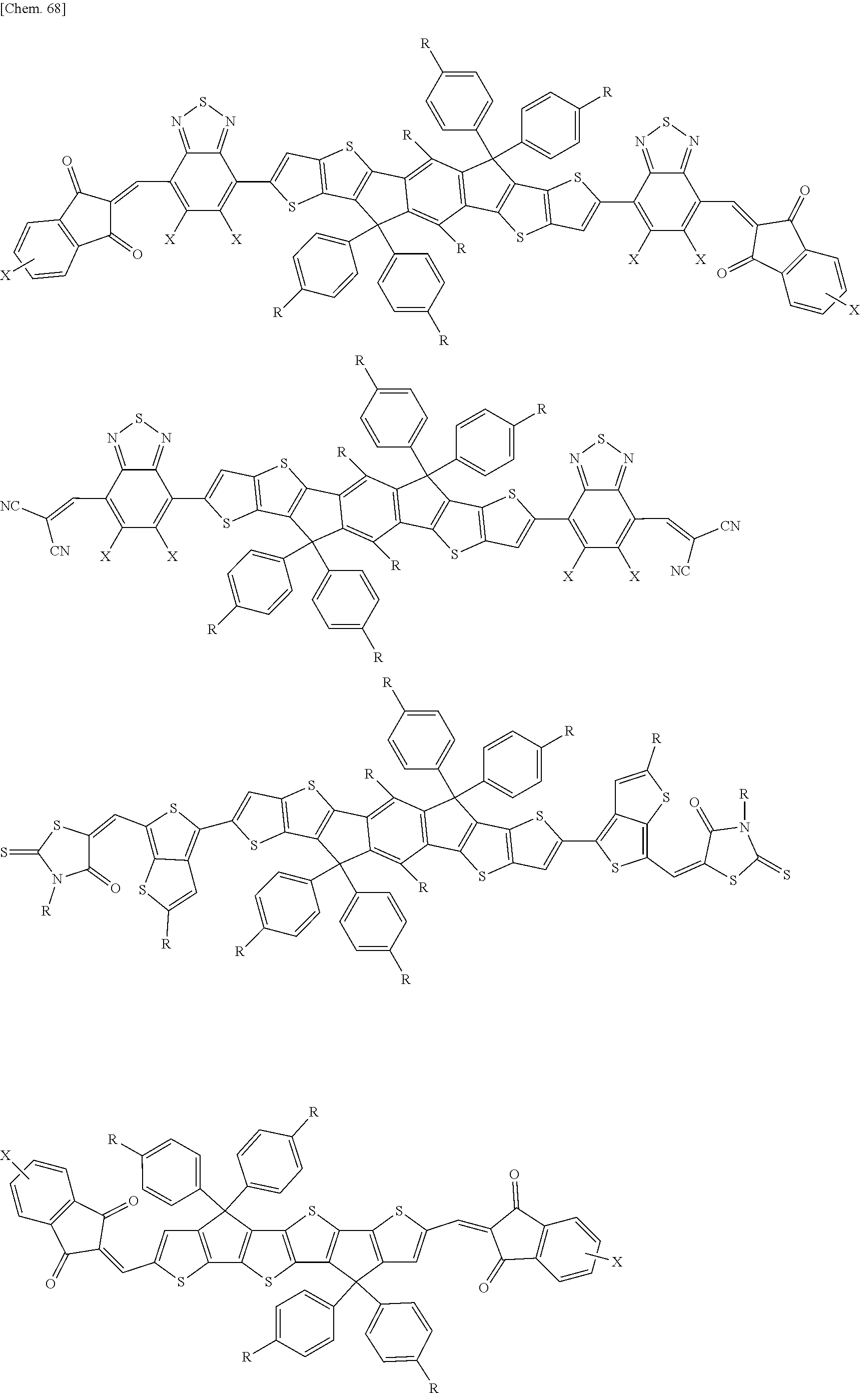

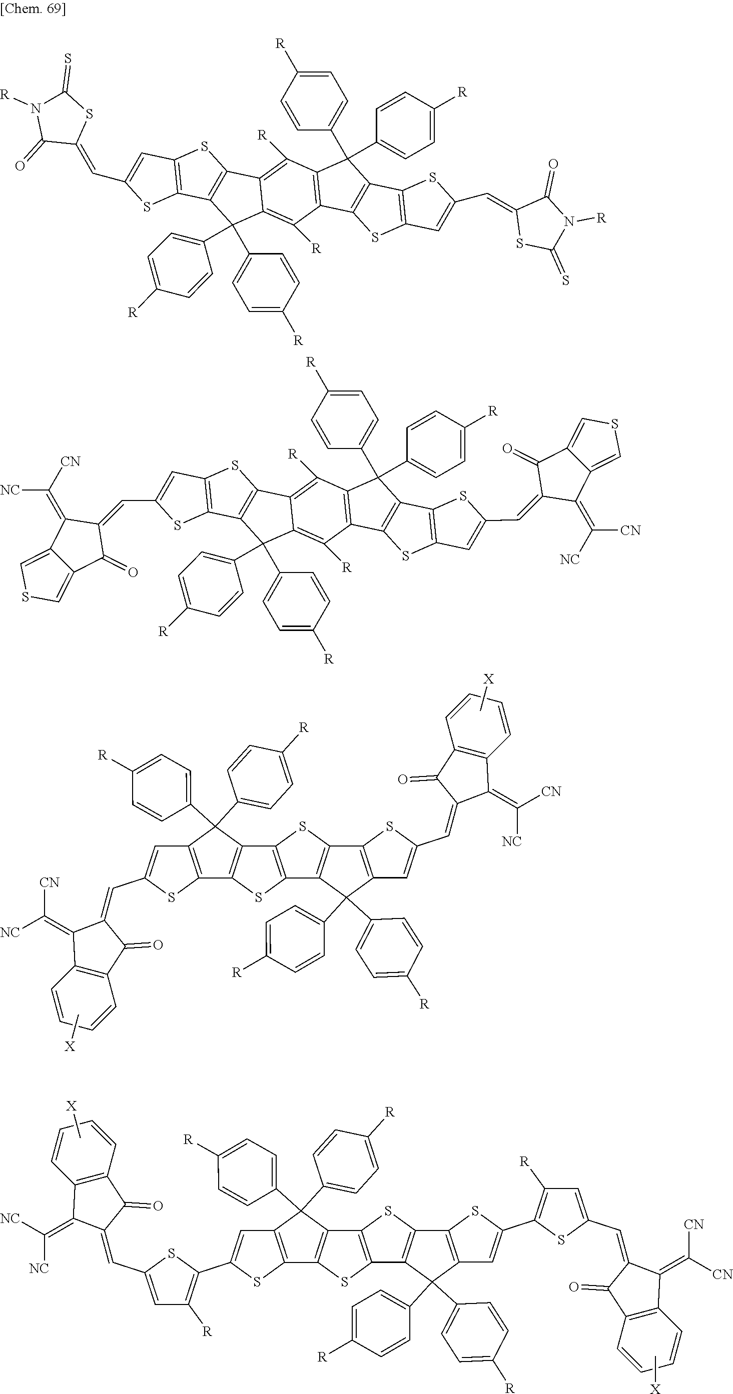

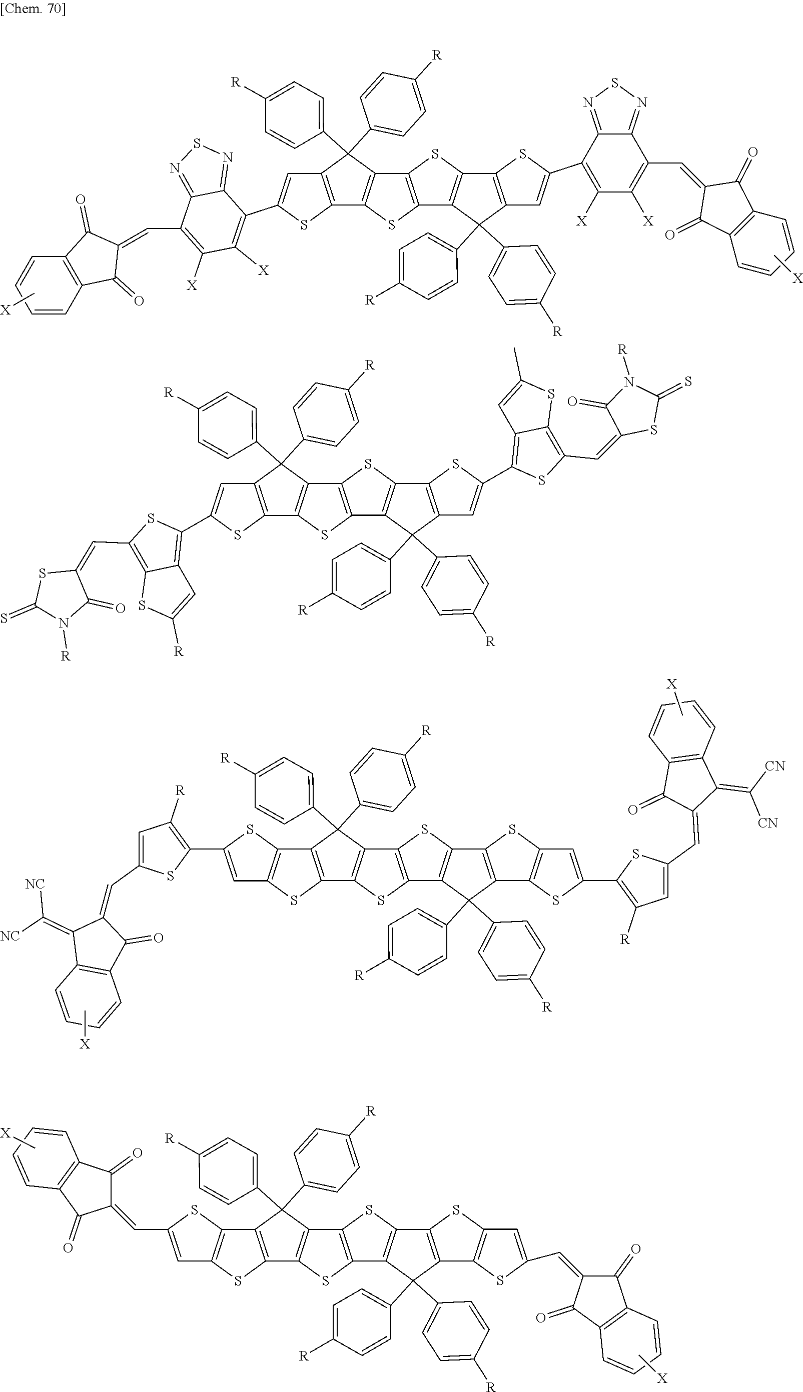

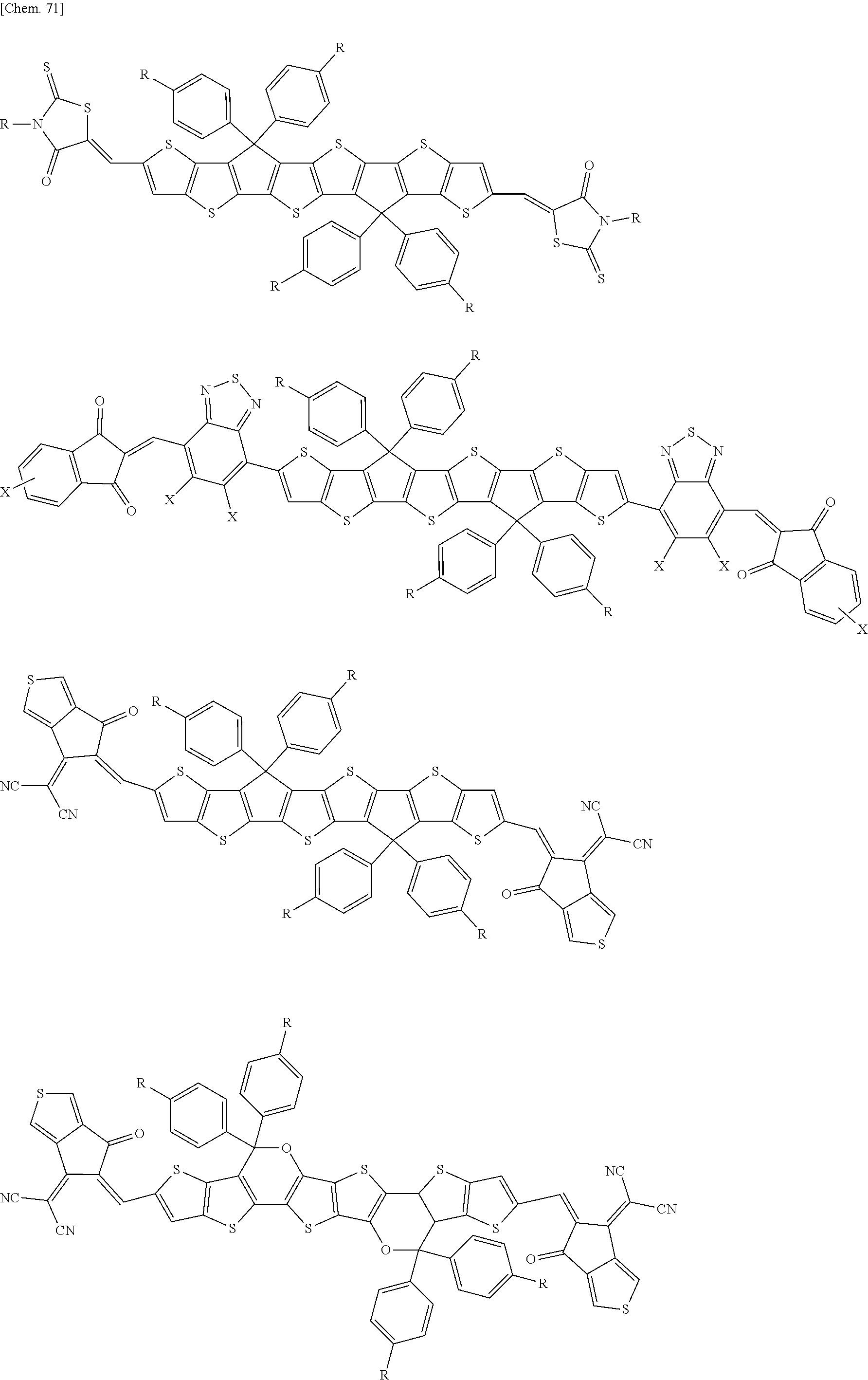

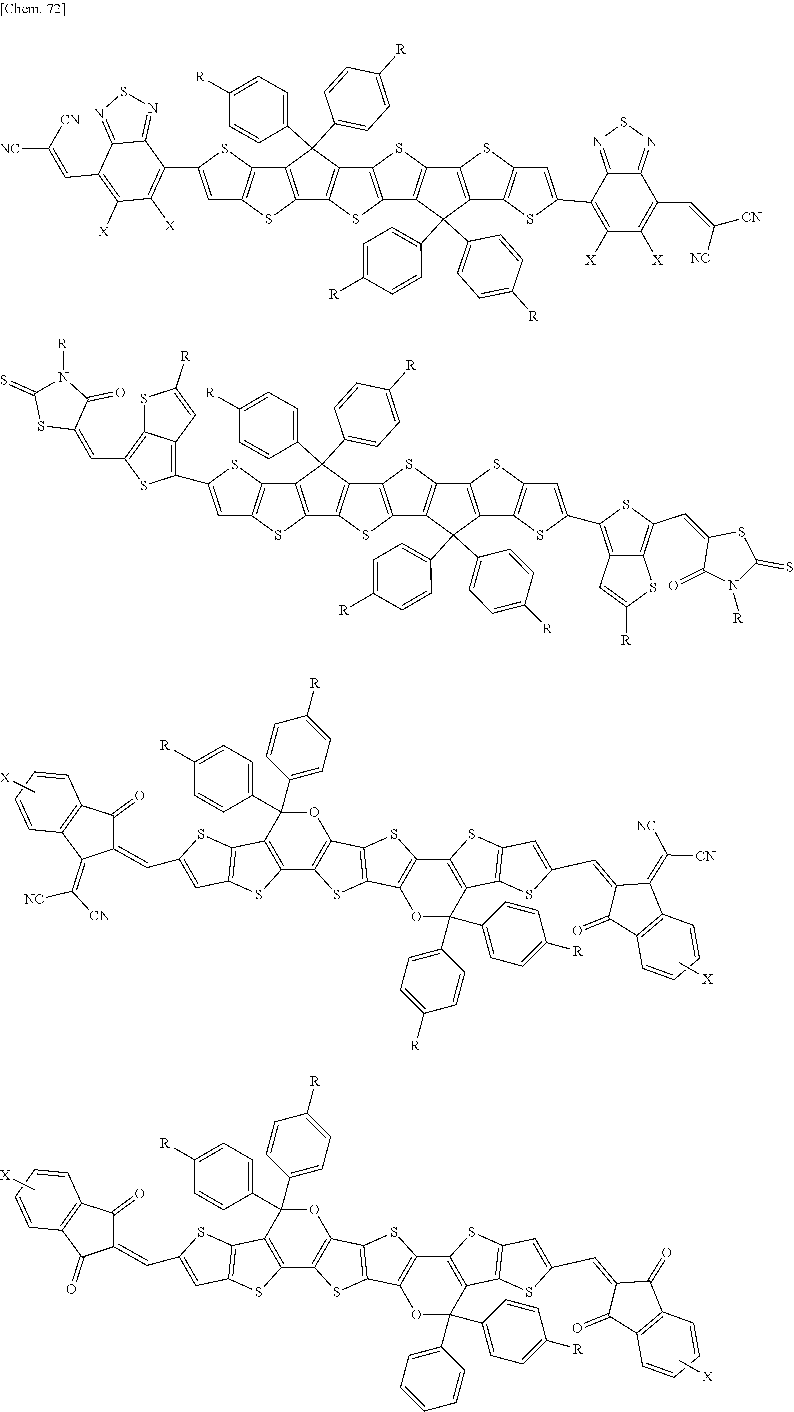

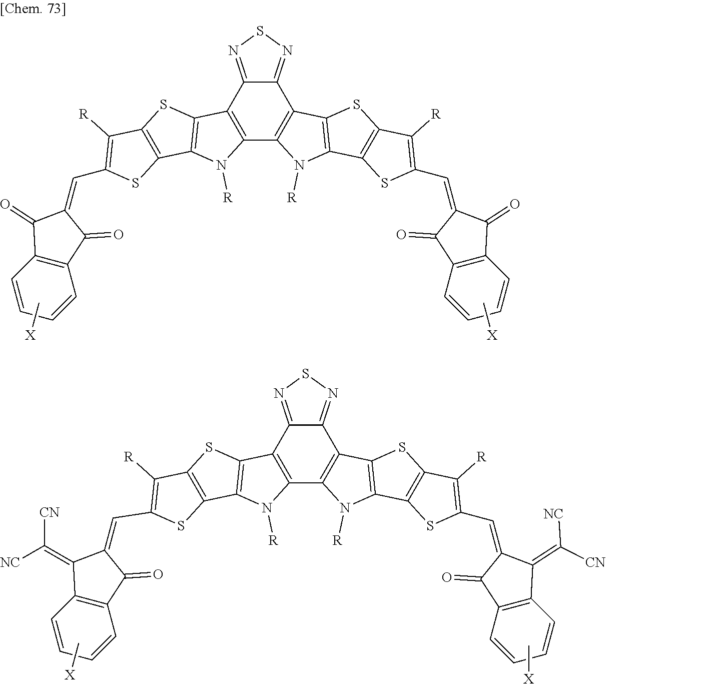

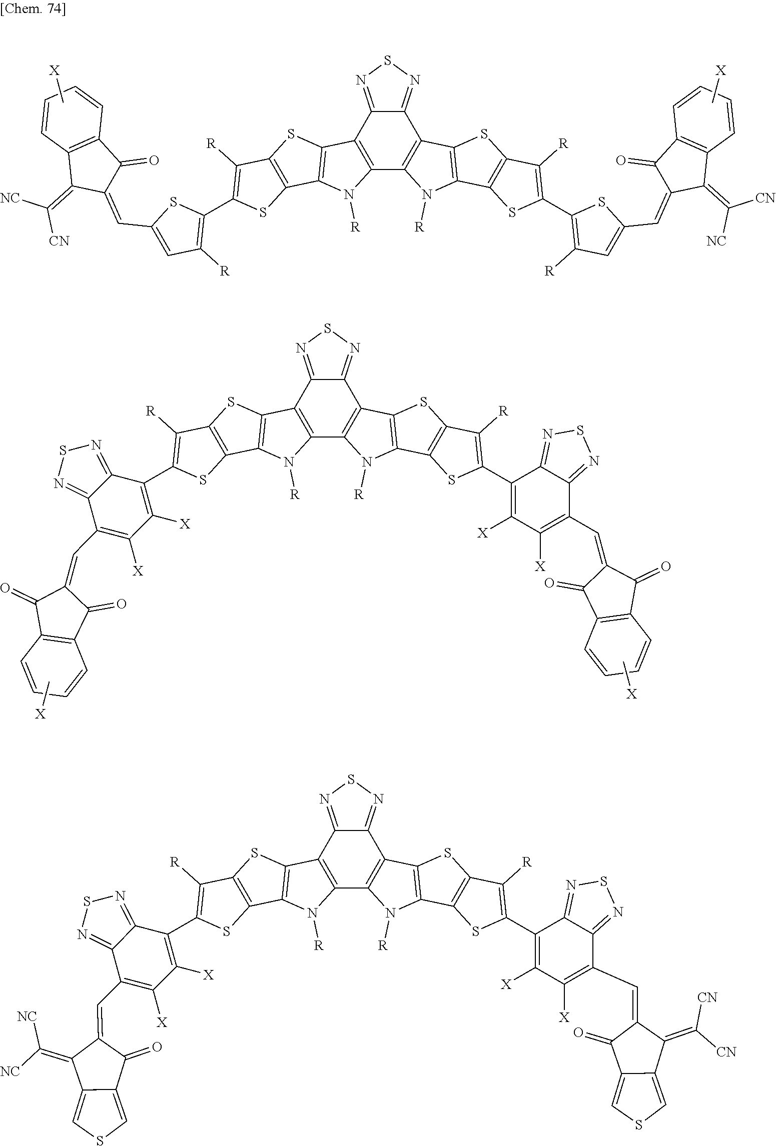

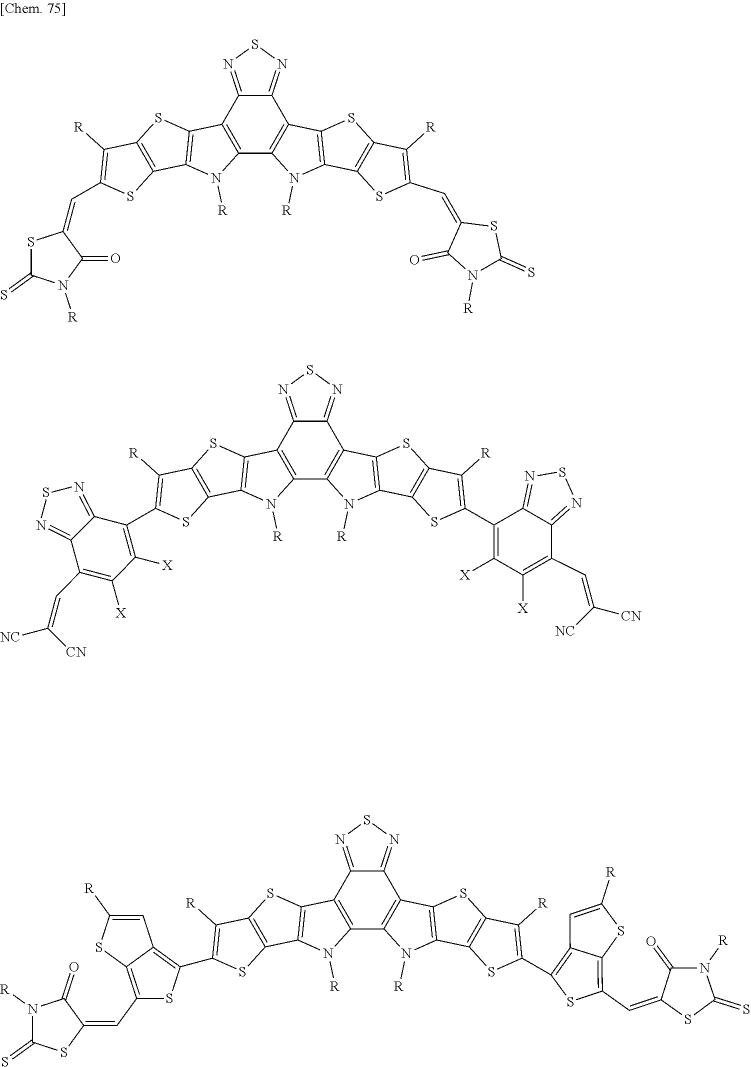

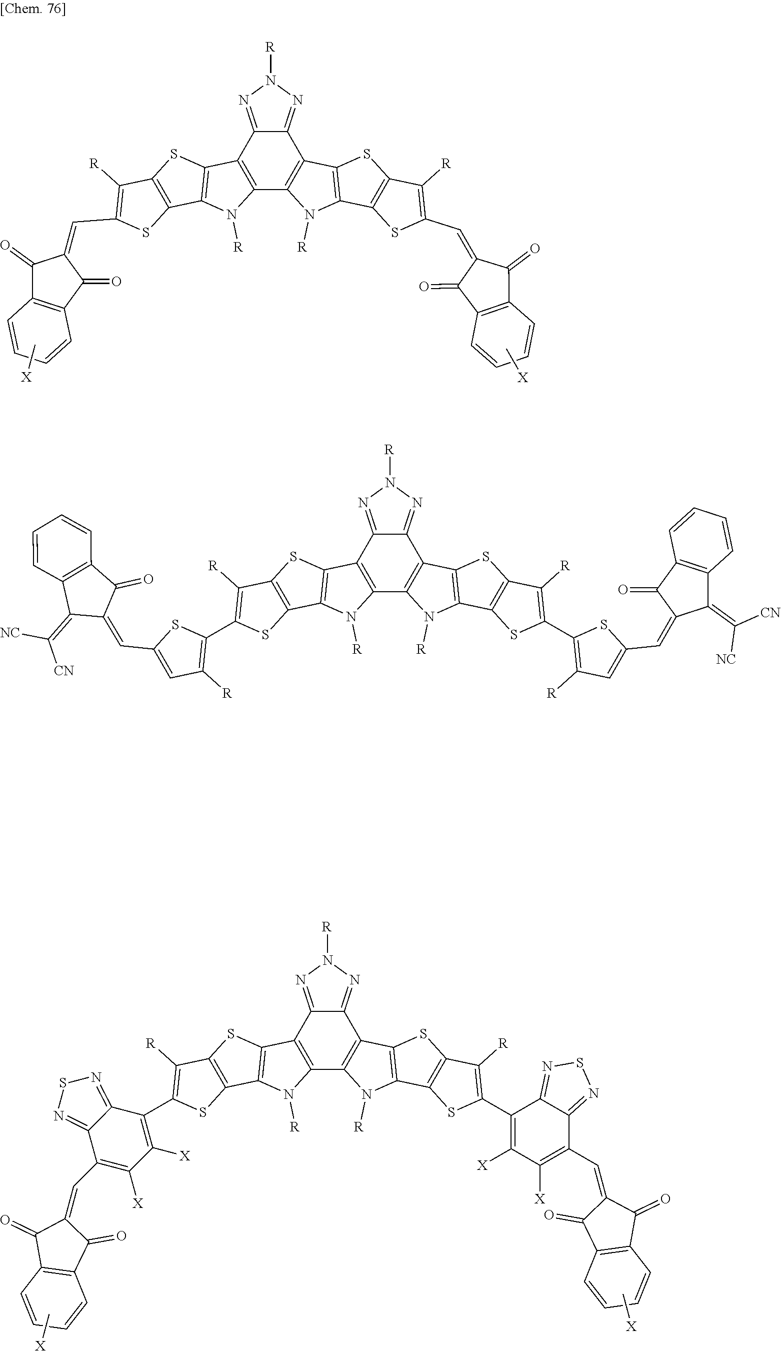

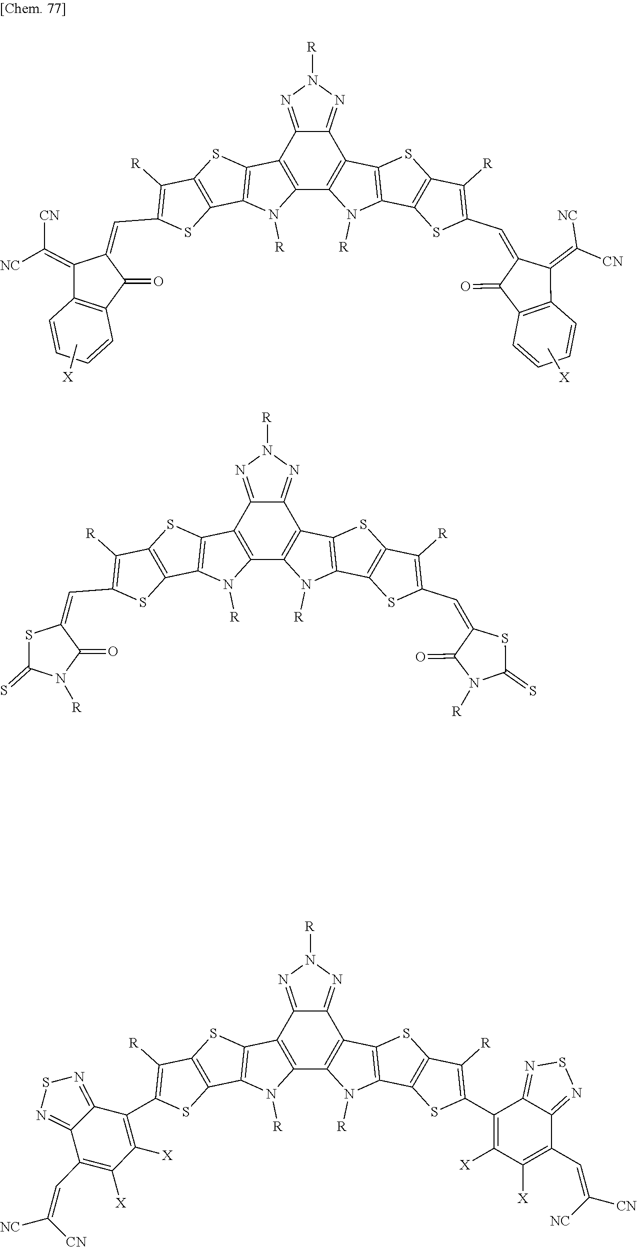

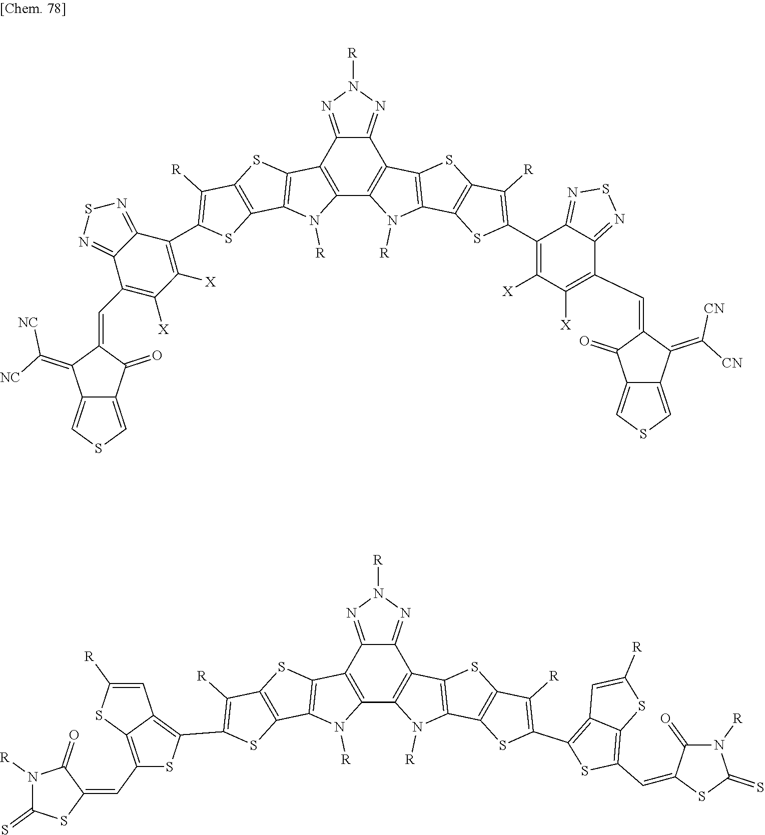

In the formulas,
R is as defined above, and
X represents a hydrogen atom, a halogen atom, a cyano group, or an alkyl group which may have a substituent.

In the formulas, R is preferably a hydrogen atom, an alkyl group which may have a substituent, an aryl group which may have a substituent, or an alkoxy group which may have a substituent.

As the compound represented by Formula (IX) or Formula (X), compounds represented by the following N-14 to N-17 are preferable.

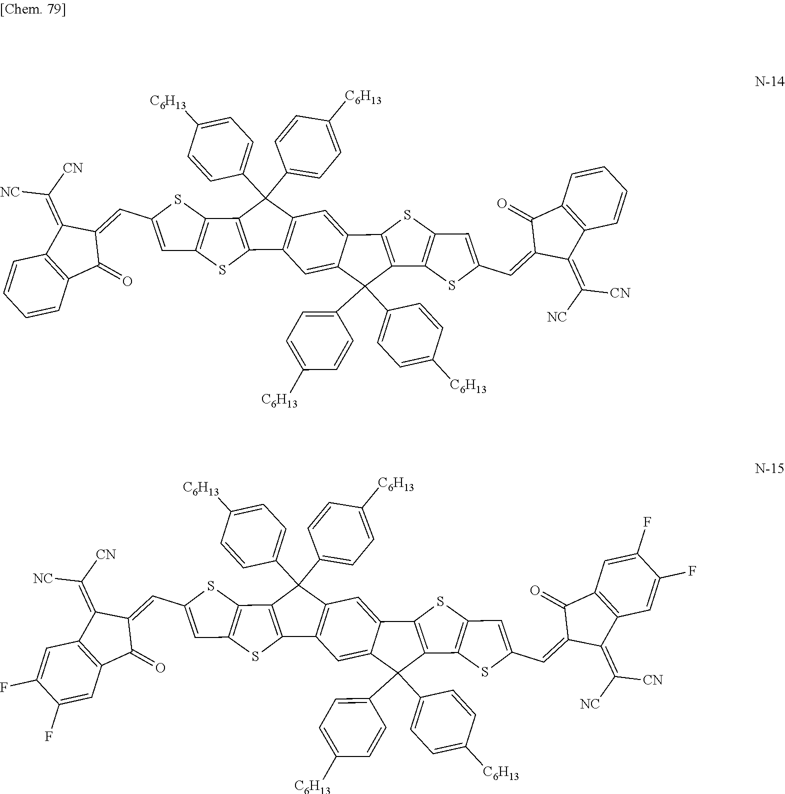

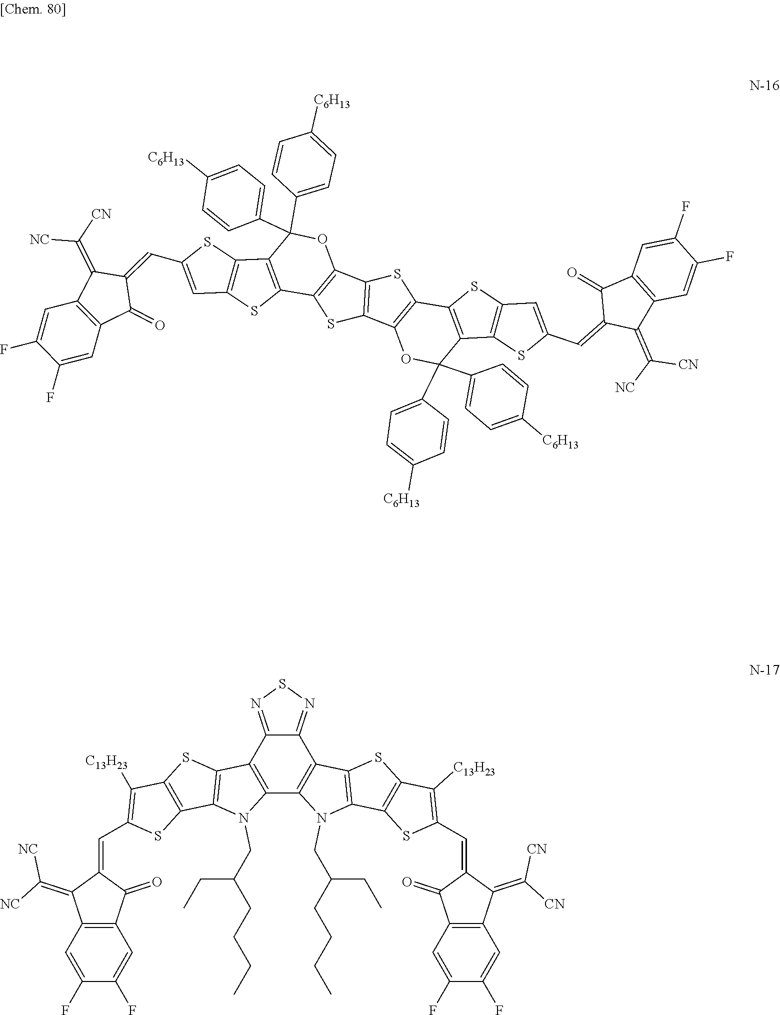

As the non-fullerene compound, it is preferable to use a non-fullerene compound represented by any one of Formulas (N-1), (N-2), and (N-14) to (N-17) because in the heat treatment in the step of manufacturing the photoelectric conversion element, the step of incorporating the photoelectric conversion element in a device to which the photoelectric conversion element is applied, or the like, it is possible to suppress the deterioration of the EQE or further improve the EQE, and it is possible to further suppress the increase in dark current or further reduce the dark current so as to improve the balance thereof, thereby improving the heat resistance.

In addition, in the present embodiment, at least one of the at least two n-type semiconductor materials contained in the active layer preferably contains a non-fullerene compound.

In the present embodiment, the active layer may contain two or more non-fullerene compounds as the at least two n-type semiconductor materials, and both of the at least two n-type semiconductor materials contained in the active layer may be non-fullerene compounds.

In the present embodiment, the “n-type semiconductor material” may be two or more compounds represented by Formula (VIII), two or more compounds represented by Formula (IX), two or more compounds represented by Formula (X), or a combination of two or more compounds selected from the group consisting of a compound represented by Formula (VIII), a compound represented by Formula (IX), and a compound represented by Formula (X).

Specific examples of the case where both of the at least two n-type semiconductor materials are non-fullerene compounds include a combination of the compound N-1 and the compound N-2, a combination of the compound N-1 and the compound N-3, a combination of the compound N-1 and the compound N-4, a combination of the compound N-1 and the compound N-14, a combination of the compound N-1 and the compound N-17, and a combination of the compound N-14 and the compound N-17.

According to such a combination, in the heat treatment in the step of manufacturing the photoelectric conversion element, the step of incorporating the photoelectric conversion element in a device to which the photoelectric conversion element is applied, or the like, it is possible to suppress the deterioration of the EQE or further improve the EQE, and it is possible to further suppress the increase in dark current or further reduce the dark current so as to improve the balance thereof, thereby improving the heat resistance.

(ii) Fullerene Derivative

The n-type semiconductor material according to the present embodiment can contain a “fullerene derivative”. In the present embodiment, it is preferable that at least one of the at least two n-type semiconductor materials is a non-fullerene compound and the remaining n-type semiconductor material is a fullerene derivative. It is preferable that at least one of the two n-type semiconductor materials contained in the active layer is a non-fullerene compound and the other n-type semiconductor material is a fullerene derivative.

In the present embodiment, both of the at least two n-type semiconductor materials may be fullerene derivatives.

Here, the fullerene derivative refers to a compound in which at least a part of fullerene (C₆₀ fullerene, C₇₀ fullerene, C₇₆ fullerene, C₇₈ fullerene, and C₈₄ fullerene) is modified. In other words, the fullerene derivative refers to a compound to which one or more functional groups are added to a fullerene skeleton. Hereinafter, in particular, a fullerene derivative of C₆₀ fullerene may be referred to as a “C₆₀ fullerene derivative”, and a fullerene derivative of C₇₀ fullerene may be referred to as a “C₇₀ fullerene derivative”.

The fullerene derivative that can be used as the n-type semiconductor material in the present embodiment is not particularly limited as long as the object of the present invention is not impaired.

Specific examples of the C₆₀ fullerene derivative that can be used in the present embodiment include the following compounds.

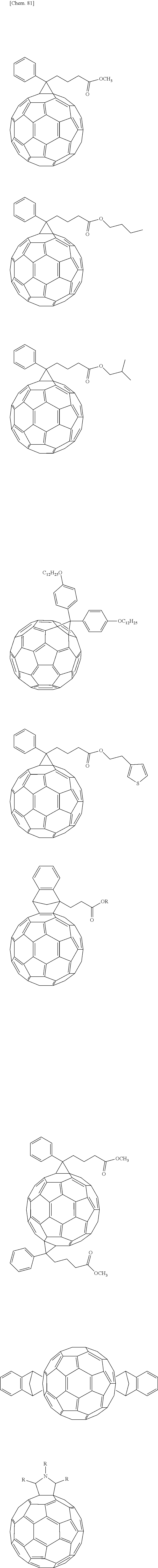

In the formulas, R is as defined above. In a case where the number of R's is plural, the plurality of R's may be the same as or different from each other.

Examples of the C₇₀ fullerene derivative include the following compounds.

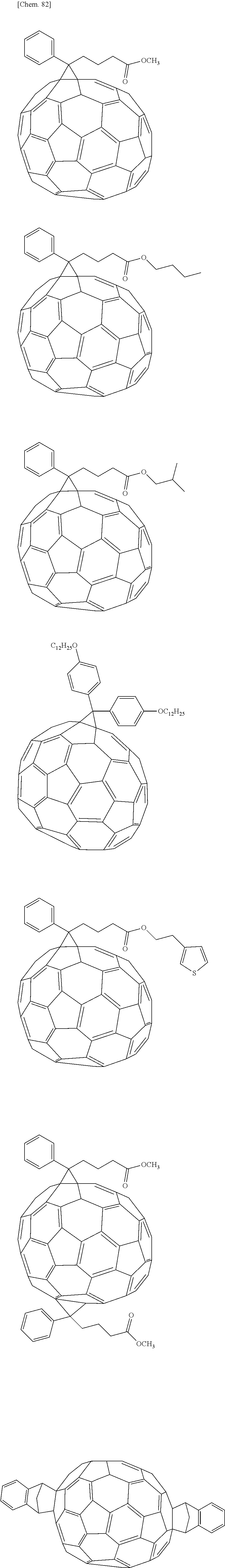

In the present embodiment, the fullerene derivative, which is the n-type semiconductor material, is preferably a compound N-18 ([C60]PCBM) or a compound N-19 ([C70]PCBM) represented by the following formula.

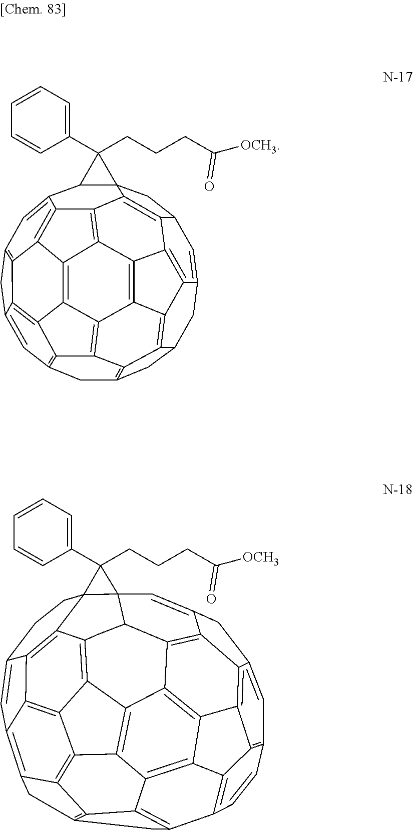 [SMILES: COC(=O)CCCC1(c2ccccc2)C2c3cc4c5c6c(cc7c8c9c%10c%11c%12c%13c%14c%15c(c%16c3c5c3c%16c%14c%12c9c3c68)C21CC%15C=C%13CC%11CC=%10C7)C4 ; COC(=O)CCCC1(c2ccccc2)C23CCc4cc5c6c7c8c9c(c%10ccc%11cc%12c%13c%14c%15c%16c%17c%18c(c2c4c5c%18c7c%17c9c2c%10c%11c%13c%162)CC%15C13C=C%14C%12)CC=8C6]

In the present embodiment, particularly, the active layer may contain only one fullerene derivative or two or more fullerene derivatives as the n-type semiconductor material.

Specific examples of the case where the at least two n-type semiconductor materials contain a non-fullerene compound and further contain a fullerene derivative include a combination of one or more of the compounds N-1 to N-17, which are the non-fullerene compounds described above, and one or more of the compounds N-18 and N-19.

In particular, from the viewpoint of suppressing aggregation or crystallization of the n-type semiconductor materials as fullerene derivatives and improving characteristics such as the EQE and the dark current so as to improve the heat resistance, a combination of the compound N-1 and the compound N-18, a combination of the compound N-1 and the compound N-19, a combination of the compound N-2 and the compound N-18, a combination of the compound N-2 and the compound N-19, a combination of the compound N-3 and the compound N-18, a combination of the compound N-3 and the compound N-19, a combination of the compound N-4 and the compound N-18, a combination of the compound N-4 and the compound N-19, a combination of the compound N-14 and the compound N-18, a combination of the compound N-14 and the compound N-19, a combination of the compound N-15 and the compound N-18, a combination of the compound N-15 and the compound N-19, a combination of the compound N-16 and the compound N-18, a combination of the compound N-16 and the compound N-19, a combination of the compound N-17 and the compound N-18, and a combination of the compound N-17 and the compound N-19 are preferable.

According to such a combination, the aggregation or crystallization of the n-type semiconductor materials is suppressed, such that in the heat treatment in the step of manufacturing the photoelectric conversion element, the step of incorporating the photoelectric conversion element in a device to which the photoelectric conversion element is applied, or the like, it is possible to suppress the deterioration of the EQE or further improve the EQE, and it is possible to further suppress the increase in dark current or further reduce the dark current so as to improve the balance thereof, thereby improving the heat resistance.

(Intermediate Layer)

As illustrated in FIG. 1, the photoelectric conversion element of the present embodiment preferably includes an intermediate layer (buffer layer) such as a charge transport layer (an electron transport layer, a hole transport layer, an electron injection layer, or a hole injection layer) as a constituent element for improving characteristics such as photoelectric conversion efficiency.

In addition, examples of a material used for the intermediate layer include a metal such as calcium, an inorganic oxide semiconductor such as molybdenum oxide or zinc oxide, and a mixture (PEDOT:PSS) of poly(3,4-ethylenedioxythiophene) (PEDOT) and poly(4-styrenesulfonate) (PSS).

As illustrated in FIG. 1, the photoelectric conversion element preferably includes a hole transport layer provided between the anode and the active layer. The hole transport layer has a function of transporting holes from the active layer to the electrode.

The hole transport layer provided in contact with the anode may be particularly referred to as a hole injection layer. The hole transport layer (hole injection layer) provided in contact with the anode has a function of promoting injection of holes into the anode. The hole transport layer (hole injection layer) may be in contact with the active layer.

The hole transport layer contains a hole transporting material. Examples of the hole transporting material include polythiophene and a derivative thereof, an aromatic amine compound, a polymer compound containing a structural unit having an aromatic amine residue, CuSCN, CuI, NiO, tungsten oxide (WO₃), and molybdenum oxide (MoO₃).

The intermediate layer can be formed by any suitable conventionally known formation method. The intermediate layer can be formed by a vacuum vapor deposition method or a coating method similar to that in the formation method of the active layer.

The photoelectric conversion element according to the present embodiment preferably has a configuration in which an intermediate layer is an electron transport layer, and a substrate (support substrate), an anode, a hole transport layer, an active layer, an electron transport layer, and a cathode are laminated in this order so as to be in contact with each other.

As illustrated in FIG. 1, the photoelectric conversion element of the present embodiment preferably includes an electron transport layer provided between the cathode and the active layer as the intermediate layer. The electron transport layer has a function of transporting electrons from the active layer to the cathode. The electron transport layer may be in contact with the cathode. The electron transport layer may be in contact with the active layer.

The electron transport layer provided in contact with the cathode may be particularly referred to as an electron injection layer. The electron transport layer (electron injection layer) provided in contact with the cathode has a function of promoting injection of electrons generated in the active layer into the cathode.

The electron transport layer contains an electron transporting material. Examples of the electron transporting material include polyalkyleneimine and a derivative thereof, a polymer compound having a fluorene structure, a metal such as calcium, and a metal oxide.

Examples of the polyalkyleneimine and the derivative thereof include a polymer obtained by polymerizing one or two or more of alkyleneimines having 2 to 8 carbon atoms, such as ethyleneimine, propyleneimine, butyleneimine, dimethylethyleneimine, pentyleneimine, hexyleneimine, heptyleneimine, and octyleneimine, particularly, alkyleneimines having 2 to 4 carbon atoms, by a normal method, and a polymer chemically modified by reacting these alkyleneimines with various compounds. As the polyalkyleneimine and the derivative thereof, polyethyleneimine (PEI) and ethoxylated polyethyleneimine (PEIE) are preferable.

Examples of the polymer compound having a fluorene structure include poly[(9,9-bis(3′-(N,N-dimethylamino)propyl)-2,7-fluoren)-ortho-2,7-(9,9′-dioctylfluorene)] (PFN) and PFN-P2.

Examples of the metal oxide include zinc oxide, gallium-doped zinc oxide, aluminum-doped zinc oxide, titanium oxide, and niobium oxide. As the metal oxide, a metal oxide containing zinc is preferable, and zinc oxide is particularly preferable.

Examples of other electron transporting materials include poly(4-vinylphenol) and perylene diimide.

(Sealing Member)

It is preferable that the photoelectric conversion element of the present embodiment further includes a sealing member and is a sealing body sealed by a sealing body.

Any suitable conventionally known member can be used as the sealing member. Examples of the sealing member include a combination of a glass substrate as a substrate (sealing substrate) and a sealing material (adhesive) as a UV curable resin.

The sealing member may be a sealing layer having a layer structure of one or more layers. Examples of the layer constituting the sealing layer include a gas barrier layer and a gas barrier film.

The sealing layer is preferably formed of a material having a property of blocking moisture (water vapor barrier property) or a property of blocking oxygen (oxygen barrier property). Examples of a preferred material as the material of the sealing layer include an organic material such as polyethylene trifluoride, polytrifluoroethylene chloride (PCTFE), polyimide, polycarbonate, polyethylene terephthalate, alicyclic polyolefin, or an ethylene vinyl alcohol copolymer, and an inorganic material such as silicon oxide, silicon nitride, aluminum oxide, or diamond-like carbon.

The sealing member is usually formed of a material that can withstand a heat treatment performed when the photoelectric conversion element is incorporated in a device to which the photoelectric conversion element is applied, for example, a device of the following application example.

(Applications of Photoelectric Conversion Element)

Examples of applications of the photoelectric conversion element of the present embodiment include a photodetector and a solar cell.

More specifically, the photoelectric conversion element of the present embodiment can allow a photocurrent to flow by irradiating light from the transparent or translucent electrode in a state in which a voltage (reverse bias voltage) is applied between the electrodes, and can be operated as a photodetector (photosensor). In addition, the photodetector can also be used as an image sensor by integrating a plurality of photodetectors. Such a photoelectric conversion element of the present embodiment can be particularly suitably used as a photodetector.

In addition, the photoelectric conversion element of the present embodiment can generate photovoltaic power between the electrodes by being irradiated with light, and can be operated as a solar cell. A solar cell module can also be formed by integrating a plurality of photoelectric conversion elements.

(Application Examples of Photoelectric Conversion Element)

The photoelectric conversion element according to the present embodiment can be suitably applied, as a photodetector, to a detection unit included in various electronic devices such as a workstation, a personal computer, a portable information terminal, an access management system, a digital camera, and a medical device.

The photoelectric conversion element of the present embodiment is included in the above-described exemplary electronic devices, and can be preferably applied to, for example, an image detection unit (for example, an image sensor such as an X-ray sensor) for a solid-state imaging device such as an X-ray imaging device or a CMOS image sensor, a detection unit (for example, a near-infrared sensor) of a biometric information authentication device that detects a predetermined feature of a part of a living body such as a fingerprint detection unit, a face detection unit, a vein detection unit, or an iris detection unit, and a detection unit of an optical biosensor such as a pulse oximeter.

The photoelectric conversion element of the present embodiment can also be suitably applied to a time-of-flight (TOF) type distance measuring device (TOF type distance measuring device) as an image detection unit for a solid-state imaging device.

In the TOF type distance measuring device, a distance is measured by allowing the photoelectric conversion element to receive reflected light obtained by reflection of light emitted from a light source on an object to be measured. Specifically, the distance to the object to be measured is determined by detecting the flight time until the irradiation light emitted from the light source is reflected by the object to be measured and returns as reflected light. The TOF type includes a direct TOF method and an indirect TOF method. In the direct TOF method, a difference between the time when light is emitted from the light source and the time when the reflected light is received by the photoelectric conversion element is directly measured, and in the indirect TOF method, a distance is measured by converting a change in charge accumulation amount depending on the flight time into a time change. As a distance measuring principle for obtaining a flight time by charge accumulation used in the indirect TOF method, there are a continuous wave (in particular, sinusoidal wave) modulation method and a pulse modulation method for obtaining a flight time from phases of light emitted from a light source and reflected light reflected by an object to be measured.

Hereinafter, among the detection units to which the photoelectric conversion element according to the present embodiment can be suitably applied, configuration examples of an image detection unit for a solid-state imaging device and an image detection unit for an X-ray imaging device, a fingerprint detection unit and a vein detection unit for a biometric authentication device (for example, a fingerprint authentication device, a vein authentication device, or the like), and an image detection unit of a TOF type distance measuring device (indirect TOF method) will be described with reference to the drawings.

(Image Detection Unit for Solid-State Imaging Device)

FIG. 2 is a view schematically illustrating a configuration example of an image detection unit for a solid-state imaging device.

An image detection unit 1 includes a CMOS transistor substrate 20, an interlayer insulating film 30 provided so as to cover the CMOS transistor substrate 20, a photoelectric conversion element 10 according to the embodiment of the present invention provided on the interlayer insulating film 30, an interlayer wiring portion 32 provided so as to penetrate through the interlayer insulating film 30 and electrically connecting the CMOS transistor substrate 20 and the photoelectric conversion element 10, a sealing layer 40 provided so as to cover the photoelectric conversion element 10, and a color filter 50 provided on the sealing layer 40.

The CMOS transistor substrate 20 is included in a form according to a design with any suitable conventionally known configuration.

The CMOS transistor substrate 20 includes a functional element such as a CMOS transistor circuit (MOS transistor circuit) for realizing various functions that includes a transistor, a capacitor, and the like formed in a thickness of the substrate.

Examples of the functional element include a floating diffusion, a reset transistor, an output transistor, and a selection transistor.

With such a functional element, a wiring, and the like, a signal reading circuit and the like are built in the CMOS transistor substrate 20.

The interlayer insulating film 30 can be formed of any suitable conventionally known insulating material such as silicon oxide or an insulating resin. The interlayer wiring portion 32 can be formed of any suitable conventionally known conductive material (wiring material) such as copper or tungsten. The interlayer wiring portion 32 may be, for example, an in-hole wiring simultaneously formed with formation of a wiring layer or a buried plug formed separately from the wiring layer.

The sealing layer 40 can be formed of any suitable conventionally known material under a condition in which permeation of harmful substances such as oxygen and water that may cause functional deterioration of the photoelectric conversion element 10 can be prevented or suppressed. The sealing layer 40 can have the same configuration as that of the sealing member 17 described above.

As the color filter 50, for example, a primary color filter formed of any suitable conventionally known material and corresponding to the design of the image detection unit 1 can be used. In addition, as the color filter 50, a complementary color filter capable of reducing the thickness as compared with the primary color filter can also be used. As the complementary color filter, for example, a color filter in which three types of (yellow, cyan, and magenta), three types of (yellow, cyan, and transparent), three types of (yellow, transparent, magenta), and three types of (transparent, cyan, and magenta) are combined can be used. This color filter can be arbitrarily preferably arranged corresponding to the design of the photoelectric conversion element 10 and the CMOS transistor substrate 20 on the condition that the color image data can be generated.

Light received by the photoelectric conversion element 10 through the color filter 50 is converted into an electrical signal according to the amount of received light by the photoelectric conversion element 10, and is output to the outside of the photoelectric conversion element 10 through the electrodes as a light reception signal, that is, an electrical signal corresponding to an imaging target.

Then, the light reception signal output from the photoelectric conversion element 10 is input to the CMOS transistor substrate 20 via the interlayer wiring portion 32, is read by the signal reading circuit built in the CMOS transistor substrate 20, and is subjected to signal processing by a further suitable conventionally known functional unit (not illustrated), such that image information is generated based on the imaging target.

(Fingerprint Detection Unit)

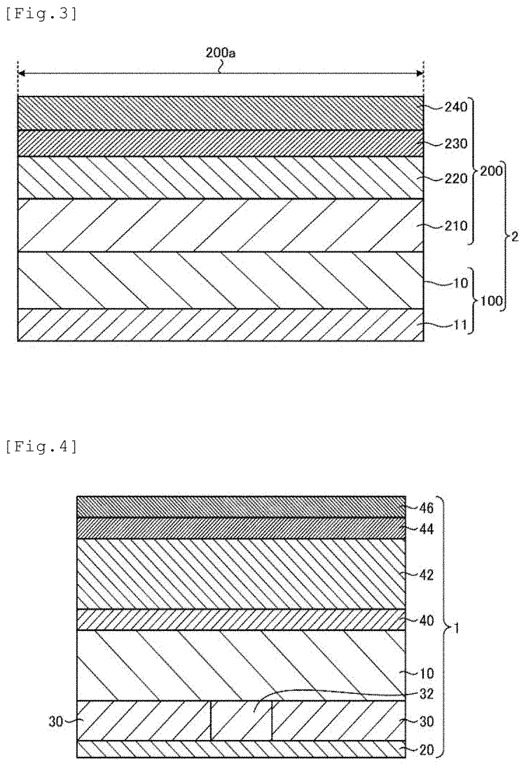

FIG. 3 is a view schematically illustrating a configuration example of a fingerprint detection unit integrally configured in a display device.

A display device 2 of a portable information terminal includes a fingerprint detection unit 100 including the photoelectric conversion element 10 according to the embodiment of the present invention as a main constituent element, and a display panel unit 200 provided on the fingerprint detection unit 100 and displaying a predetermined image.

In this configuration example, the fingerprint detection unit 100 is provided in an area coinciding with a display area 200a of the display panel unit 200. In other words, the display panel unit 200 is integrally laminated on the fingerprint detection unit 100.

In a case where the fingerprint detection unit is performed only in a partial area of the display area 200a, the fingerprint detection unit 100 may be provided corresponding to only the partial area.

The fingerprint detection unit 100 includes the photoelectric conversion element 10 according to the present embodiment of the present invention as a functional unit exhibiting an essential function. The fingerprint detection unit 100 can include any suitable conventionally known member such as a protection film, a support substrate, a sealing substrate, a sealing member, a barrier film, a bandpass filter, or an infrared cut film (not illustrated) in a form corresponding to a design that can obtain desired characteristics. The configuration of the image detection unit described above can also be adopted for the fingerprint detection unit 100.

The photoelectric conversion element 10 can be included in the display area 200a in any form. For example, a plurality of photoelectric conversion elements 10 may be arranged in a matrix.

As described above, the photoelectric conversion element 10 is provided on the support substrate 11, and electrodes (anode and cathode) are provided in the support substrate 11 in, for example, a matrix.

The light received by the photoelectric conversion element 10 is converted into an electrical signal according to the amount of received light by the photoelectric conversion element 10, and is output to the outside of the photoelectric conversion element 10 through the electrodes as a light reception signal, that is, an electrical signal corresponding to an imaged fingerprint.

In this configuration example, the display panel unit 200 is configured as an organic electroluminescent display panel (organic EL display panel) including a touch sensor panel. For example, instead of the organic EL display panel, the display panel unit 200 may be configured as a display panel having any suitable conventionally known configuration such as a liquid crystal display panel including a light source such as a backlight.

The display panel unit 200 is provided on the fingerprint detection unit 100 described above. The display panel unit 200 includes an organic electroluminescent element (organic EL element) 220 as a functional unit exhibiting an essential function. The display panel unit 200 may further include any suitable conventionally known member such as a substrate (a support substrate 210 or a sealing substrate 240) such as a suitable conventionally known glass substrate, a sealing member, a barrier film, a polarizing plate such as a circular polarizing plate, or a touch sensor panel 230, in a form corresponding to desired characteristics.

In the configuration examples described above, the organic EL element 220 is used as a light source of a pixel in the display area 200a, and is also used as a light source for imaging a fingerprint in the fingerprint detection unit 100.

Here, an operation of the fingerprint detection unit 100 will be briefly described.

At the time of executing fingerprint authentication, the fingerprint detection unit 100 detects a fingerprint using light emitted from the organic EL element 220 of the display panel unit 200. Specifically, the light emitted from the organic EL element 220 passes through a constituent element existing between the organic EL element 220 and the photoelectric conversion element 10 of the fingerprint detection unit 100, and is reflected by the skin (finger surface) of the fingertip of the finger placed so as to be in contact with a surface of the display panel unit 200 in the display area 200a. At least a part of the light reflected by the finger surface is transmitted through the constituent element existing between the organic EL element 220 and the photoelectric conversion element 10, and is converted into an electrical signal corresponding to the amount of light received by the photoelectric conversion element 10. Then, image information on the fingerprint of the finger surface is obtained from the converted electrical signal.

The portable information terminal including the display device 2 performs fingerprint authentication by comparing the obtained image information with previously recorded fingerprint data for fingerprint authentication by any suitable conventionally known step.

(Image Detection Unit for X-Ray Imaging Device)

FIG. 4 is a view schematically illustrating a configuration example of an image detection unit for an X-ray imaging device.

An image detection unit 1 for an X-ray imaging device includes a CMOS transistor substrate 20, an interlayer insulating film 30 provided so as to cover the CMOS transistor substrate 20, a photoelectric conversion element 10 according to the embodiment of the present invention provided on the interlayer insulating film 30, an interlayer wiring portion 32 provided so as to penetrate through the interlayer insulating film 30 and electrically connecting the CMOS transistor substrate 20 and the photoelectric conversion element 10, a sealing layer 40 provided so as to cover the photoelectric conversion element 10, a scintillator 42 provided on the sealing layer 40, a reflective layer 44 provided so as to cover the scintillator 42, and a protection layer 46 provided so as to cover the reflective layer 44.

The CMOS transistor substrate 20 is included in a form according to a design with any suitable conventionally known configuration.

The CMOS transistor substrate 20 includes a functional element such as a CMOS transistor circuit (MOS transistor circuit) for realizing various functions that includes a transistor, a capacitor, and the like formed in a thickness of the substrate.

Examples of the functional element include a floating diffusion, a reset transistor, an output transistor, and a selection transistor.

With such a functional element, a wiring, and the like, a signal reading circuit and the like are built in the CMOS transistor substrate 20.

The interlayer insulating film 30 can be formed of any suitable conventionally known insulating material such as silicon oxide or an insulating resin. The interlayer wiring portion 32 can be formed of any suitable conventionally known conductive material (wiring material) such as copper or tungsten. The interlayer wiring portion 32 may be, for example, an in-hole wiring simultaneously formed with formation of a wiring layer or a buried plug formed separately from the wiring layer.

The sealing layer 40 can be formed of any suitable conventionally known material under a condition in which permeation of harmful substances such as oxygen and water that may cause functional deterioration of the photoelectric conversion element 10 can be prevented or suppressed. The sealing layer 40 can have the same configuration as that of the sealing member 17 described above.

The scintillator 42 can be formed of any suitable conventionally known material corresponding to the design of the image detection unit 1 for an X-ray imaging device. Examples of the suitable material for the scintillator 42 include inorganic crystals of inorganic materials such as cesium iodide (CsI), sodium iodide (NaI), zinc sulfide (ZnS), gadolinium oxysulfide (GOS), and gadolinium silicate (GSO), organic crystals of organic materials such as anthracene, naphthalene, and stilbene, an organic liquid obtained by dissolving an organic material such as diphenyl oxazole (PPO) or terphenyl (TP) in an organic solvent such as toluene, xylene, and dioxane, gas such as xenon or helium, and plastic.

The constituent elements described above can be arranged in any suitable manner corresponding to the design of the photoelectric conversion element 10 and the CMOS transistor substrate 20 under a condition in which the scintillator 42 can convert the incident X-ray into light having a wavelength centered on the visible region to generate image data.

The reflective layer 44 reflects light converted by the scintillator 42. The reflective layer 44 can reduce a loss of the converted light and increase detection sensitivity. In addition, the reflective layer 44 can also block light directly incident from the outside.

The protection layer 46 can be formed of any suitable conventionally known material under a condition in which permeation of harmful substances such as oxygen and water that may cause functional deterioration of the scintillator 42 can be prevented or suppressed.

Here, the operation of the image detection unit 1 for an X-ray imaging device having the configuration described above will be briefly described.

When radiation energy such as X-rays or y-rays is incident on the scintillator 42, the scintillator 42 absorbs the radiation energy and converts the radiation energy into light (fluorescence) having a wavelength from ultraviolet to infrared regions centered on the visible region. Then, the light converted by the scintillator 42 is received by the photoelectric conversion element 10.

As described above, light received by the photoelectric conversion element 10 through the scintillator 42 is converted into an electrical signal according to the amount of received light by the photoelectric conversion element 10, and is output to the outside of the photoelectric conversion element 10 through the electrodes as a light reception signal, that is, an electrical signal corresponding to an imaging target. The radiation energy (X-ray) to be detected may be incident from either the scintillator 42 or the photoelectric conversion element 10.

Then, the light reception signal output from the photoelectric conversion element 10 is input to the CMOS transistor substrate 20 via the interlayer wiring portion 32, is read by the signal reading circuit built in the CMOS transistor substrate 20, and is subjected to signal processing by a further suitable conventionally known functional unit (not illustrated), such that image information is generated based on the imaging target.

(Vein Detection Unit)

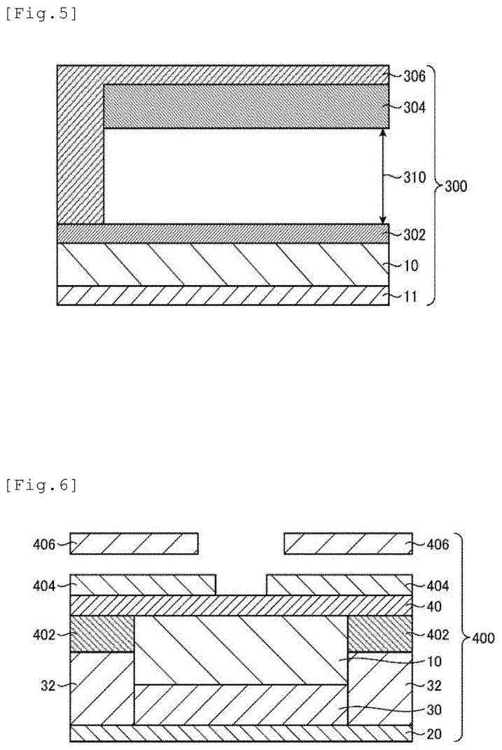

FIG. 5 is a view schematically illustrating a configuration example of a vein detection unit for a vein authentication device.

A vein detection unit 300 for a vein authentication device includes a cover portion 306 that partitions an insertion portion 310 into which a finger (for example, one or more fingertips, fingers, and palms) that is an object to be measured is inserted at the time of measurement, a light source portion 304 that is provided on the cover portion 306 and irradiates the object to be measured with light, a photoelectric conversion element 10 that receives the light emitted from the light source portion 304 through the object to be measured, a support substrate 11 that supports the photoelectric conversion element 10, and a glass substrate 302 that is arranged so as to face the support substrate 11 with the photoelectric conversion element 10 interposed therebetween, is spaced apart from the cover portion 306 at a predetermined distance, and partitions the insertion portion 306 together with the cover portion 306.

In this configuration example, the light source portion 304 is a transmission imaging system in which the light source portion is integrated with the cover portion 306 so as to be spaced apart from the photoelectric conversion element 10 with the object to be measured interposed therebetween during use, but the light source portion 304 is not necessarily located on the cover portion 306.

Under a condition in which the object to be measured can be efficiently irradiated with the light emitted from the light source portion 304, for example, a reflection imaging system of irradiating the object to be measured from the photoelectric conversion element 10 may be adopted.

The vein detection unit 300 includes the photoelectric conversion element 10 according to the present embodiment of the present invention as a functional unit exhibiting an essential function. The vein detection unit 300 can include any suitable conventionally known member such as a protection film, a sealing member, a barrier film, a bandpass filter, a near infrared transmission filter, a visible light cut film, or a finger placement guide (not illustrated) in a form corresponding to a design that can obtain desired characteristics. The configuration of the image detection unit 1 described above can also be adopted for the vein detection unit 300.

The photoelectric conversion element 10 can be included in any form. For example, a plurality of photoelectric conversion elements 10 may be arranged in a matrix.

As described above, the photoelectric conversion element 10 is provided on the support substrate 11, and electrodes (anode and cathode) are provided in the support substrate 11 in, for example, a matrix.

The light received by the photoelectric conversion element 10 is converted into an electrical signal according to the amount of received light by the photoelectric conversion element 10, and is output to the outside of the photoelectric conversion element 10 through the electrodes as a light reception signal, that is, an electrical signal corresponding to an imaged vein.

At the time of vein detection (at the time of use), the object to be measured may or may not be in contact with the glass substrate 302 provided on the photoelectric conversion element 10.

Here, an operation of the vein detection unit 300 will be briefly described.

At the time of vein detection, the vein detection unit 300 detects a vein pattern of the object to be measured using light emitted from the light source portion 304. Specifically, the light emitted from the light source portion 304 passes through the object to be measured and is converted into an electrical signal corresponding to the amount of light received by the photoelectric conversion element 10. Then, image information on the vein pattern of the object to be measured is obtained from the converted electrical signal.

In the vein authentication device, vein authentication is performed by comparing the obtained image information with the vein data for the vein authentication recorded in advance by any suitable conventionally known step.

(Image Detection Unit for TOF Type Distance Measuring Device)

FIG. 6 is a view schematically illustrating a configuration example of an image detection unit for an indirect time-of-flight (TOF) type distance measuring device.

An image detection unit 400 for a TOF type distance measuring device includes a CMOS transistor substrate 20, an interlayer insulating film 30 provided so as to cover the CMOS transistor substrate 20, a photoelectric conversion element 10 according to the embodiment of the present invention provided on the interlayer insulating film 30, two floating diffusion layers 402 arranged to be spaced from each other so as to interpose the photoelectric conversion element 10 therebetween, an insulating layer 40 provided so as to cover the photoelectric conversion element 10 and the floating diffusion layer 402, and two photo-gates 404 provided on the insulating layer 40 and arranged to be spaced apart from each other.

A part of the insulating layer 40 is exposed from a gap between the two photo-gates 404 spaced apart from each other, and the remaining region is shielded from light by a light shielding portion 406. The CMOS transistor substrate 20 and the floating diffusion layer 402 are electrically connected by an interlayer wiring portion 32 provided so as to penetrate the interlayer insulating film 30.

The interlayer insulating film 30 can be formed of any suitable conventionally known insulating material such as silicon oxide or an insulating resin. The interlayer wiring portion 32 can be formed of any suitable conventionally known conductive material (wiring material) such as copper or tungsten. The interlayer wiring portion 32 may be, for example, an in-hole wiring simultaneously formed with formation of a wiring layer or a buried plug formed separately from the wiring layer.

In this configuration example, the insulating layer 40 can have any suitable conventionally known configuration such as a field oxide film formed of silicon oxide.

The photo-gate 404 can be formed of any suitable conventionally known material such as polysilicon.

The image detection unit 400 for a TOF type distance measuring device includes the photoelectric conversion element 10 according to the embodiment of the present invention as a functional unit exhibiting an essential function. The image detection unit 400 for a TOF type distance measuring device can include any suitable conventionally known member such as a protection film, a support substrate, a sealing substrate, a sealing member, a barrier film, a bandpass filter, or an infrared cut film (not illustrated) in a form corresponding to a design that can obtain desired characteristics.

Here, an operation of the image detection unit 400 for a TOF type distance measuring device will be briefly described.

Light is emitted from a light source, the light emitted from the light source is reflected by an object to be measured, and the reflected light is received by the photoelectric conversion element 10. The two photo-gates 404 are provided between the photoelectric conversion element 10 and the floating diffusion layer 402, and pulses are alternately applied, such that signal charges generated by the photoelectric conversion element 10 are transferred to one of the two floating diffusion layers 402, and charges are accumulated in the floating diffusion layers 402. When light pulses arrive so as to spread equally with respect to the timing at which the two photo-gates 404 are opened, the amounts of charges accumulated in the two floating diffusion layers 402 become equal. When the light pulses arrive at the other photo-gate 404 later than the timing at which the light pulses arrive at the one photo-gate 404, a difference in the amounts of charges accumulated in the two floating diffusion layers 402 occurs.

The difference in the amount of charges accumulated in the floating diffusion layer 402 depends on the delay time of the light pulse. Since a distance L to the object to be measured has a relationship of L=(½)ctd using a round-trip time of light td and a velocity of light c, when the delay time can be estimated from the difference in the amounts of charges accumulated in the two floating diffusion layers 402, the distance to the object to be measured can be determined.

The amount of light received by the photoelectric conversion element 10 is converted into an electrical signal as the difference in the amounts of charges accumulated in the two floating diffusion layers 402, and is output to the outside of the photoelectric conversion element 10 as a light reception signal, that is, an electrical signal corresponding to the object to be measured.

Then, the light reception signal output from the floating diffusion layers 402 is input to the CMOS transistor substrate 20 via the interlayer wiring portion 32, is read by the signal reading circuit built in the CMOS transistor substrate 20, and is further subjected to signal processing by any suitable conventionally known functional unit (not illustrated), such that distance information is generated based on the object to be measured.

In the step of incorporating the photoelectric conversion element in a device according to the application example to which the photoelectric conversion element of the present embodiment is applied, for example, a heat treatment such as a reflow step for mounting the photoelectric conversion element on a wiring substrate or the like may be performed. For example, in manufacturing the image sensor, a step of heating the photoelectric conversion element at a heating temperature of 200° C. or higher may be performed.

According to the photoelectric conversion element of the present embodiment, as the material of the active layer, the at least one p-type semiconductor material satisfying the requirements (i) and (ii) and the at least two n-type semiconductor materials as described above are used. Therefore, in the step of forming the active layer (details will be described below), in the step of manufacturing the photoelectric conversion element after formation of the active layer, or in the step of incorporating the manufactured photoelectric conversion element in the image sensor or the biometric authentication device, even when the heat treatment is performed at a heating temperature of 200° C. or higher, the aggregation or crystallization of the n-type semiconductor materials is suppressed, or even when the heat treatment is performed at a heating temperature of 220° C. or higher, the deterioration of the EQE can be suppressed or the EQE can be further improved, the increase in dark current can be suppressed or the dark current can be further reduced, and thus, the heat resistance can be effectively improved.

Specifically, as for the EQE, based on a value of the EQE in the photoelectric conversion element when a heating temperature in the post-baking step in the step of forming the active layer in the method for manufacturing the photoelectric conversion element is set to 100° C., a value obtained by normalization by dividing by the value of the EQE of a photoelectric conversion element in which a heating temperature in a post-baking step is changed to a higher temperature of 200° C. or higher (for example, 200° C. or 220° C.) (hereinafter, referred to as “EQEₕₑₐₜ/EQE_{100° C.}”) is preferably 0.80 or more, more preferably 0.85 or more, and still more preferably 1.0 or more.

For example, EQEₕₑₐₜ/EQE_{100° C.} is preferably 0.80 or more, more preferably 0.85 or more, and still more preferably 1.0 or more, when the temperature in the post-baking step is set to 200° C. or 220° C. and the heating time is set to 1 hour.

In addition, as for the EQE of the sealing body of the photoelectric conversion element, based on a value of the EQE of the sealing body of the photoelectric conversion element that is not subjected to an additional heat treatment during the incorporating step, a value obtained by normalization by dividing the value of the EQE of the sealing body subjected to a heat treatment at 200° C. or higher (for example, 200° C. or 220° C.) (hereinafter, referred to as “EQEₕₑₐₜ/EQEᵤₙₕₑₐₜ”) is preferably 0.80 or more, more preferably 0.85 or more, and still more preferably 1.0 or more.

In the present embodiment, for example, EQEₕₑₐₜ/EQEᵤₙₕₑₐₜ is preferably 0.80 or more, more preferably 0.85 or more, and still more preferably 1.0 or more, when the temperature in the additional heat treatment is set to 200° C. and the heating time is set to 1 hour.

As for the dark current, based on a value of the dark current in the photoelectric conversion element when a heating temperature in the post-baking step is set to 100° C., a value obtained by normalization by dividing by the value of the dark current of the photoelectric conversion element in which the heating temperature in the post-baking step is changed to a higher temperature of 200° C. or higher (for example, 200° C. or 220° C.) (hereinafter, referred to as “dark currentₕₑₐₜ/dark current_{100° C.}”) is preferably 7.0 or less, more preferably 2.0 or less, and still more preferably 1.20 or less.

For example, dark currentₕₑₐₜ/dark current_{100° C.} is preferably 7.0 or less, more preferably 2.0 or less, and still more preferably 1.20 or less, when the temperature in the post-baking step is set to 200° C. or 220° C. and the heating time is set to 1 hour.

In addition, as for the dark current of the sealing body of the photoelectric conversion element, based on a value of the dark current of the sealing body of the photoelectric conversion element that is not subjected to an additional heat treatment during incorporation, a value obtained by normalization by dividing the value of the dark current of the sealing body subjected to a heat treatment at 200° C. or higher (for example, 200° C. or 220° C.) (hereinafter, referred to as “dark currentₕₑₐₜ/dark currentᵤₙₕₑₐₜ”) is preferably 7.0 or less, more preferably 2.0 or less, and still more preferably 1.20 or less.

In the present embodiment, for example, dark currentₕₑₐₜ/dark currentᵤₙₕₑₐₜ is preferably 7.0 or less, more preferably 2.0 or less, and still more preferably 1.20 or less, when the temperature in the additional heat treatment is set to 200° C. or 220° C. and the heating time is set to 1 hour.

2. Method for Manufacturing Photoelectric Conversion Element

The method for manufacturing the photoelectric conversion element of the present embodiment is not particularly limited. The photoelectric conversion element of the present embodiment can be manufactured by combining formation methods suitable for the selected materials to form constituent elements.

The method for manufacturing the photoelectric conversion element of the present embodiment can include a step including a heat treatment performed at a heating temperature of 200° C. or higher. More specifically, the method can include a step of forming an active layer by a step including a heat treatment performed at a heating temperature of 200° C. or higher or 220° C. or higher, and/or a step including a heat treatment performed at a heating temperature of 200° C. or higher or 220° C. or higher after the step of forming the active layer.

Hereinafter, as an embodiment of the present invention, a method for manufacturing the photoelectric conversion element having a configuration in which a substrate (support substrate), an anode, a hole transport layer, an active layer, an electron transport layer, and a cathode are in contact with each other in this order will be described.

(Step of Preparing Substrate)

In the present step, for example, a support substrate provided with an anode is prepared. In addition, it is possible to prepare a support substrate provided with an anode by obtaining a substrate provided with a conductive thin film formed of the electrode material described above from the market and patterning the conductive thin film to form the anode, if necessary.

In the method for manufacturing the photoelectric conversion element according to the present embodiment, the method for forming the anode in the case of forming the anode on the support substrate is not particularly limited. The anode can be formed on a structure (for example, a support substrate, an active layer, or a hole transport layer) in which the anode is to be formed by any suitable conventionally known method such as a vacuum vapor deposition method, a sputtering method, an ion-plating method, a plating method, or a coating method.

(Step of Forming Hole Transport Layer)

The method for manufacturing the photoelectric conversion element may include a step of forming a hole transport layer (hole injection layer) provided between the active layer and the anode.

A method for forming the hole transport layer is not particularly limited. From the viewpoint of further simplifying the step of forming the hole transport layer, it is preferable to form a hole transport layer by any suitable conventionally known coating method.

The hole transport layer can be formed, for example, by a coating method or a vacuum vapor deposition method using a coating solution containing the material for the hole transport layer described above and a solvent.

(Step of Forming Active Layer)

In the method for manufacturing the photoelectric conversion element of the present embodiment, an active layer is formed on the hole transport layer. The active layer, which is a main constituent element, can be formed by any suitable conventionally known forming step. In the present embodiment, the active layer is preferably produced by a coating method using an ink (coating solution).

Hereinafter, the step (i) and the step (ii) included in the step of forming the active layer, which is a main constituent element of the photoelectric conversion element of the present invention, will be described.

Step (i)

As a method for coating the ink to an object to be coated, any suitable coating method can be used.

As the coating method, a slit coating method, a knife coating method, a spin coating method, a micro-gravure coating method, a gravure coating method, a bar coating method, an inkjet printing method, a nozzle coating method, or a capillary coating method is preferable, a slit coating method, a spin coating method, a capillary coating method, or a bar coating method is more preferable, and a slit coating method or a spin coating method is still more preferable.

The ink for forming an active layer of the present embodiment will be described. Note that the ink for forming an active layer of the present embodiment is an ink for forming a bulk heterojunction type active layer. Therefore, the ink for forming an active layer preferably contains a composition containing the combination of the at least one p-type semiconductor material and the at least two n-type semiconductor materials described above. The ink for forming an active layer of the present embodiment preferably contains at least one or two or more solvents in addition to the composition.

The ink for forming an active layer of the present embodiment contains a combination of the at least one p-type semiconductor material satisfying the requirements (i) and (ii) described above and the at least two n-type semiconductor materials described above.

According to such a combination, the aggregation or crystallization of the n-type semiconductor materials is suppressed. As a result, from the viewpoint of improving characteristics such as the EQE and the dark current, in the heat treatment in the step of manufacturing the photoelectric conversion element, the step of incorporating the photoelectric conversion element in a device to which the photoelectric conversion element is applied, or the like, it is possible to suppress the deterioration of the EQE or further improve the EQE, and it is possible to further suppress the increase in dark current or further reduce the dark current so as to improve the balance thereof, thereby improving the heat resistance.

In the ink for forming an active layer according to the present embodiment, the mixed solvent obtained by combining a first solvent and a second solvent described above is preferably used as the solvent. Specifically, in a case where the ink for forming an active layer contains two or more solvents, it is preferable that the ink contains a main solvent (first solvent) as a main component and another additional solvent (second solvent) added for improving solubility and the like.

Hereinafter, the combination of the first solvent and the second solvent that can be preferably used in the ink for forming an active layer of the present embodiment will be described.

(1) First Solvent

The first solvent is preferably a solvent in which the p-type semiconductor material can be dissolved. The first solvent of the present embodiment is an aromatic hydrocarbon.

Examples of the aromatic hydrocarbon, which is the first solvent, include toluene, xylene (for example, o-xylene, m-xylene, or p-xylene), o-dichlorobenzene, trimethylbenzene (for example, mesitylene or 1,2,4-trimethylbenzene (pseudocumene)), butylbenzene (for example, n-butylbenzene, sec-butylbenzene, or tert-butylbenzene), methylnaphthalene (for example, 1-methylnaphthalene), tetralin, and indane.

The first solvent may be composed of only one aromatic hydrocarbon or two or more aromatic hydrocarbons. The first solvent is preferably composed of one aromatic hydrocarbon.

The first solvent is preferably one or more selected from the group consisting of toluene, o-xylene, m-xylene, p-xylene, mesitylene, o-dichlorobenzene, 1,2,4-trimethylbenzene, n-butylbenzene, sec-butylbenzene, tert-butylbenzene, methylnaphthalene, tetralin, and indane, and is more preferably toluene, o-xylene, m-xylene, p-xylene, o-dichlorobenzene, mesitylene, 1,2,4-trimethylbenzene, n-butylbenzene, sec-butylbenzene, tert-butylbenzene, methylnaphthalene, tetralin, or indane.

(2) Second Solvent

The second solvent is a solvent selected from the viewpoint of further facilitating execution of the manufacturing step and further improving the characteristics of the photoelectric conversion element. Examples of the second solvent include ketone solvents such as acetone, methyl ethyl ketone, cyclohexanone, acetophenone, and propiophenone, and ester solvents such as ethyl acetate, butyl acetate, phenyl acetate, ethyl cellosolve acetate, methyl benzoate, butyl benzoate, and benzyl benzoate.

The second solvent is preferably acetophenone, propiophenone, or butyl benzoate from the viewpoint of reducing the dark current.

(3) Combination of First Solvent and Second Solvent

Examples of a preferred combination of the first solvent and the second solvent include combinations of tetralin and ethyl benzoate, tetralin and propyl benzoate, and tetralin and butyl benzoate, and more preferably a combination of tetralin and butyl benzoate.

(4) Weight Ratio of First Solvent to Second Solvent

A weight ratio of the first solvent, which is a main solvent, to the second solvent, which is an additional solvent, (first solvent:second solvent) is preferably 85:15 to 99:1 from the viewpoint of further improving solubility of each of the n-type semiconductor material and the p-type semiconductor material.

(5) Any Other Solvents

The solvent may include any other solvents in addition to the first solvent and the second solvent. When the total weight of all the solvents contained in the ink is 100% by weight, a content of the any other solvents is preferably 5% by weight or less, more preferably 3% by weight or less, and still more preferably 1% by weight or less. As the any other solvents, a solvent having a boiling point higher than that of the second solvent is preferable.

(6) Optional Components

In addition to the first solvent, the second solvent, the n-type semiconductor material, and the p-type semiconductor material, the ink may contain optional components such as a surfactant, an ultraviolet absorber, an antioxidant, a sensitizer for sensitizing a function of generating a charge by absorbed light, and a light stabilizer for increasing stability from ultraviolet light as long as the object and effect of the present invention are not impaired.

(7) Concentration of Each of p-Type Semiconductor Material and n-Type Semiconductor Material

A concentration of each of the at least one p-type semiconductor material and the at least two n-type semiconductor materials in the ink (composition) can be set to any suitable concentration within a range in which the object of the present invention is not impaired in consideration of solubility in the solvent and the like.

A weight ratio of the “at least one p-type semiconductor material” to the “at least two n-type semiconductor materials” in the ink (composition) (for example, polymer/non-fullerene compound) is usually 1/0.1 to 1/10, preferably 1/0.5 to 1/2, and more preferably 1/1.5.

The total concentration of the “at least one p-type semiconductor material” and the “at least two n-type semiconductor materials” in the ink is usually 0.01% by weight or more, more preferably 0.02% by weight or more, and still more preferably 0.25% by weight or more. In addition, the total concentration of the “at least one p-type semiconductor material” and the “at least two n-type semiconductor materials” in the ink is usually 20% by weight or less, preferably 10% by weight or less, and more preferably 7.50% by weight or less.

The concentration of the “at least one p-type semiconductor material” in the ink is usually 0.01% by weight or more, more preferably 0.02% by weight or more, and still more preferably 0.10% by weight or more.

In addition, the concentration of the “at least one p-type semiconductor material” in the ink is usually 10% by weight or less, more preferably 5.00% by weight or less, and still more preferably 3.00% by weight or less.

The concentration of the “at least two n-type semiconductor materials” in the ink is usually 0.01% by weight or more, more preferably 0.02% by weight or more, and still more preferably 0.15% by weight or more.

In addition, the concentration of the “at least two n-type semiconductor materials” in the ink is usually 10% by weight or less, more preferably 5% by weight or less, and still more preferably 4.50% by weight or less.

In the present embodiment, as a result of using the at least one p-type semiconductor material satisfying the requirements (i) and (ii) described above and the at least two n-type semiconductor materials, the deterioration of the EQE can be suppressed and the dark current can be reduced, thereby improving the heat resistance. Therefore, a solvent having a higher boiling point can also be used as the solvent. Thus, since the range of choices of raw materials in the step of manufacturing the photoelectric conversion element is widened, the photoelectric conversion element can be more simply and easily manufactured.

(8) Preparation of Ink

The ink can be prepared by a known method. For example, the ink can be prepared by a method for preparing a mixed solvent by mixing a first solvent and a second solvent and adding a p-type semiconductor material and an n-type semiconductor material to the obtained mixed solvent, a method of adding a p-type semiconductor material to a first solvent, adding an n-type semiconductor material to a second solvent, and then mixing the first solvent and the second solvent to which the respective materials are added, or the like.

The first solvent, the second solvent, the p-type semiconductor material, and the n-type semiconductor material may be heated to a temperature equal to or higher than the boiling point of the solvent to be mixed.

After the first solvent, the second solvent, the n-type semiconductor material, and the p-type semiconductor material are mixed, the obtained mixture may be filtered using a filter, and the obtained filtrate may be used. As the filter, for example, a filter formed of a fluororesin such as polytetrafluoroethylene (PTFE) can be used.

The ink for forming an active layer is coated to an object to be coated selected according to the photoelectric conversion element and the method for manufacturing the same. The ink for forming an active layer can be coated to a functional layer of the photoelectric conversion element in which the active layer can be present in the step of manufacturing the photoelectric conversion element. Therefore, the object to be coated with the ink for forming an active layer varies depending on the layer configuration of the manufactured photoelectric conversion element and the layer formation order. For example, in a case where the photoelectric conversion element has a layer configuration in which a substrate, an anode, a hole transport layer, an active layer, an electron transport layer, and a cathode are laminated and the layer disposed on the left side is formed first, the object to be coated with the ink for forming an active layer is the hole transport layer. In addition, for example, in a case where the photoelectric conversion element has a layer configuration in which a substrate, a cathode, an electron transport layer, an active layer, a hole transport layer, and an anode are laminated and the layer disposed on the left side is formed first, the object to be coated with the ink for forming an active layer is the electron transport layer.

Step (ii)

As a method for removing the solvent from the coating film of the ink, that is, a method for removing the solvent from the coating film and solidifying the coating film, any preferred method can be used. Examples of the method for removing the solvent include drying methods such as a direct heating method using a hot plate under an inert gas atmosphere such as nitrogen gas, a hot air drying method, an infrared heating drying method, a flash lamp annealing drying method, and a reduced pressure drying method.

In the method for manufacturing the photoelectric conversion element of the present embodiment, the step (ii) is a step for volatilizing and removing the solvent, and is also referred to as a pre-baking step (first heat treatment step). In the method for manufacturing the photoelectric conversion element according to the present embodiment, it is preferable to perform, after the step (ii), a post-baking step (second heat treatment step) that is performed subsequently to the pre-baking step so as to form a solidified film by a heat treatment.

The conditions for performing the pre-baking step and the post-baking step, that is, the conditions such as the heating temperature and the heat treatment time can be set to any preferred conditions in consideration of the composition of the ink to be used, the boiling point of the solvent, and the like.

In the method for manufacturing the photoelectric conversion element according to the present embodiment, specifically, for example, a pre-baking step and a post-baking step can be performed using a hot plate in a nitrogen gas atmosphere.

The heating temperature in each of the pre-baking step and the post-baking step is usually about 100° C.

However, in the method for manufacturing the photoelectric conversion element according to the present embodiment, as a result of containing the at least one p-type semiconductor material and the at least two n-type semiconductor materials described above as the materials of the active layer, the heating temperature in the pre-baking step and/or the post-baking step can be further increased. Specifically, the heating temperature in the pre-baking step and/or the post-baking step can be preferably 200° C. or higher and more preferably 220° C. or higher. An upper limit of the heating temperature is preferably 300° C. or lower and more preferably 250° C. or lower.

The total heat treatment time in the pre-baking step and the post-baking step can be, for example, 1 hour.

The heating temperature in the pre-baking step and the heating temperature in the post-baking step may be the same as or different from each other.

The heat treatment time can be, for example, 10 minutes or longer. An upper limit value of the heat treatment time is not particularly limited, and can be, for example, 4 hours, in consideration of tact time and the like.

A thickness of the active layer can be set to any preferred predetermined thickness by appropriately adjusting the solid content concentration in the coating solution and the conditions of the step (i) and/or the step (ii).

The step of forming the active layer may include other steps in addition to the step (i) and the step (ii) as long as the object and the effect of the present invention are not impaired.

The method for manufacturing the photoelectric conversion element of the present embodiment may be a method for manufacturing a photoelectric conversion element including a plurality of active layers or a method in which a step (i) and a step (ii) are repeated a plurality of times.

(Step of Forming Electron Transport Layer)

The method for manufacturing the photoelectric conversion element of the present embodiment may include a step of forming an electron transport layer (electron injection layer) provided on the active layer.

A method for forming the electron transport layer is not particularly limited. From the viewpoint of further simplifying the step of forming the electron transport layer, it is preferable to form an electron transport layer by any suitable conventionally known vacuum vapor deposition method.

(Step of Forming Cathode)

A method for forming the cathode is not particularly limited. The cathode can be formed on the electron transport layer using the electrode material exemplified above by any suitable conventionally known method such as a coating method, a vacuum vapor deposition method, a sputtering method, an ion-plating method, or a plating method. Through the steps described above, the photoelectric conversion element of the present embodiment is manufactured.

(Step of Forming Sealing Body)

In the present embodiment, when forming a sealing body, any suitable conventionally known sealing material (adhesive) and substrate (sealing substrate) are used. Specifically, a sealing material such as a UV curable resin is applied onto the support substrate so as to surround the periphery of the manufactured photoelectric conversion element, and bonding is performed with the sealing material without a gap, and then, the photoelectric conversion element is sealed in a gap between the support substrate and the sealing substrate using a method suitable for the selected sealing material such as irradiation with UV rays, such that a sealing body of the photoelectric conversion element can be obtained.

3. Methods for Manufacturing Image Sensor and Biometric Authentication Device

In particular, a photodetector, which is the photoelectric conversion element of the present embodiment, can function by being incorporated in the image sensor and the biometric authentication device as described above.

The image sensor or the biometric authentication device can be manufactured by a manufacturing method including a step of heating the photoelectric conversion element (the sealing body of the photoelectric conversion element) at a heating temperature of 200° C. or higher.

Specifically, in the step of incorporating the photoelectric conversion element in the image sensor or the biometric authentication device, for example, a reflow step performed when the photoelectric conversion element is mounted on a wiring substrate or the like is performed, such that the heat treatment performed at a heating temperature of 200° C. or higher or further 220° C. or higher can be performed.

However, according to the photoelectric conversion element of the present embodiment, as a material of the active layer, the n-type semiconductor material described above is used. As a result, the deterioration of the EQE of the incorporated photoelectric conversion element can be suppressed or the EQE can be further improved, and the increase in dark current can be suppressed or the dark current can be reduced, thereby effectively improving the heat resistance. Therefore, the characteristics such as detection accuracy in the manufactured image sensor and the biometric authentication device can be improved.

The heat treatment time can be, for example, 10 minutes or longer. An upper limit value of the heat treatment time is not particularly limited, and can be, for example, 4 hours, in consideration of tact time and the like.

### EXAMPLES

Hereinafter, Examples will be shown in order to describe the present invention in more detail. The present invention is not limited to the examples described below.

In the present Examples, the p-type semiconductor materials (electron donating compounds) shown in Tables 1 and 2 and the n-type semiconductor materials (electron accepting compounds) shown in Tables 3 and 4 were used.

TABLE 1

| | Polymer | |
|---|---|---|
| | compound | Chemical structure |
| p-type semiconductor material | P-1 | 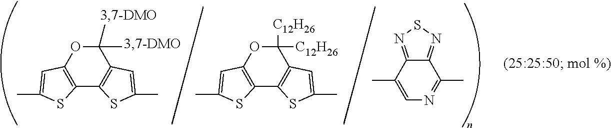 |
| | | 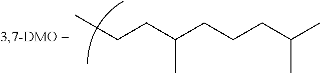 |
| | P-2 | 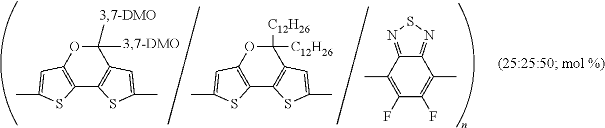 |
| | | 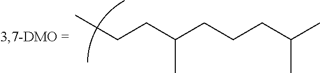 |
| | P-3 | 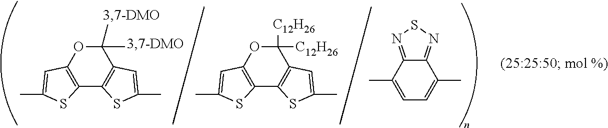 |
| | | 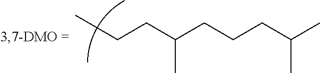 |
| | P-4 | 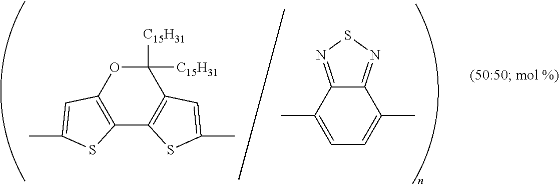 |

TABLE 2

| | Polymer | |
|---|---|---|
| | compound | Chemical structure |
| p-type semiconductor material | P-5 | 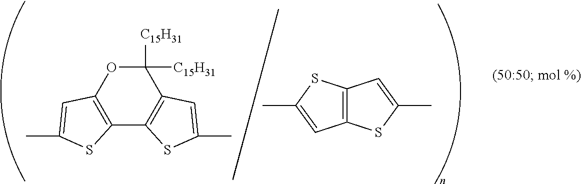 |
| | P-13 | 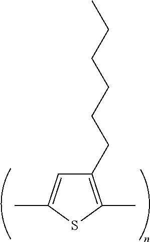 |
| | P-14 | 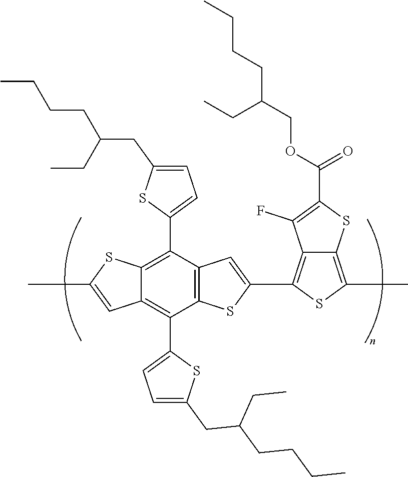 |

TABLE 3

| | Compound | Chemical structure |
|---|---|---|
| n-type semiconductor material | N-1 | 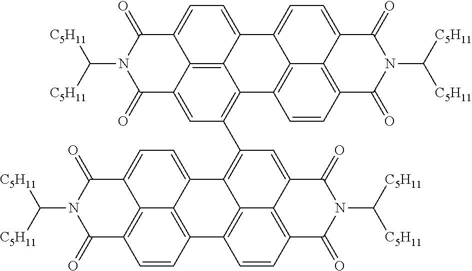 |
| | N-2 | 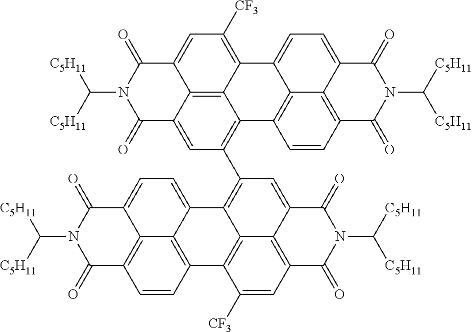 |
| | N-14 | 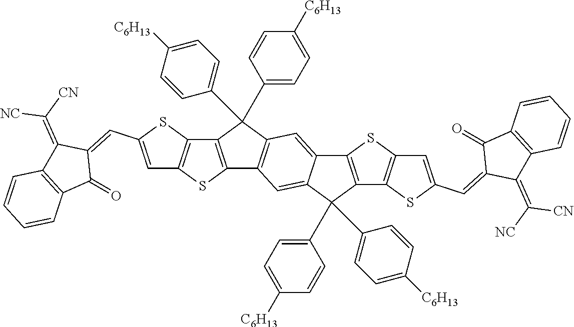 |
| | N-15 | 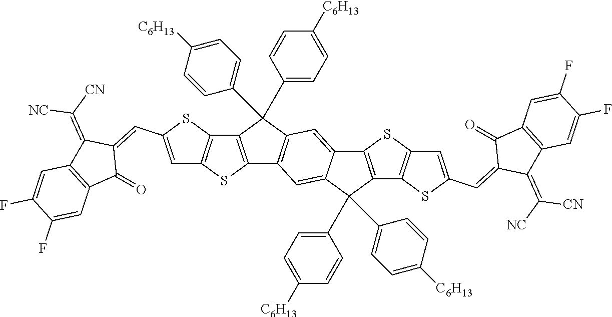 |

TABLE 4

| | Compound | Chemical structure |
|---|---|---|
| n-type semiconductor material | N-16 | 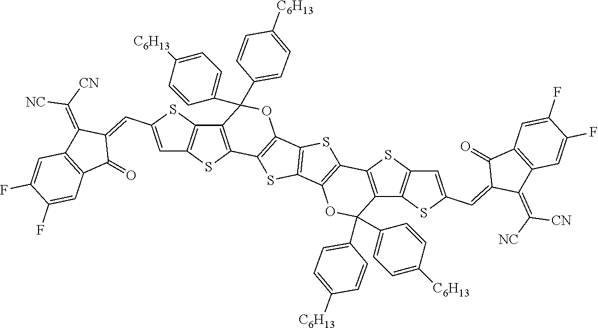 |
| | N-17 | 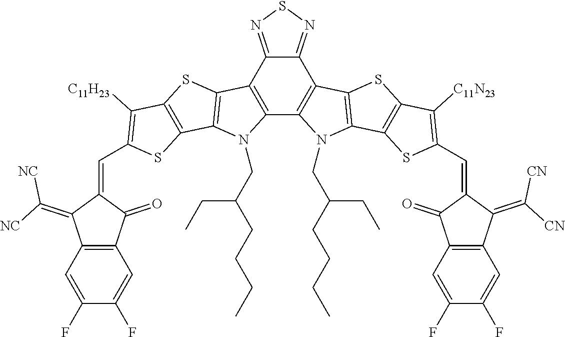 |
| | N-18 | 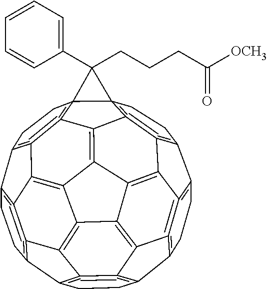 |
| | N-19 | 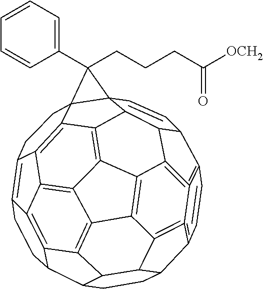 |

The polymer compound P-1, which was the p-type semiconductor material, was synthesized with reference to the method described in WO 2011/052709 A and used.

The polymer compound P-2, which was the p-type semiconductor material, was synthesized with reference to the method described in WO 2013/051676 A and used.

The polymer compound P-3, which was the p-type semiconductor material, was synthesized with reference to the method described in WO 2011/052709 A and used.

The polymer compound P-4, which was the p-type semiconductor material, was synthesized with reference to the method described in WO 2014/31364 A and used.

The polymer compound P-5, which was the p-type semiconductor material, was synthesized with reference to the method described in WO 2014/31364 A and used.

As the polymer compound P-13, which was the p-type semiconductor material, P3HT (trade name, manufactured by Sigma-Aldrich) was obtained from the market and used.

As the polymer compound P-14, which was the p-type semiconductor material, PCE10/PTB7-Th (trade name, manufactured by 1-Material Inc.) was obtained from the market and used.

As the compound N-1, which was the n-type semiconductor material, diPDI (trade name, manufactured by 1-Material Inc.) was obtained from the market and used.

The compound N-2 (diPDI(C11)-2CF3), which was the n-type semiconductor material, was synthesized and used as in Synthesis Example 1 to be described below.

As the compound N-14, which was the n-type semiconductor material, ITIC (trade name, manufactured by 1-Material Inc.) was obtained from the market and used.

As the compound N-15, which was the n-type semiconductor material, ITIC-4F (trade name, manufactured by 1-Material Inc.) was obtained from the market and used.

As the compound N-16, which was the n-type semiconductor material, COi8DFIC (trade name, manufactured by 1-Material Inc.) was obtained from the market and used.

As the compound N-17, which was the n-type semiconductor material, Y6 (trade name, manufactured by 1-Material Inc.) was obtained from the market and used.

As the compound N-18, which was the n-type semiconductor material, E100 (trade name, manufactured by Frontier Carbon Corporation) was obtained from the market and used.

As the compound N-19, which was the n-type semiconductor material, [C70]PCBM (trade name, manufactured by Nano-C, Inc.) was obtained from the market and used.

Here, Table 5 shows the values of the dispersive energy (δD), the polarization energy (δP), and the hydrogen bond energy (δH), which are components of the Hansen solubility parameters (HSPs) of the p-type semiconductor material and the n-type semiconductor material used in Examples.

TABLE 5

| | | Hansen solubility parameter | | |
|---|---|---|---|---|
| | Compound | δD [MPa^{0.5}] | δP [MPa^{0.5}] | δH [MPa^{0.5}] |
| p-type | P-1 | 18.57 | 3.99 | 4.80 |
| semiconductor | P-2 | 18.33 | 3.17 | 4.80 |
| material | P-3 | 18.58 | 3.20 | 4.90 |
| | P-4 | 18.37 | 3.57 | 4.55 |
| | P-5 | 18.51 | 2.80 | 5.93 |
| | P-13 | 17.51 | 2.49 | 4.39 |
| | P-14 | 19.46 | 3.54 | 6.84 |
| | P-1 + P-2 | 18.45 | 3.58 | 4.80 |
| n-type | N-1 | 20.32 | 1.64 | 2.13 |
| semiconductor | N-2 | 20.01 | 1.49 | 1.72 |
| material | N-14 | 20.74 | 8.70 | 5.90 |
| | N-15 | 20.35 | 9.05 | 6.03 |
| | N-16 | 20.63 | 6.49 | 6.09 |
| | N-17 | 19.61 | 6.75 | 5.21 |
| | N-18 | 21.42 | 1.19 | 3.27 |
| | N-19 | 21.55 | 1.12 | 3.23 |

Note that in Table 5, the Hansen solubility parameters of the mixture (P-1+P-2) of the polymer compound P-1 and the polymer compound P-2 as the p-type semiconductor materials when the weight ratio thereof was 1:1 (both the weight fractions were 0.5) were calculated as described above, for example, δD was calculated as in the following equation (δP and δH were also calculated in the same manner).

δD(P-1+P-2)=δD(P-1)×Weight Fraction (0.5)+δD(P-2)×Weight Fraction (0.5)=18.45

### <Synthesis Example 1> (Synthesis of Compound N-2)

A compound 2 (compound N-2) represented by the following formula was synthesized from a compound 1 represented by the following formula.

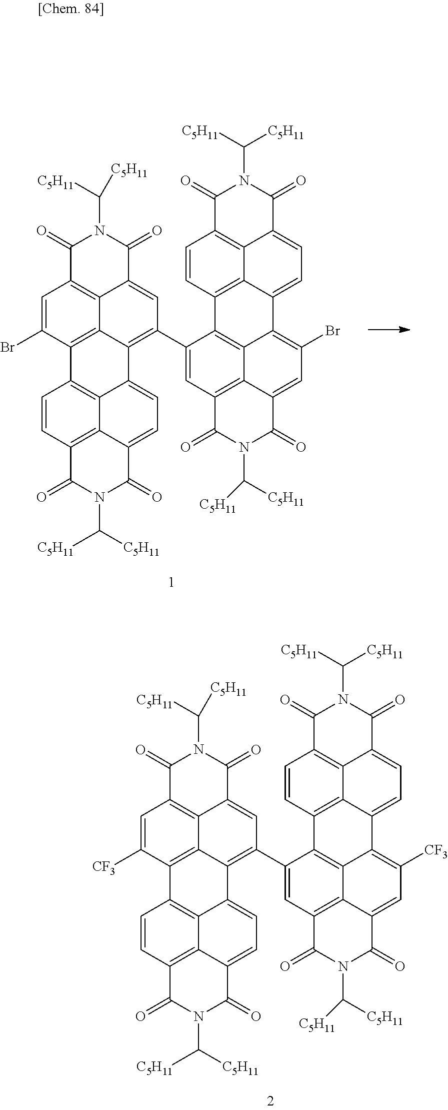

In a 100 mL three-necked flask in which the internal atmosphere was replaced with nitrogen gas, 295 mg (0.190 mmol) of the compound 1 synthesized by the method described in J. Mater. Chem. C, 2016, 4, 4134-4137, 107 mg of (0.399 mmol) of 4,4′-di-tert-butyl-2,2′-bipyridyl, 367 mg (0.399 mmol) of (trifluoromethyl)tris(triphenylphosphine)copper(I), and 15 mL of dehydrated toluene were placed to obtain a solution.

The obtained solution was reacted while being heated and stirred at 80° C. (bath temperature) for 8 hours. After completion of the reaction, the obtained reaction solution was cooled to room temperature, and the cooled reaction solution was separated and washed with each of water and 10% acetic acid water.

The organic layer obtained by the separation washing was dried with anhydrous magnesium sulfate, filtration was performed, and the solvent was distilled off under reduced pressure, thereby obtaining a crude product. The obtained crude product was purified with a silica gel column to obtain 228 mg (0.149 mmol, a yield of 78.4%) of a target compound 2 as a blackish brown solid.

An NMR spectrum of the obtained compound 2 was analyzed. The results are as follows.

[1H NMR (400 MHz, CDCl3)]

δ 9.10 (br, 2H), 8.78 (br, 2H), 8.67 (m, 2H), 8.27 (m, 6H), 5.13 (br, 4H), 2.16 (br, 8H), 1.78 (br, 8H), 1.21 (br, 48H), 0.78 (t, 24H).

[19F NMR (400 MHz, CDCl3)]

δ −55.1

### <Preparation Example 1> (Preparation of Ink I-1)

A mixed solvent was prepared using tetralin as a first solvent and butyl benzoate as a second solvent at a volume ratio of the first solvent to the second solvent of 97:3.

The obtained mixed solvent was mixed with the polymer compound P-1 as a p-type semiconductor material, the compound N-1 (first n-type semiconductor material) as an n-type semiconductor material, and further the compound N-18 (second n-type semiconductor material) as an n-type semiconductor material so that a concentration of the polymer compound P-1 was 1.5% by weight with respect to the total weight of the ink, a concentration of the compound N-1 was 1.125% by weight with respect to the total weight of the ink, and a concentration of the compound N-18 was 1.125% by weight with respect to the total weight of the ink (p-type semiconductor material/n-type semiconductor materials=1/1.5), and a mixed solution obtained by stirring the mixture at 60° C. for 8 hours was filtered using a filter, thereby obtaining an ink (I-1).

### Preparation Examples 2 to 8 and 14

Inks (I-2) to (I-8) and (I-14) were prepared in the same manner as that of Preparation Example 1, except that the p-type semiconductor material and the n-type semiconductor materials were used in the combination as shown in Table 6.

### Preparation Example 9

Ortho-dichlorobenzene was mixed with the polymer compound P-3 as a p-type semiconductor material, the compound N-1 (first n-type semiconductor material) as an n-type semiconductor material, and further the compound N-18 (second n-type semiconductor material) as an n-type semiconductor material so that a concentration of the polymer compound P-3 was 1.2% by weight with respect to the total weight of the ink, a concentration of the compound N-1 was 0.9% by weight with respect to the total weight of the ink, and a concentration of the compound N-18 was 0.9% by weight with respect to the total weight of the ink (p-type semiconductor material/n-type semiconductor materials=1/1.5), and a mixed solution obtained by stirring the mixture at 60° C. for 8 hours was filtered using a filter, thereby obtaining an ink (I-9).

### Preparation Example 10

Ortho-dichlorobenzene was mixed with the polymer compound P-4 as a p-type semiconductor material, the compound N-1 (first n-type semiconductor material) as an n-type semiconductor material, and further the compound N-18 (second n-type semiconductor material) as an n-type semiconductor material so that a concentration of the polymer compound P-4 was 0.5% by weight with respect to the total weight of the ink, a concentration of the compound N-1 was 0.375% by weight with respect to the total weight of the ink, and a concentration of the compound N-18 was 0.375% by weight with respect to the total weight of the ink (p-type semiconductor material/n-type semiconductor materials=1/1.5), and a mixed solution obtained by stirring the mixture at 60° C. for 8 hours was filtered using a filter, thereby obtaining an ink (I-10).

### Preparation Example 11

An ink (I-11) was prepared in the same manner as that of Preparation Example 10, except that the p-type semiconductor material and the n-type semiconductor materials were used in the combination as shown in Table 6.

### Preparation Example 12

An ink (I-12) was prepared in the same manner as that of Preparation Example 1, except that the polymer compound P-1 as a p-type semiconductor material, the compound N-1 (first n-type semiconductor material) as an n-type semiconductor material, and further the compound N-18 (second n-type semiconductor material) as an n-type semiconductor material were mixed so that a concentration of the polymer compound P-1 was 1.5% by weight with respect to the total weight of the ink, a concentration of the compound N-1 was 2.04% by weight with respect to the total weight of the ink, and a concentration of the compound N-18 was 0.21% by weight with respect to the total weight of the ink (p-type semiconductor material/n-type semiconductor materials=1/1.5).

### Preparation Example 13

An ink (I-13) was prepared in the same manner as that of Preparation Example 1, except that the polymer compound P-1 as a p-type semiconductor material, the compound N-1 (first n-type semiconductor material) as an n-type semiconductor material, and further the compound N-18 (second n-type semiconductor material) as an n-type semiconductor material were mixed so that a concentration of the polymer compound P-1 was 1.5% by weight with respect to the total weight of the ink, a concentration of the compound N-1 was 1.875% by weight with respect to the total weight of the ink, and a concentration of the compound N-18 was 0.375% by weight with respect to the total weight of the ink (p-type semiconductor material/n-type semiconductor materials=1/1.5).

### Preparation Example 15

An ink (I-15) was prepared in the same manner as that of Preparation Example 1, except that the polymer compound P-1 (first p-type semiconductor material) as a p-type semiconductor material, the polymer compound P-2 (second p-type semiconductor material) as a p-type semiconductor material, the compound N-1 (first n-type semiconductor material) as an n-type semiconductor material, and further the compound N-18 (second n-type semiconductor material) as an n-type semiconductor material were mixed so that a concentration of the polymer compound P-1 was 0.7% by weight with respect to the total weight of the ink, a concentration of the polymer compound P-2 was 0.7% by weight with respect to the total weight of the ink, a concentration of the compound N-1 was 1.1% by weight with respect to the total weight of the ink, and a concentration of the compound N-18 was 1.1% by weight with respect to the total weight of the ink (p-type semiconductor materials/n-type semiconductor materials=1/1.57).

### Comparative Preparation Example 1

An ink (C-1) was prepared in the same manner as that of Preparation Example 1, except that the polymer compound P-13 as a p-type semiconductor material, the compound N-14 (first n-type semiconductor material) as an n-type semiconductor material, and further the compound N-19 (second n-type semiconductor material) as an n-type semiconductor material were mixed so that a concentration of the polymer compound P-13 was 1.5% by weight with respect to the total weight of the ink, a concentration of the compound N-14 was 0.75% by weight with respect to the total weight of the ink, and a concentration of the compound N-19 was 0.75% by weight with respect to the total weight of the ink (p-type semiconductor material/n-type semiconductor materials=1/1).

### Comparative Preparation Example 2

An ink (C-2) was prepared in the same manner as that of Preparation Example 1, except that the polymer compound P-13 as a p-type semiconductor material, the compound N-1 (first n-type semiconductor material) as an n-type semiconductor material, and further the compound N-19 (second n-type semiconductor material) as an n-type semiconductor material were mixed so that a concentration of the polymer compound P-13 was 1.5% by weight with respect to the total weight of the ink, a concentration of the compound N-1 was 0.75% by weight with respect to the total weight of the ink, and a concentration of the compound N-19 was 0.75% by weight with respect to the total weight of the ink (p-type semiconductor material/n-type semiconductor materials=1/1).

### Comparative Preparation Example 3

An ink (C-3) was prepared in the same manner as that of Preparation Example 1, except that the polymer compound P-14 as a p-type semiconductor material, the compound N-16 (first n-type semiconductor material) as an n-type semiconductor material, and further the compound N-19 (second n-type semiconductor material) as an n-type semiconductor material were mixed so that a concentration of the polymer compound P-14 was 1.5% by weight with respect to the total weight of the ink, a concentration of the compound N-16 was 1.575% by weight with respect to the total weight of the ink, and a concentration of the compound N-19 was 0.675% by weight with respect to the total weight of the ink (p-type semiconductor material/n-type semiconductor materials=1/1.5).

### Comparative Preparation Example 4

An ink (C-4) was prepared in the same manner as that of Preparation Example 1, except that the polymer compound P-14 as a p-type semiconductor material, the compound N-15 (first n-type semiconductor material) as an n-type semiconductor material, and further the compound N-19 (second n-type semiconductor material) as an n-type semiconductor material were mixed so that a concentration of the polymer compound P-14 was 1.5% by weight with respect to the total weight of the ink, a concentration of the compound N-15 was 2.25% by weight with respect to the total weight of the ink, and a concentration of the compound N-19 was 0.45% by weight with respect to the total weight of the ink (p-type semiconductor material/n-type semiconductor materials=1/1.8).

### Comparative Preparation Example 5

An ink (C-5) was prepared in the same manner as that of Preparation Example 1, except that the polymer compound P-1 as a p-type semiconductor material, the compound N-18 (first n-type semiconductor material) as an n-type semiconductor material, and further the compound N-19 (second n-type semiconductor material) as an n-type semiconductor material were mixed so that a concentration of the polymer compound P-1 was 1.5% by weight with respect to the total weight of the ink, a concentration of the compound N-18 was 2.04% by weight with respect to the total weight of the ink, and a concentration of the compound N-19 was 0.21% by weight with respect to the total weight of the ink (p-type semiconductor material/n-type semiconductor materials=1/1.5).

TABLE 6

| | | p-type | First n-type | Second n-type |
|---|---|---|---|---|
| | | semiconductor | semiconductor | semiconductor |
| | Ink | material | material | material |
| Preparation | I-1 | P-1 | N-1 | N-18 |
| example 1 | | | | |
| Preparation | I-2 | P-1 | N-2 | N-18 |
| example 2 | | | | |
| Preparation | I-3 | P-1 | N-1 | N-19 |
| example 3 | | | | |
| Preparation | I-4 | P-1 | N-14 | N-19 |
| example 4 | | | | |
| Preparation | I-5 | P-1 | N-15 | N-19 |
| example 5 | | | | |
| Preparation | I-6 | P-1 | N-16 | N-19 |
| example 6 | | | | |
| Preparation | I-7 | P-1 | N-17 | N-18 |
| example 7 | | | | |
| Preparation | I-8 | P-2 | N-1 | N-18 |
| example 8 | | | | |
| Preparation | I-9 | P-3 | N-1 | N-18 |
| example 9 | | | | |
| Preparation | I-10 | P-4 | N-1 | N-18 |
| example 10 | | | | |
| Preparation | I-11 | P-5 | N-1 | N-18 |
| example 11 | | | | |
| Preparation | I-12 | P-1 | N-1 | N-18 |
| example 12 | | | | |
| Preparation | I-13 | P-1 | N-1 | N-18 |
| example 13 | | | | |
| Preparation | I-14 | P-1 | N-1 | N-14 |
| example 14 | | | | |
| Preparation | I-15 | P-1 + P-2 | N-1 | N-18 |
| example 15 | | | | |
| Comparative | C-1 | P-13 | N-14 | N 19 |
| preparation | | | | |
| example 1 | | | | |
| Comparative | C-2 | P-13 | N-1 | N-19 |
| preparation | | | | |
| example 2 | | | | |
| Comparative | C-3 | P-14 | N-16 | N-19 |
| preparation | | | | |
| example 3 | | | | |
| Comparative | C-4 | P-14 | N-15 | N-19 |
| preparation | | | | |
| example 4 | | | | |
| Comparative | C-5 | P-1 | N-18 | N-19 |
| preparation | | | | |
| example 5 | | | | |

### <Example 1> (Manufacture and Evaluation of Photoelectric Conversion Element)

(1) Manufacture of Photoelectric Conversion Element and Sealing Body Thereof

A photoelectric conversion element and a sealing body thereof were manufactured as follows. Note that a plurality of photoelectric conversion elements and sealing bodies thereof were manufactured for each of Examples (and Comparative Examples) for evaluation described below.

A glass substrate on which an ITO thin film (anode) was formed was prepared at a thickness of 50 nm by a sputtering method, and the glass substrate was subjected to an ozone UV treatment as a surface treatment.

Next, the ink (I-1) was coated onto the ITO thin film by a spin coating method to form a coating film, and then the coating film was dried by a heat treatment for 10 minutes using a hot plate heated to 100° C. under a nitrogen gas atmosphere (pre-baking step).

Furthermore, on the hot plate heated to 100° C. under a nitrogen gas atmosphere, a structure in which an anode and an active layer were laminated in this order on a glass substrate was subjected to a heat treatment for 50 minutes (post-baking step) to form an active layer. A thickness of the formed active layer was about 300 nm.

Next, a calcium (Ca) layer having a thickness of about 5 nm was formed on the formed active layer in a resistance heating vapor deposition device to form an electron transport layer.

Then, a silver (Ag) layer having a thickness of about 60 nm was formed on the formed electron transport layer to form a cathode.

A photoelectric conversion element was manufactured on the glass substrate by the above steps. The obtained structure was used as a sample 1.

Next, a UV-curable sealing agent as a sealing material was coated onto a glass substrate as a support substrate so as to surround the periphery of the manufactured photoelectric conversion element, a glass substrate as a sealing substrate was bonded, and then, the photodetector was sealed in a gap between the support substrate and the sealing substrate by irradiation with UV light, thereby obtaining a sealing body of the photoelectric conversion element. The photoelectric conversion element sealed in the gap between the support substrate and the sealing substrate had a planar shape of a square of 2 mm×2 mm when viewed from a thickness direction.

(2) Evaluation of Photoelectric Conversion Element

(i) Evaluation of Heat Resistance and Characteristics

A reverse bias voltage of −5 V was applied to the sealing body of the manufactured photoelectric conversion element, and an external quantum efficiency (EQE) and a dark current at the applied voltage were evaluated using a solar simulator (CEP-2000, manufactured by Bunkoukeiki Co., Ltd.) and a source meter (KEITHLEY 2450 Source Meter, manufactured by Keithley Instruments), respectively.

As for the EQE, first, a current value of a current generated when light of a constant number of photons (1.0×10¹⁶) was radiated every 20 nm in a wavelength range of 300 nm to 1,200 nm in a state where a reverse bias voltage of −5 V was applied to the sealing body of the photoelectric conversion element was measured, and a spectrum of the EQE at a wavelength of 300 nm to 1,200 nm was obtained by a known method.

Next, among the plurality of obtained measured values for every 20 nm, the measured value at the wavelength (Amax) closest to the absorption peak wavelength was taken as the value (%) of EQE.

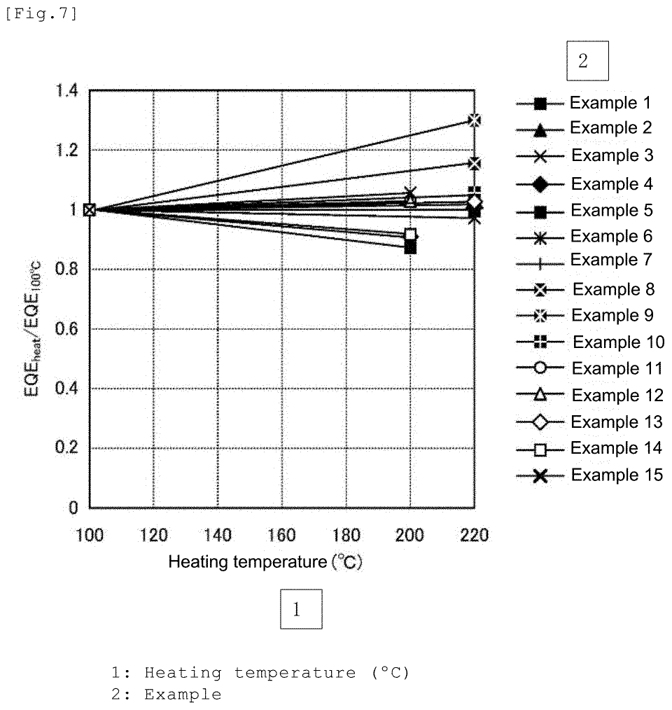

In the evaluation of the EQE of the photoelectric conversion element, a value (EQEₕₑₐₜ/EQE_{100° C.}) obtained by normalization by dividing the value by the value of the EQE in the photoelectric conversion element (sample 1) in which the heating temperature in the post-baking step was 100° C. as a reference by the value of the EQE in the photoelectric conversion element (sample 2) in which the heating temperature in the post-baking step was changed was evaluated. The results are shown in Table 7 and illustrated in FIG. 7. FIG. 7 is a graph showing a relationship between the heating temperature and EQEₕₑₐₜ/EQE_{100° C.}

TABLE 7

| | | Heat | EQEₕₑₐₜ/ |
|---|---|---|---|
| | Ink | resistance | EQE_{100° C.} |
| Example 1 | I-1 | ◯ (220° C.) | 1.00 (220° C.) |
| Example 2 | I-2 | ◯ (220° C.) | 1.03 (220° C.) |
| Example 3 | I-3 | ◯ (220° C.) | 0.97 (220° C.) |
| Example 4 | I-4 | ◯ (200° C.) | 0.91 (200° C.) |
| Example 5 | I-5 | ◯ (200° C.) | 0.88 (200° C.) |
| Example 6 | I-6 | ◯ (200° C.) | 1.06 (200° C.) |
| Example 7 | I-7 | ◯ (200° C.) | 1.05 (200° C.) |
| Example 8 | I-8 | ◯ (220° C.) | 1.15 (220° C.) |
| Example 9 | I-9 | ◯ (220° C.) | 1.29 (220° C.) |
| Example 10 | I-10 | ◯ (220° C.) | 1.05 (220° C.) |
| Example 11 | I-11 | ◯ (200° C.) | 1.03 (200° C.) |
| Example 12 | I-12 | ◯ (220° C.) | 1.03 (220° C.) |
| Example 13 | I-13 | ◯ (220° C.) | 1.03 (220° C.) |
| Example 14 | I-14 | ◯ (200° C.) | 0.92 (200° C.) |
| Example 15 | I-15 | ◯ (220° C.) | 1.00 (220° C.) |

As was clear from Table 7 and FIG. 7, in the “sample 2” according to Example 1, it was found that the value of the EQE was not decreased even though the heating temperature in the post-baking step was 220° C., and the EQE rather tended to be increased. Therefore, it can be said that the heat resistance is evaluated as “good (o)” in the range of 100° C. to 220° C.

### <Examples 2 to 15> (Manufacture and Evaluation of Photoelectric Conversion Elements)

Sealing bodies of the photoelectric conversion elements were manufactured in the same manner as that of Example 1 described above, except that the inks (I-2) to (I-15) were used instead of the ink (I-1). Note that in all of Examples 2 to 15, the heating temperature in the post-baking step for the “sample 1” was 100° C.

The heating temperature in the post-baking step for the “sample 2” of each of Examples 2, 3, 8 to 10, 12, 13, and 15 was 220° C. as shown in Table 7, and the heating temperature in the post-baking step for the “sample 2” of each of Examples 4 to 7, 11, and 14 was 200° C. as shown in Table 7. The results are illustrated in FIG. 7.

### <Comparative Examples 1 to 5> (Manufacture and Evaluation of Photoelectric Conversion Elements)

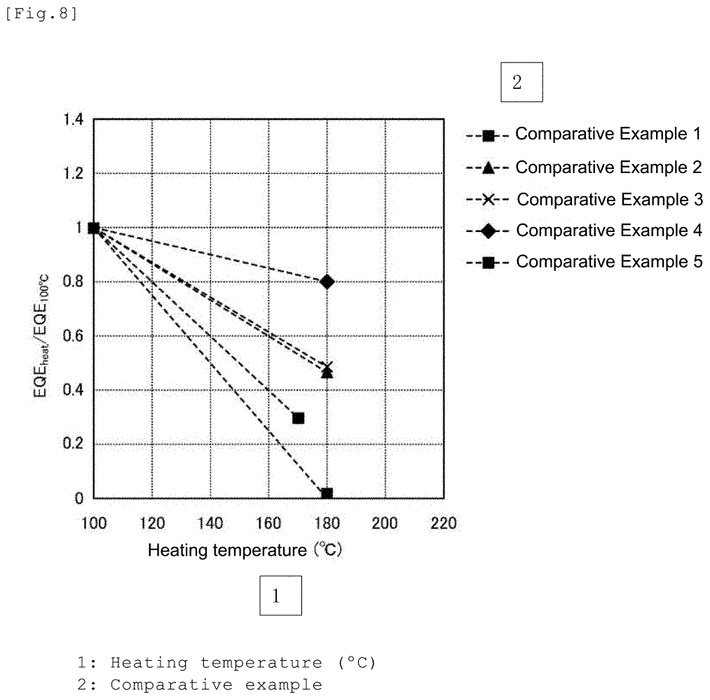

Sealing bodies of the photoelectric conversion elements were manufactured in the same manner as that of Example 1 described above, except that the inks (C-1) to (C-5) were used instead of the ink (I-1). Note that in all of Comparative Examples 1 to 5, the heating temperature in the post-baking step for the “sample 1” was 100° C. The heating temperature in the post-baking step for the “sample 2” of each of Comparative Examples 1 to 4 was 180° C. as shown in Table 8, and the heating temperature in the post-baking step for the “sample 2” of Comparative Example 5 was 170° C. as shown in Table 8. The results are illustrated in FIG. 8.

TABLE 8

| | | Heat | EQEₕₑₐₜ/ |
|---|---|---|---|
| | Ink | resistance | EQE_{100° C.} |
| Comparative example 1 | C-1 | X (180° C.) | 0.012 (180° C.) |
| Comparative example 2 | C-2 | X (180° C.) | 0.48 (180° C.) |
| Comparative example 3 | C-3 | X (180° C.) | 0.48 (180° C.) |
| Comparative example 4 | C-4 | X (180° C.) | 0.80 (180° C.) |
| Comparative example 5 | C-5 | X (170° C.) | 0.30 (170° C.) |

As was clear from Table 7 and FIG. 7, in the “sample 2” according to each of Examples 2 to 15, it was confirmed that since the value of “EQEₕₑₐₜ/EQE_{100° C.}” was maintained at 0.85 or more even though the heating temperature in the post-baking step was 200° C. or higher, the value of the EQE was not decreased by the heat treatment in the post-baking step. Therefore, it can be said that the heat resistance using the EQE of the “sample 2” as an index is evaluated as “good (o)” even at 200° C. or higher.

On the other hand, in the evaluation of the heat resistance of the “sample 2” according to each of Comparative Examples 1 to 5, as was clear from FIG. 8, in particular, since the value of “EQEₕₑₐₜ/EQE_{100° C.}” in a range of at least 180° C. or lower was less than 0.85, the value of the EQE was decreased by the heat treatment in the post-baking step. Therefore, the heat resistance using the EQE as an index according to each of Comparative Examples 1 to 5 is evaluated as “poor (x)”.

As for the dark current, a voltage of −10 V to 2 V was applied to the sealing body of the photoelectric conversion element in a dark state in which light was not radiated, and a current value at the time of applying a voltage of −5 V measured using a known method was obtained as a value of the dark current.

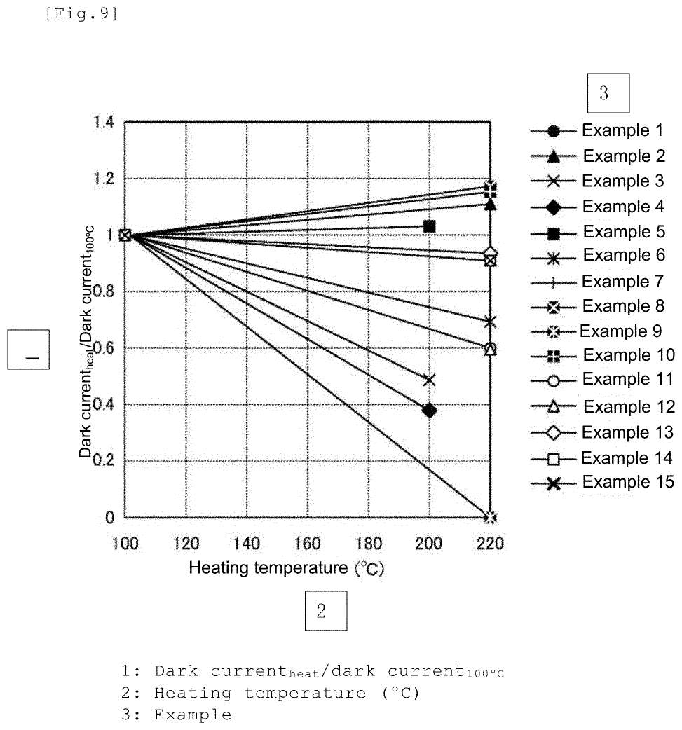

In the evaluation of the dark current of the photoelectric conversion element, a value (dark currentₕₑₐₜ/dark current_{100° C.}) obtained by normalization by dividing the value by the value of the dark current in the photoelectric conversion element (sample 1) in which the heating temperature in the post-baking step was 100° C. as a reference by the value of the dark current in the photoelectric conversion element (sample 2) in which the heating temperature in the post-baking step was changed was evaluated. The evaluation results according to Examples 1 to 15 are shown in Table 9 and illustrated in FIG. 9. FIG. 9 is a graph showing a relationship between the heating temperature and dark currentₕₑₐₜ/dark current_{100° C.}

TABLE 9

| | | Heat | Dark currentₕₑₐₜ/ | |
|---|---|---|---|---|
| | Ink | resistance | dark current_{100° C.} | |
| Example 1 | I-1 | ◯ (220° C.) | 0.91 | (220° C.) |
| Example 2 | I-2 | ◯ (220° C.) | 1.10 | (220° C.) |
| Example 3 | I-3 | ◯ (220° C.) | 0.69 | (220° C.) |
| Example 4 | I-4 | ◯ (200° C.) | 0.38 | (200° C.) |
| Example 5 | I-5 | ◯ (200° C.) | 1.03 | (200° C.) |
| Example 6 | I-6 | ◯ (200° C.) | 0.49 | (200° C.) |
| Example 7 | I-7 | ◯ (200° C.) | 0.74 | (200° C.) |
| Example 8 | I-8 | ◯ (220° C.) | 1.16 | (220° C.) |
| Example 9 | I-9 | ◯ (220° C.) | 0.0045 | (220° C.) |
| Example 10 | I-10 | ◯ (220° C.) | 1.15 | (220° C.) |
| Example 11 | I-11 | ◯ (220° C.) | 0.6 | (220° C.) |
| Example 12 | I-12 | ◯ (220° C.) | 0.93 | (220° C.) |
| Example 13 | I-13 | ◯ (220° C.) | 0.90 | (220° C.) |
| Example 14 | I-14 | ◯ (220° C.) | 0.91 | (220° C.) |
| Example 15 | I-15 | ◯ (220° C.) | 0.91 | (220° C.) |

As was clear from Table 9 and FIG. 9, the value of “dark currentₕₑₐₜ/dark current_{100° C.}” was 1.20 or less even through the heating temperature in the post-baking step was 220° C. in the “sample 2” according to each of Examples 1 to 3 and 8 to 15 and the heating temperature in the post-baking step was 200° C. in Examples 4 to 7. Therefore, it can be said that the heat resistance according to each of Examples 1 to 15 is evaluated as “good (o)” at 200° C. or higher from the viewpoint of using the dark current of the “sample 2” as an index.

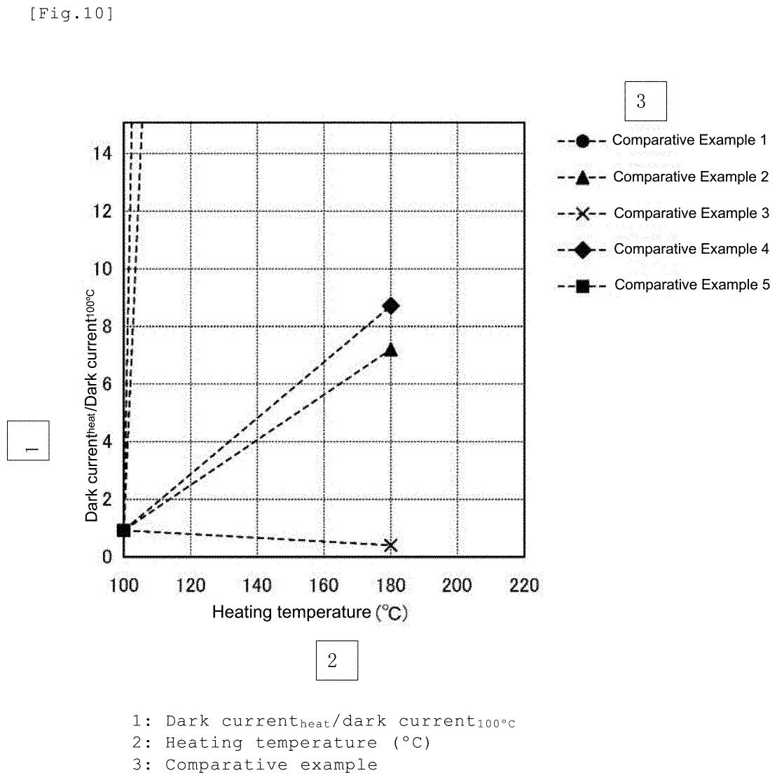

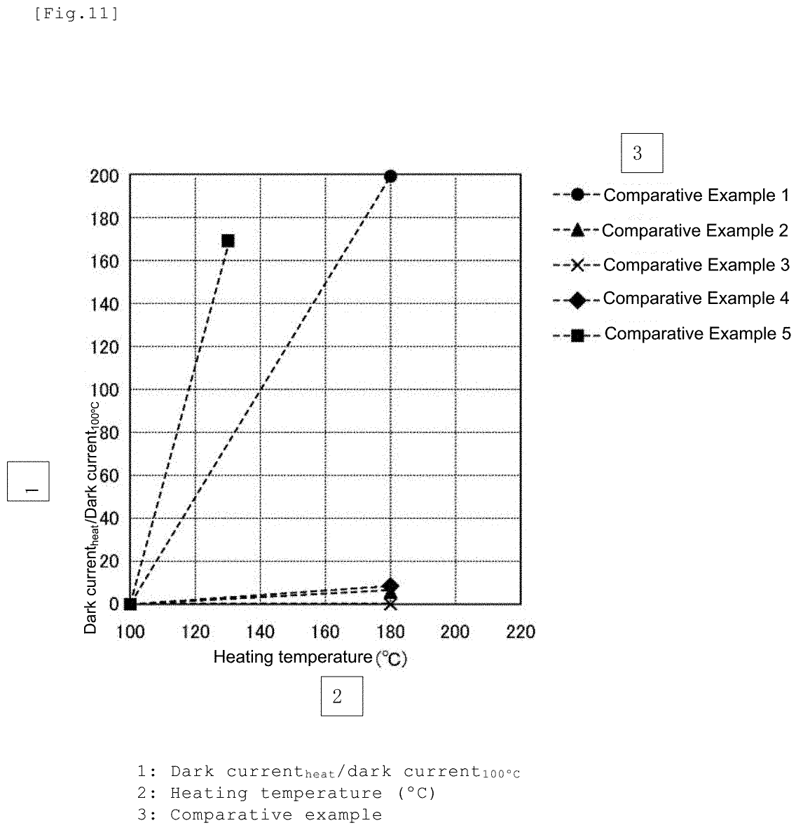

In Comparative Examples 1 to 5, the dark current was evaluated in the same manner as in Examples 1 to 15. Note that in all of Comparative Examples 1 to 5, the heating temperature in the post-baking step for the “sample 1” was 100° C. The heating temperature in the post-baking step for the “sample 2” of each of Comparative Examples 1 to 4 was 180° C. as shown in Table 10, and the heating temperature in the post-baking step for the “sample 2” of Comparative Example 5 was 130° C. as shown in Table 10. The results are shown in Table 10 and illustrated in FIGS. 10 and 11.

TABLE 10

| | | Heat | | Dark currentₕₑₐₜ/ | |
|---|---|---|---|---|---|
| | Ink | resistance | | dark current_{100° C.} | |
| Comparative example 1 | C-1 | X | (180° C.) | 198 | (180° C.) |
| Comparative example 2 | C-2 | X | (180° C.) | 7.24 | (180° C.) |
| Comparative example 3 | C-3 | ◯ | (180° C.) | 0.48 | (180° C.) |
| Comparative example 4 | C-4 | X | (180° C.) | 8.73 | (180° C.) |
| Comparative example 5 | C-5 | X | (130° C.) | 168 | (130° C.) |

As was clear from Table 10 and FIGS. 10 and 11, in the “sample 2” according to each of Comparative Examples 1, 2, 4, and 5, it was confirmed that since the value of “dark currentₕₑₐₜ/dark current_{100° C.}” in a range of at least 180° C. or lower was more than 1.20, the value of the dark current was increased by the heat treatment in the post-baking step. Therefore, the heat resistance using the dark current as an index according to each of Comparative Examples 1, 2, 4, and 5 is evaluated as “poor (x)”. On the other hand, in the case of the “sample 2” of Comparative Example 3, the heating temperature in the post-baking step was 180° C., the value of “dark currentₕₑₐₜ/dark current_{100° C.}” was 1.20 or less. Therefore, it can be said that the heat resistance using the dark current of the “sample 2” as an index is evaluated as “good (o)”. However, since the heat resistance is evaluated as “poor (x)” from the viewpoint of using the EQE as an index, the heat resistance as a whole is evaluated as “poor (x)”.

(ii) Evaluation Based on Hansen Solubility Parameters

First, as for the photoelectric conversion elements according to Examples 1 to 15 and Comparative Examples 1 to 5, the dispersive energy (dispersive energy Hansen solubility parameter: δD), which is a component of the Hansen solubility parameter of each of the p-type semiconductor material, the first n-type semiconductor material, and the second n-type semiconductor material used as the materials of the active layer was calculated. The calculation was performed using commercially available calculation software “Hansen Solubility Parameters in Practice (HSPiP Ver. 5.2)”.

Note that in calculating the Hansen solubility parameters, the p-type semiconductor material, the first n-type semiconductor material, and the second n-type semiconductor material according to Examples 1 to 15 and Comparative Examples 1 to 5 had a complicated chemical structure, and therefore the Hansen solubility parameters could not be directly calculated by HSPiP.

Therefore, according to a general method, [1] the chemical structure of each of the p-type semiconductor material, the first n-type semiconductor material, and the second n-type semiconductor material was cut to be divided into a plurality of partial structures, [2] δD was calculated for each partial compound including the partial structure, which could be directly calculated by HSPiP, and [3] a value obtained by multiplying the calculated δD value for each partial compound by the weight fraction of the partial compound was added, and the finally obtained value was set as each of the dispersive energy Hansen solubility parameter δD(P) of the p-type semiconductor material, the dispersive energy Hansen solubility parameter (δD(N′)) of the first n-type semiconductor material, and the dispersive energy Hansen solubility parameter (δD(N″)) of the second n-type semiconductor material. δD of C60 fullerene, which was a partial structure of fullerene derivative, was 22.5 MPa^{0.5} described in the e-Book attached to the software, and δD of C₇₀ fullerene was also 22.5 MPa^{0.5}. The results are as shown in Table 5.

Here, as for δD(Ni) and δD(Nii), when the value of |δD(P)−δD(N′)| and the value of |δD(P)−δD(N″)| were compared, a dispersive energy Hansen solubility parameter with a smaller value was δD(Ni), and a dispersive energy Hansen solubility parameter with a larger value was δD(Nii).

Using δD(P) of the p-type semiconductor material and the dispersive energy Hansen solubility parameters δD(Ni) and δD(Nii) of the n-type semiconductor material calculated as described above, the sum value (|δD(P)−δD(Ni)|+|δD(Ni)−δD(Nii)|) of the absolute value (|δD(P)−δD(Ni)|) of the value obtained by subtracting the value of the first dispersive energy Hansen solubility parameter δD(Ni) from the value of δD(P) of the p-type semiconductor material, the absolute value (|δD(Ni)−δD(Nii)|) of the value obtained by subtracting the value of the second dispersive energy Hansen solubility parameter δD(Nii) from the value of the first dispersive energy Hansen solubility parameter δD(Ni), the absolute value of the value obtained by subtracting the first dispersive energy Hansen solubility parameter δD(Ni) from the value of δD(P) of the p-type semiconductor material, and the absolute value of the value obtained by subtracting the value of the second dispersive energy Hansen solubility parameter δD(Nii) from the value of the first dispersive energy Hansen solubility parameter δD(Ni).

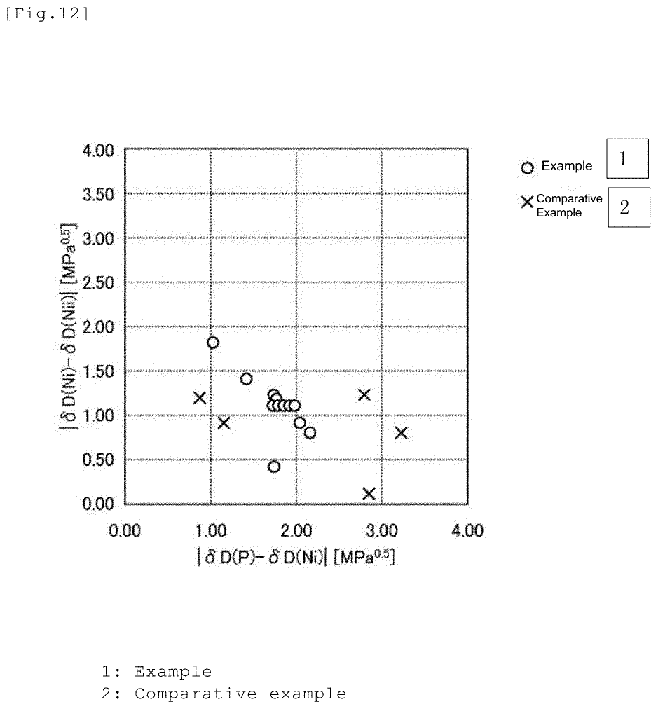

The results according to Examples 1 to 15 and Comparative Examples 1 to 5 are shown in Tables 11 and 12 and illustrated in FIG. 12. FIG. 12 is a graph showing a relationship between |δD(P)−δD(Ni)| and |δD(Ni)−δD(Nii)|.

TABLE 11

| | \|δD(P) − | \|δD(Ni) − | \|δD(P) − δD(Ni) \|+\| |
|---|---|---|---|
| | δD(Ni) \| | δD(Nii) \| | δD(Ni) − δD(Nii) |
| | [MPa^{0.5}] | [MPa^{0.5}] | [MPa^{0.5}] |
| Example 1 | 1.75 | 1.10 | 2.85 |
| Example 2 | 1.44 | 1.41 | 2.85 |
| Example 3 | 1.75 | 1.23 | 2.98 |
| Example 4 | 2.17 | 0.80 | 2.98 |
| Example 5 | 1.78 | 1.20 | 2.98 |
| Example 6 | 2.06 | 0.91 | 2.97 |
| Example 7 | 1.04 | 1.82 | 2.85 |
| Example 8 | 1.99 | 1.10 | 3.10 |
| Example 9 | 1.74 | 1.10 | 2.85 |
| Example 10 | 1.95 | 1.10 | 3.05 |
| Example 11 | 1.81 | 1.10 | 2.91 |
| Example 12 | 1.75. | 1.10 | 2.85 |
| Example 13 | 1.75 | 1.10 | 2.85 |
| Example 14 | 1.75 | 0.42 | 2.17 |
| Example 15 | 1.87 | 1.10 | 2.98 |

TABLE 12

| | \|δD(P) − | \|δD(Ni) − | \|δD(P) − δD(Ni) \|+\| |
|---|---|---|---|
| | δD(Ni) \| | δD(Nii) \| | δD(Ni) − δD(Nii) \| |
| | [MPa^{0.5}] | [MPa^{0.5}] | [MPa^{0.5}] |
| Comparative | 3.23 | 0.80 | 4.04 |
| example 1 | | | |
| Comparative | 2.81 | 1.23 | 4.04 |
| example 2 | | | |
| Comparative | 1.17 | 0.91 | 2.09 |
| example 3 | | | |
| Comparative | 0.89 | 1.20 | 2.09 |
| example 4 | | | |
| Comparative | 2.85 | 0.12 | 2.98 |
| example 5 | | | |

As shown in Tables 11 and 12 and illustrated in FIG. 12, the photoelectric conversion element of each of Examples 1 to 15 proven to have excellent characteristics and excellent heat resistance satisfied both the requirements (i) and (ii) described above. On the other hand, the photoelectric conversion element of each of Comparative Examples 1 to 5 did not satisfy any one of the requirements (i) and (ii). As described above, it was found that the action and effect of the present invention correlated with the parameter group related to the dispersive energy Hansen solubility parameter (δD).

### DESCRIPTION OF REFERENCE SIGNS

1 Image detection unit
2 Display device
10 Photoelectric conversion element
11, 210 Support substrate
12 Anode
13 Hole transport layer
14 Active layer
15 Electron transport layer
16 Cathode
17 Sealing member
20 CMOS transistor substrate
30 Interlayer insulating film
32 Interlayer wiring portion
40 Sealing layer
42 Scintillator
44 Reflective layer
46 Protection layer
50 Color filter
100 Fingerprint detection unit
200 Display panel unit
200a Display area
220 Organic EL element
230 Touch sensor panel
240 Sealing substrate
300 Vein detection unit
302 Glass substrate
304 Light source portion
306 Cover portion
310 Insertion portion
400 Image detection unit for TOF type distance measuring device
402 Floating diffusion layer
404 Photo-gate
406 Light shielding portion

1. A photoelectric conversion element comprising an anode, a cathode, and an active layer provided between the anode and the cathode,
wherein the active layer contains at least one p-type semiconductor material and at least two n-type semiconductor materials, and
a dispersive energy Hansen solubility parameter δD(P) of the at least one p-type semiconductor material and a first dispersive energy Hansen solubility parameter δD(Ni) and a second dispersive energy Hansen solubility parameter δD(Nii) of the at least two n-type semiconductor materials satisfy the following requirements (i) and (ii):
2.1 MPa^{0.5}<|δD(P)−δD(Ni)|+|δD(Ni)−δD(Nii)|<4.0 MPa^{0.5} Requirement (i):
0.8 MPa^{0.5}<|δD(P)−δD(Ni)| and 0.2 MPa^{0.5}<|δD(Ni)−δD(Nii)| Requirement (ii):
in the requirements (i) and (ii),
δD(P) is a value calculated by the following Equation (1),
$$\begin{matrix}[ Math . 10 ] & \\ δ D ( P ) = \frac{1}{{\sum }_{b = 1}^{a} {w}_{b}} {\sum }_{b = 1}^{a} {w}_{b} δ D ( {P}_{b} ) & ( 1 )\end{matrix}$$
in Equation (1),
a is an integer of 1 or more and represents the number of types of the p-type semiconductor materials contained in the active layer,
b is an integer of 1 or more and represents the order of weight values of the p-type semiconductor materials contained in the active layer when the weight values are arranged in descending order,
W_{b} represents a weight of the p-type semiconductor material (P_{b}) whose weight order is b, the p-type semiconductor material being contained in the active layer, and
δD(P_{b}) represents a dispersive energy Hansen solubility parameter of the p-type semiconductor material (P_{b}), and
δD(Ni) and δD(Nii) are determined based on δD(N′) and δD(N″) calculated by the following Equations (2) and (3), respectively, and when a value of |δD(P)−δD(N′)| and a value of |δD(P)−δD(N″)| are compared, a dispersive energy Hansen solubility parameter with a smaller value is δD(Ni), and a dispersive energy Hansen solubility parameter with a larger value is δD(Nii), in which δD(N′) is a value of a material having the largest value of the dispersive energy Hansen solubility parameter (δD) among two or more materials in a case where the number of materials having the highest order is two or more when weight values are arranged in descending order,
[Math. 2]
δD(N′)=δD(N₁) (2)
in Equation (2),
δD(N₁) represents a dispersive energy Hansen solubility parameter of an n-type semiconductor material having the largest weight value contained in the active layer among the two or more n-type semiconductor materials,
$$\begin{matrix}[ Math . 3 ] & \\ δ D ( N ’ ’ ) = \frac{1}{{\sum }_{d = 2}^{c} {w}_{d}} {\sum }_{d = 2}^{c} {w}_{d} δ D ( {N}_{d} ) & ( 3 )\end{matrix}$$
in Equation (3),
c is an integer of 2 or more and represents the number of types of the n-type semiconductor materials contained in the active layer,
d is an integer of 1 or more and represents the order of weight values of the n-type semiconductor materials contained in the active layer when the weight values are arranged in descending order,
W_{d} represents a weight of the n-type semiconductor material (N_{d}) whose weight order is d, the n-type semiconductor material being contained in the active layer, and
δD(N_{d}) represents a dispersive energy Hansen solubility parameter of the n-type semiconductor material (N_{d}).

2. The photoelectric conversion element according to claim 1, wherein the p-type semiconductor material contains a polymer compound having a structural unit represented by the following Formula (I): 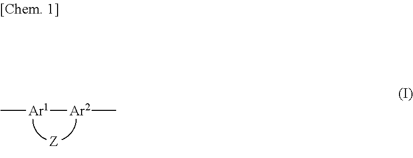
in Formula (I),
Ar¹ and Ar² each independently represent a trivalent aromatic heterocyclic group which may have a substituent, and
Z represents a group represented by any one of the following Formulas (Z-1) to (Z-7), 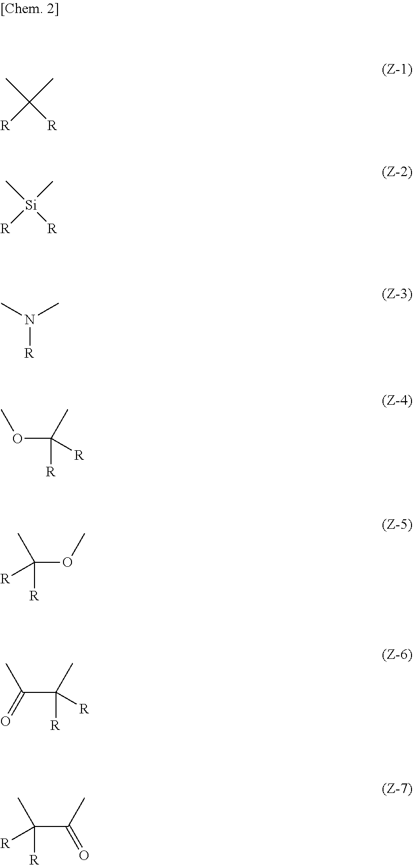
in Formulas (Z-1) to (Z-7),
R represents
a hydrogen atom,
a halogen atom,
an alkyl group which may have a substituent,
an aryl group which may have a substituent,
a cycloalkyl group which may have a substituent,
an alkoxy group which may have a substituent,
a cycloalkoxy group which may have a substituent,
an aryloxy group which may have a substituent,
an alkylthio group which may have a substituent,
a cycloalkylthio group which may have a substituent,
an arylthio group which may have a substituent,
a monovalent heterocyclic group which may have a substituent,
a substituted amino group which may have a substituent,
an acyl group which may have a substituent,
an imine residue which may have a substituent,
an amide group which may have a substituent,
an acid imide group which may have a substituent,
a substituted oxycarbonyl group which may have a substituent,
an alkenyl group which may have a substituent,
a cycloalkenyl group which may have a substituent,
an alkynyl group which may have a substituent,
a cycloalkynyl group which may have a substituent,
a cyano group,
a nitro group,
a group represented by —C(═O)—R^{a}, or
a group represented by —SO₂—R^{b},
R^{a} and R^{b} each independently represent
a hydrogen atom,
an alkyl group which may have a substituent,
an aryl group which may have a substituent,
an alkoxy group which may have a substituent,
an aryloxy group which may have a substituent, or
a monovalent heterocyclic group which may have a substituent, and
in Formulas (Z-1) to (Z-7), when the number of R′s is two, the two R′s may be the same as or different from each other.

3. The photoelectric conversion element according to claim 1, wherein at least one of the at least two n-type semiconductor materials is a non-fullerene compound.

4. The photoelectric conversion element according to claim 3, wherein at least one of the at least two n-type semiconductor materials is a non-fullerene compound, and the remaining n-type semiconductor material is a fullerene derivative.

5. The photoelectric conversion element according to claim 3, wherein both of the at least two n-type semiconductor materials are non-fullerene compounds.

6. The photoelectric conversion element according to claim 3, wherein the non-fullerene compound is a compound represented by the following Formula (VIII): 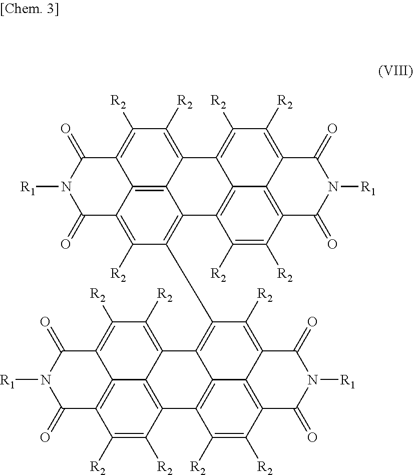
in Formula (VIII),
R₁ represents a hydrogen atom, a halogen atom, an alkyl group which may have a substituent, an alkoxy group which may have a substituent, a monovalent aromatic hydrocarbon group which may have a substituent, or a monovalent aromatic heterocyclic group which may have a substituent, and the plurality of R₁'s may be the same as or different from each other, and
R₂ represents a hydrogen atom, a halogen atom, an alkyl group which may have a substituent, an alkoxy group which may have a substituent, a monovalent aromatic hydrocarbon group which may have a substituent, or a monovalent aromatic heterocyclic group which may have a substituent, and the plurality of R₂'s may be the same as or different from each other.

7. The photoelectric conversion element according to claim 3, wherein the non-fullerene compound is a compound represented by the following Formula (IX):
A¹-B¹⁰-A² (IX)
n Formula (IX),
A¹ and A² each independently represent an electron-withdrawing group, and
B¹⁰ represents a group having a π-conjugated system.

8. The photoelectric conversion element according to claim 7, wherein the non-fullerene compound is a compound represented by the following Formula (X):
A¹-(S¹)ₙ₁—B¹¹—(S²)ₙ₂-A² (X)
in Formula (X),
A¹ and A² each independently represent an electron-withdrawing group,
S¹ and S² each independently represent
a divalent carbocyclic group which may have a substituent,
a divalent heterocyclic group which may have a substituent,
a group represented by —C(R^{s1})═C(R^{s2})—, or
a group represented by —C≡C—,
R^{s1} and R^{s2} each independently represent a hydrogen atom or a substituent,
B¹¹ represents a divalent group having a condensed ring in which two or more ring structures selected from the group consisting of a carbocyclic ring and a heterocyclic ring are condensed, in which the divalent group does not have an ortho-peri-condensed structure and may have a substituent, and
n1 and n2 each independently represent an integer of 0 or more.

9. The photoelectric conversion element according to claim 8, wherein B¹¹ is a divalent group having a condensed ring in which two or more ring structures selected from the group consisting of structures represented by the following Formulas (Cy1) to (Cy9) are condensed, in which the divalent group may have a substituent: 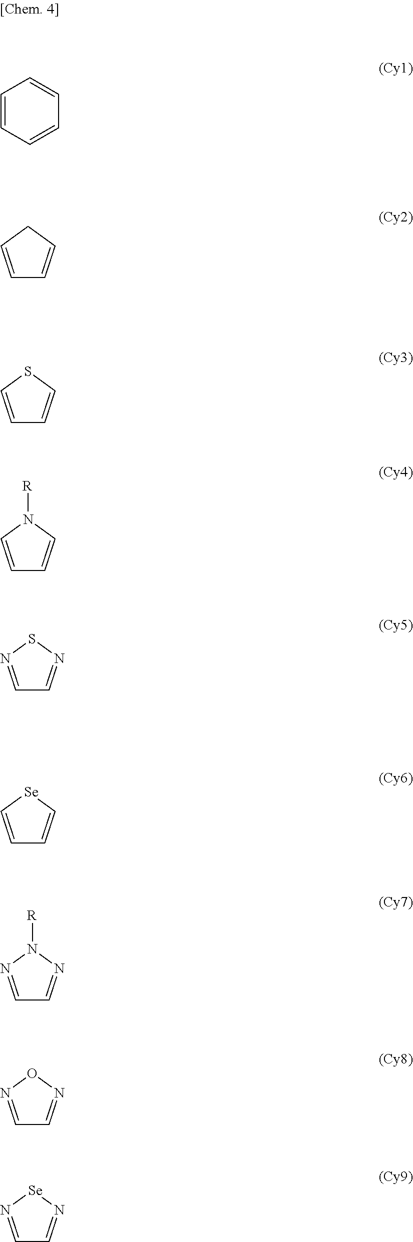
in the formulas, R is as defined above.

10. The photoelectric conversion element according to claim 8, wherein S¹ and S² each independently represent a group represented by the following Formula (s-1) or a group represented by the following Formula (s-2): 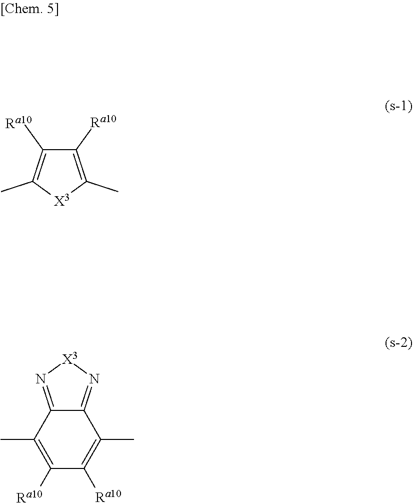
in Formulas (s-1) and (s-2),
X³ represents an oxygen atom or a sulfur atom, and
R^{a10}'s each independently represent a hydrogen atom, a halogen atom, or an alkyl group.

11. The photoelectric conversion element according to claim 7, wherein A¹ and A² are each independently a group represented by —CH═C(—CN)₂ or a group selected from the group consisting of the following Formulas (a-1) to (a-7): 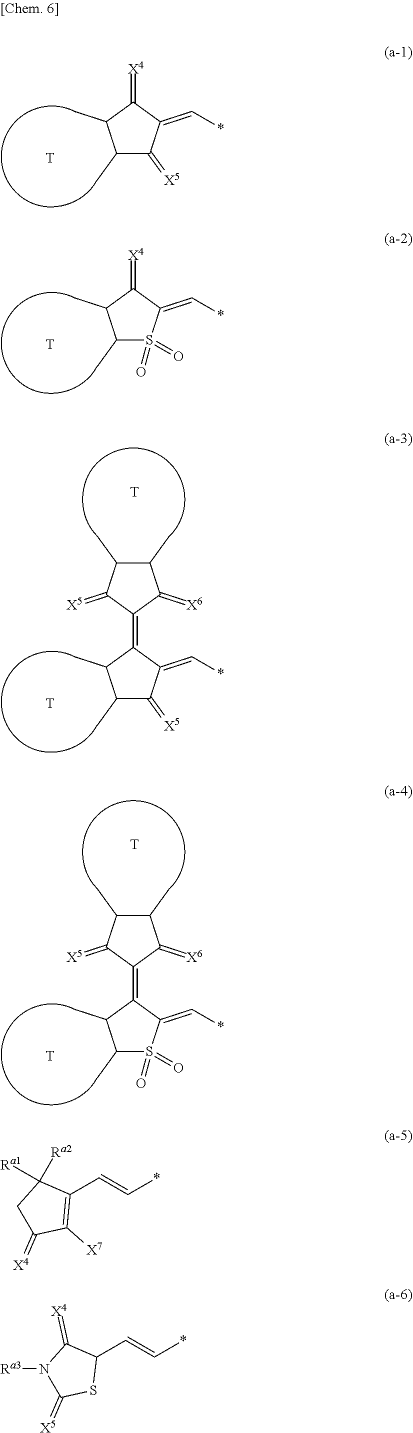 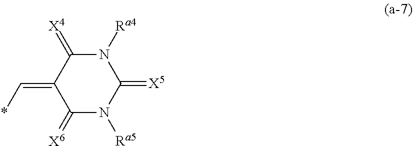
in Formulas (a-1) to (a-7),
T represents
a carbocyclic ring which may have a substituent or
a heterocyclic ring which may have a substituent,
X⁴, X⁵, and X⁶ each independently represent an oxygen atom, a sulfur atom, an alkylidene group, or a group represented by ═C(—CN)₂,
X⁷ represents a hydrogen atom, a halogen atom, a cyano group, an alkyl group which may have a substituent, an alkoxy group which may have a substituent, an aryl group which may have a substituent, or a monovalent heterocyclic group which may have a substituent, and
R^{a1}, R^{a2}, R^{a3}, R^{a4}, and R^{a5} each independently represent a hydrogen atom, a halogen atom, an alkyl group which may have a substituent, an alkoxy group which may have a substituent, an aryl group which may have a substituent, or a monovalent heterocyclic group.

12. The photoelectric conversion element according to claim 1, wherein the active layer is formed by a step including a heat treatment performed at a heating temperature of 200° C. or higher.

13. The photoelectric conversion element according to claim 1, wherein the photoelectric conversion element is a photodetector.

14. An image sensor comprising the photoelectric conversion element according to claim 13,
wherein the image sensor is manufactured by a manufacturing method including a step including heating the photoelectric conversion element at a heating temperature of 200° C. or higher.

15. A biometric authentication device comprising the photoelectric conversion element according to claim 13,
wherein the biometric authentication device is manufactured by a manufacturing method including a step including heating the photoelectric conversion element at a heating temperature of 200° C. or higher.

16. A method for manufacturing the photoelectric conversion element according to claim 1, the method comprising:
a step of forming the active layer that includes a step (i) of obtaining a coating film by applying an ink containing the at least one p-type semiconductor material and the at least two n-type semiconductor materials to an object to be coated; and a step (ii) of removing a solvent from the obtained coating film.

17. The method for manufacturing the photoelectric conversion element according to claim 16, further comprising a step of performing heating at a heating temperature of 200° C. or higher.

18. The method for manufacturing the photoelectric conversion element according to claim 17, wherein the step of performing heating at a heating temperature of 200° C. or higher is performed after the step (ii).

19. A composition comprising at least one p-type semiconductor material and at least two n-type semiconductor materials,
wherein a dispersive energy Hansen solubility parameter δD(P) of the at least one p-type semiconductor material and a first dispersive energy Hansen solubility parameter δD(Ni) and a second dispersive energy Hansen solubility parameter δD(Nii) of the at least two n-type semiconductor materials satisfy the following requirements (i) and (ii):
2.1 MPa^{0.5}<|δD(P)−δD(Ni)|+|δD(Ni)−δD(Nii)|<4.0 MPa^{0.5} Requirement (i):
0.8 MPa^{0.5}<|δD(P)−δD(Ni)| and 0.2 MPa^{0.5}<|δD(Ni)−δD(Nii)| Requirement (ii):
in the requirements (i) and (ii),
δD(P) is a value calculated by the following Equation (1),
$$\begin{matrix}[ Math . 4 ] & \\ δ D ( P ) = \frac{1}{{\sum }_{b = 1}^{a} {w}_{b}} {\sum }_{b = 1}^{a} {w}_{b} δ D ( {P}_{b} ) & ( 1 )\end{matrix}$$
in Equation (1),
a is an integer of 1 or more and represents the number of types of the p-type semiconductor materials contained in the active layer,
b is an integer of 1 or more and represents the order of weight values of the p-type semiconductor materials contained in the active layer when the weight values are arranged in descending order,
W_{b} represents a weight of the p-type semiconductor material (P_{b}) whose weight order is b, the p-type semiconductor material being contained in the active layer, and
δD(P_{b}) represents a dispersive energy Hansen solubility parameter of the p-type semiconductor material (P_{b}), and
δD(Ni) and δD(Nii) are determined based on δD(N′) and δD(N″) calculated by the following Equations (2) and (3), respectively, and when a value of |δD(P)−δD(N′)| and a value of |δD(P)−δD(N″)| are compared, a dispersive energy Hansen solubility parameter with a smaller value is δD(Ni), and a dispersive energy Hansen solubility parameter with a larger value is δD(Nii), in which δD(N′) is a value of a material having the largest value of the dispersive energy Hansen solubility parameter (δD) among two or more materials in a case where the number of materials having the highest order is two or more when weight values are arranged in descending order,
[Math. 5]
δD(N′)=δD(N₁) (2)
in Equation (2),
δD(Ni) represents a dispersive energy Hansen solubility parameter of an n-type semiconductor material having the largest weight value contained in the active layer among the two or more n-type semiconductor materials,
$$\begin{matrix}[ Math . 6 ] & \\ δ D ( N ’ ’ ) = \frac{1}{{\sum }_{d = 2}^{c} {w}_{d}} {\sum }_{d = 2}^{c} {w}_{d} δ D ( {N}_{d} ) & ( 3 )\end{matrix}$$
in Equation (3),
c is an integer of 2 or more and represents the number of types of the n-type semiconductor materials contained in the active layer,
d is an integer of 1 or more and represents the order of weight values of the n-type semiconductor materials contained in the active layer when the weight values are arranged in descending order,
W_{d} represents a weight of the n-type semiconductor material (N_{d}) whose weight order is d, the n-type semiconductor material being contained in the active layer, and
δD(N_{d}) represents a dispersive energy Hansen solubility parameter of the n-type semiconductor material (N_{d}).

20. The composition according to claim 19, wherein the p-type semiconductor material is a polymer compound having a structural unit represented by the following Formula (I): 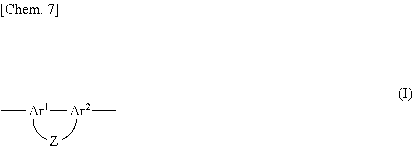
in Formula (I),
Ar¹ and Ar² each independently represent a trivalent aromatic heterocyclic group which may have a substituent, and
Z represents a group represented by any one of the following Formulas (Z-1) to (Z-7), 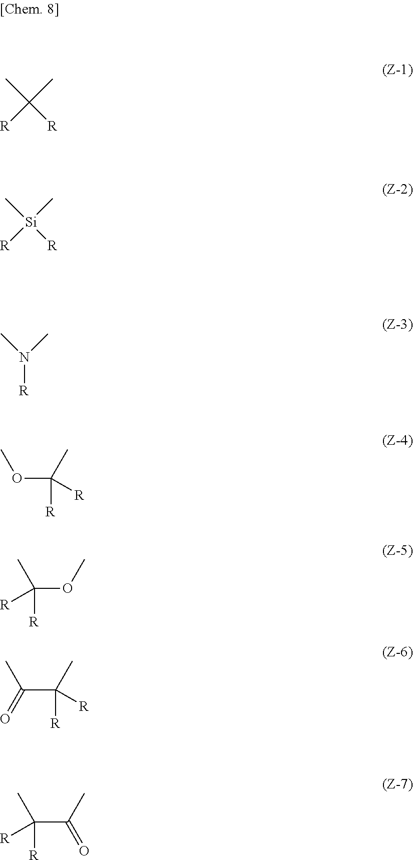
in Formulas (Z-1) to (Z-7),
R represents
a hydrogen atom,
a halogen atom,
an alkyl group which may have a substituent,
an aryl group which may have a substituent,
a cycloalkyl group which may have a substituent,
an alkoxy group which may have a substituent,
a cycloalkoxy group which may have a substituent,
an aryloxy group which may have a substituent,
an alkylthio group which may have a substituent,
a cycloalkylthio group which may have a substituent,
an arylthio group which may have a substituent,
a monovalent heterocyclic group which may have a substituent,
a substituted amino group which may have a substituent,
an acyl group which may have a substituent,
an imine residue which may have a substituent,
an amide group which may have a substituent,
an acid imide group which may have a substituent,
a substituted oxycarbonyl group which may have a substituent,
an alkenyl group which may have a substituent,
a cycloalkenyl group which may have a substituent,
an alkynyl group which may have a substituent,
a cycloalkynyl group which may have a substituent,
a cyano group,
a nitro group,
a group represented by —C(═O)—R^{a}, or
a group represented by —SO₂—R^{b},
R^{a} and R^{b} each independently represent
a hydrogen atom,
an alkyl group which may have a substituent,
an aryl group which may have a substituent,
an alkoxy group which may have a substituent,
an aryloxy group which may have a substituent, or
a monovalent heterocyclic group which may have a substituent, and
in Formulas (Z-1) to (Z-7), when the number of R's is two, the two R's may be the same as or different from each other, and
at least one of the at least two n-type semiconductor materials is a non-fullerene compound.

21. The composition according to claim 20, wherein at least one of the at least two n-type semiconductor materials is a non-fullerene compound, and the remaining n-type semiconductor material is a fullerene derivative.

22. The composition according to claim 20, wherein both of the at least two n-type semiconductor materials are non-fullerene compounds.

23. The composition according to claim 20, wherein the non-fullerene compound is a compound represented by the following Formula (VIII): 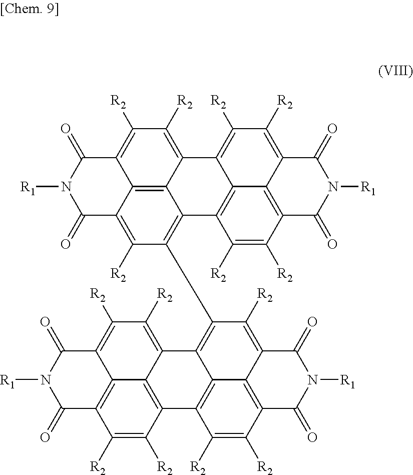
in Formula (VIII),
R₁ represents a hydrogen atom, a halogen atom, an alkyl group which may have a substituent, an alkoxy group which may have a substituent, a monovalent aromatic hydrocarbon group which may have a substituent, or a monovalent aromatic heterocyclic group which may have a substituent, and the plurality of R₁'s may be the same as or different from each other, and
R₂ represents a hydrogen atom, a halogen atom, an alkyl group which may have a substituent, an alkoxy group which may have a substituent, a monovalent aromatic hydrocarbon group which may have a substituent, or a monovalent aromatic heterocyclic group which may have a substituent, and the plurality of R₂'s may be the same as or different from each other.

24. The composition according to claim 20, wherein the non-fullerene compound is a compound represented by the following Formula (IX):
A¹-B¹⁰-A² (IX)
in Formula (IX),
A¹ and A² each independently represent an electron-withdrawing group, and
B¹⁰ represents a group having a π-conjugated system.

25. An ink comprising the composition according to claim 19.
